(19) United States
(12) Patent Application Publication
(10) Pub. No.: US 2026/0322183 A1
(43) Pub. Date: Oct. 15, 2026

(54) HYBRID COUNTERTOP WIRELESS CHARGING

(71) Applicant: AIRA, INC., Phoenix, AZ (US)

(72) Inventors: Jake Slatnick, Scottsdale, AZ (US); Mohammad Ali Saket Tokaldani, Phoenix, AZ (US); David Russell, Scottsdale, AZ (US); Aleksandar Petrovic, Phoenix, AZ (US)

(21) Appl. No.: 19/200,655

(22) Filed: May 6, 2025

Related U.S. Application Data
(60) Provisional application No. 63/787,698, filed on Apr. 11, 2025.

(51) Int. Cl. H02J 50/90; H01F 27/28; H02J 50/12; H02J 50/40; H05K 1/16

(52) U.S. Cl. CPC H02J 50/90; H01F 27/2823; H02J 50/12; H02J 50/402; H05K 1/165

(57) ABSTRACT

A hybrid charging system has a plurality of fixed charging coils and at least one movable charging coil. The plurality of fixed charging coils may be formed in a metal layer of a PCB that is located adjacent to a charging surface. A first movable charging coil may be mechanically coupled to a first positioning mechanism that is configured to move the first movable charging coil across the charging surface, wherein the printed circuit board is located between the charging surface and the first movable charging coil. The processing circuit may be configured to align the first movable charging coil with the estimated location of the detected chargeable device. One or more other movable charging coils may be mechanically coupled to respective positioning mechanisms, and each positioning mechanism that can be configured to move the corresponding movable charging coil across the charging surface.

### PRIORITY CLAIM

This application claims priority to and the benefit of provisional patent application No. 63/787,698 filed in the United States Patent Office on Apr. 11, 2025, the entire content of this application being incorporated herein by reference as if fully set forth below in its entirety and for all applicable purposes.

### TECHNICAL FIELD

The present invention relates generally to charging surfaces for wireless charging of batteries in mobile computing devices, and more particularly to providing a charging surface in a countertop that includes fixed and relocatable coils.

### BACKGROUND

Wireless charging systems have been deployed to enable certain types of devices to charge internal batteries without the use of a physical charging connection. Devices that can take advantage of wireless charging include mobile processing and/or communication devices. Standards, such as the Qi standard defined by the Wireless Power Consortium enable devices manufactured by a first supplier to be wirelessly charged using a charger manufactured by a second supplier. Standards for wireless charging are optimized for relatively simple configurations of devices and tend to provide basic charging capabilities.

Improvements in wireless charging capabilities are required to provide flexibility in charging configurations and support continually increasing complexity of mobile devices and changing form factors.

### BRIEF DESCRIPTION OF THE DRAWINGS

FIG. 1 illustrates an example of a charging cell that may be employed to provide a charging surface in accordance with certain aspects disclosed herein.

FIG. 2 illustrates an example of an arrangement of charging cells provided on a single layer of a segment of a charging surface that may be adapted in accordance with certain aspects disclosed herein.

FIG. 3 illustrates an example of an arrangement of charging cells when multiple layers are overlaid within a segment of a charging surface that may be adapted in accordance with certain aspects disclosed herein.

FIG. 4 illustrates the arrangement of power transfer areas provided by a charging surface that employs multiple layers of charging cells configured in accordance with certain aspects disclosed herein.

FIG. 5 illustrates an example of a Litz transmitting coil configured in accordance with certain aspects of this disclosure.

FIG. 6 illustrates an example of a portion of a charging surface provided using multiple overlapping Litz coils in accordance with certain aspects of this disclosure.

FIG. 7 illustrates a charging assembly in a wireless charging device constructed from Litz coils according to certain aspects of this disclosure.

FIG. 8 illustrates certain aspects of a Litz coil substrate provided in accordance with certain aspects of this disclosure.

FIG. 9 illustrates a wireless transmitter in a charger base station.

FIG. 10 illustrates examples of responses to a passive ping.

FIG. 11 illustrates differences in responses to a passive ping.

FIG. 12 illustrates a method involving passive ping implemented in a wireless charging device adapted in accordance with certain aspects disclosed herein.

FIG. 13 illustrates an example of frequency response obtained when a resonant circuit is stimulated by a ping that includes several cycles of a signal that oscillates at or near the nominal resonant frequency of the resonant circuit.

FIG. 14 illustrates an example of frequency response obtained when a resonant circuit is stimulated by a ping that includes a burst of a stimulation signal that oscillates at a frequency that is greater than the nominal resonant frequency of the resonant circuit.

FIG. 15 illustrates a circuit that can measure response of a resonant circuit in a passive ping procedure.

FIG. 16 illustrates examples of processing circuits in a power receiving device that may be configured to encode information in an ASK-modulated signal.

FIG. 17 illustrates examples of encoding schemes that may be adapted to digitally encode messages exchanged between power receivers and power transmitters.

FIG. 18 is a flowchart that illustrates a power transfer management procedure that may be employed by a wireless charging device implemented in accordance with certain aspects disclosed herein.

FIG. 19 illustrates an example of a PCB manufactured in accordance with certain aspects disclosed herein.

FIG. 20 illustrates an example of a modular or physically distributed charging surface that have charging cell of different sizes in accordance with certain aspects disclosed herein.

FIG. 21 illustrates an example of a charging system that includes multiple charging devices provided in accordance with certain aspects of this disclosure.

FIG. 22 illustrates a first example of a combined control circuit in a modular charging surface provided in accordance with certain aspects disclosed herein.

FIG. 23 illustrates a second example of a combined control circuit that may be provided in a modular charging surface provided according to certain aspects disclosed herein.

FIG. 24 illustrates the use of modular charging devices to provide one or more charging surfaces on an item of furniture in accordance with certain aspects of this disclosure.

FIG. 25 illustrates a configuration of charging areas on a surface configured in accordance with certain aspects of this disclosure.

FIG. 26 illustrates an example of a countertop in which a cavity, hollow or pocket is provided near an upper surface of the countertop.

FIG. 27 illustrates an example of a structural brace that may be configured in accordance with certain aspects of this disclosure.

FIG. 28 illustrates an example of a mounting bracket that may be configured in accordance with certain aspects of this disclosure.

FIG. 29 illustrates an example of a charging system that includes fixed and relocatable charging coils configured in accordance with certain aspects of this disclosure.

FIG. 30 illustrates a first example of a movable charging coil subsystem in accordance with certain aspects of this disclosure.

FIG. 31 shows an example of the topside of a printed circuit board that provides fixed charging coils configured in accordance with certain aspects of this disclosure.

FIG. 32 illustrates a second example of a movable charging coil subsystem in accordance with certain aspects of this disclosure.

FIG. 33 is flowchart illustrating an example of a method for mounting a charging device to a countertop in accordance with certain aspects disclosed herein.

FIG. 34 illustrates one example of an apparatus employing a processing circuit that may be adapted according to certain aspects disclosed herein.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of wireless charging systems will now be presented with reference to various apparatus and methods. These apparatus and methods will be described in the following detailed description and illustrated in the accompanying drawing by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented with a “processing system” that includes one or more processors. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a processor-readable storage medium. A processor-readable storage medium, which may also be referred to herein as a computer-readable medium may include, by way of example, a magnetic storage device (e.g., hard disk, floppy disk, magnetic strip), an optical disk (e.g., compact disk (CD), digital versatile disk (DVD)), a smart card, a flash memory device (e.g., card, stick, key drive), Near Field Communications (NFC) token, random access memory (RAM), read only memory (ROM), programmable ROM (PROM), erasable PROM (EPROM), electrically erasable PROM (EEPROM), a register, a removable disk, a carrier wave, a transmission line, and any other suitable medium for storing or transmitting software. The computer-readable medium may be resident in the processing system, external to the processing system, or distributed across multiple entities including the processing system. Computer-readable medium may be embodied in a computer-program product. By way of example, a computer-program product may include a computer-readable medium in packaging materials. Those skilled in the art will recognize how best to implement the described functionality presented throughout this disclosure depending on the particular application and the overall design constraints imposed on the overall system.

Certain aspects of the present disclosure relate to systems, apparatus and methods associated with wireless charging devices that provide a free-positioning charging surface using multiple transmitting coils or that can concurrently charge multiple receiving devices. In one aspect, a controller in the wireless charging device can locate a device to be charged and can configure one or more transmitting coils optimally positioned to deliver power to the receiving device. Charging cells may be provisioned or configured with one or more inductive transmitting coils and multiple charging cells may be arranged or configured to provide the charging surface. The location of a device to be charged may be detected through sensing techniques that associate location of the device to changes in a physical characteristic centered at a known location on the charging surface. In some examples, sensing of location may be implemented using capacitive, resistive, inductive, touch, pressure, load, strain, and/or another appropriate type of sensing.

Conventional wireless charging systems typically use a “Ping” to determine if a receiving device is present on or proximate to a transmitting coil in a base station for wireless charging. The transmitter coil has an inductance (L) and, a resonant capacitor that has a capacitance (C) is coupled to the transmitting coil to obtain a resonant LC circuit. A Ping is produced by delivering power to the resonant LC circuit. Power is applied for a duration of time (90 ms in one example) while the transmitter listens for a response from a receiving device. The response may be provided in a signal encoded using Amplitude Shift Key (ASK) modulation. This conventional Ping-based approach can be slow due to the 90 ms duration, and can dissipate large and significant amounts of energy, which may amount to 80 mJ per Ping. In one example, a typical transmitting base station may ping as fast as 12.5 times a second (period= 1/80 ms) with a power consumption of (80 mJ*12.5) per second=1 W. In practice most, designs trade off responsiveness for a lower quiescent power draw by lowering the ping rate. As an example, a transmitter may ping 5 times a second with a resultant power draw of 400 mW.

Certain aspects of the present disclosure relate to systems, apparatus and methods that enable fast, low-power detection of objects placed in proximity to a charging surface. In one example, an object may be detected when a pulse provided to a charging circuit stimulates an oscillation in the charging circuit, or in some portion thereof. A frequency of oscillation of the charging circuit responsive to the pulse or a rate of decay of the oscillation of the charging circuit may be indicative or determinative of presence of a chargeable device has been placed in proximity to a coil of the charging circuit. Identification of a type or nature of the object may be made based on changes in a characteristic of the charging circuit. The pulse provided to the charging circuit may have a duration that is less than half the period of a nominal resonant frequency of the charging circuit.

Certain aspects disclosed herein relate to improved wireless charging systems. Systems, apparatus and methods are disclosed that accommodate free placement of chargeable devices on one or more surfaces provided by a charging system constructed from modular surface elements. In one example, a single surface provided by the charging system is formed from a configuration of multiple modular multi-coil wireless charging elements. In another example, a distributed charging surface may be provided by the charging system using multiple interconnected multi-coil wireless charging elements.

Certain aspects can improve the efficiency and capacity of a wireless power transmission to a receiving device. In one example, a wireless charging device has a battery charging power source, a plurality of charging cells configured in a matrix, a first plurality of switches in which each switch is configured to couple a row of coils in the matrix to a first terminal of the battery charging power source, and a second plurality of switches in which each switch is configured to couple a column of coils in the matrix to a second terminal of the battery charging power source. Each charging cell in the plurality of charging cells may include one or more coils surrounding a power transfer area. The plurality of charging cells may be arranged adjacent to a charging surface without overlap of power transfer areas of the charging cells in the plurality of charging cells.

Certain aspects of the present disclosure relate to systems, apparatus and methods for a wireless charging system that provide multiple power transmitting coils in elements of a modular or distributed surface. The coils may be stacked and can be used to charge target devices presented to the wireless charging systems without a requirement to match a particular geometry or location within a charging surface of the charging device. Each coil may have a shape that is substantially polygonal. In one example, each coil may have a hexagonal shape. Each coil may be implemented using wires, printed circuit board traces and/or other connectors that are provided in a spiral. Each coil may span two or more layers separated by an insulator or substrate such that coils in different layers are centered around a common axis.

According to certain aspects disclosed herein, devices placed on a charging surface provided by the wireless charging system may receive power that is wirelessly transmitted through one or more of the charging cells that are associated with the charging surface. Power can be wirelessly transferred to a receiving device located anywhere on the charging surface. The receiving device can have an arbitrarily defined size and/or shape and may be placed without regard to any discrete placement locations enabled for charging. Multiple devices can be simultaneously or concurrently charged on a single surface. The apparatus can track motion of one or more devices across the surface. A charging system may provide multiple charging surface portions that are physically separated from one another but managed as a single modular charging surface that can manage and control simultaneously charging of multiple devices. The charging system may be manufactured using printed circuit board technology, at low cost and/or with a compact design.

Certain aspects of this disclosure relate to systems and methods implemented using low power radio frequency (RF) communication. For example, near-field communication (NFC) standards or protocols can be used to operate low-power wireless tags using a small amount of energy incident in a radio frequency (RF) field. In one example, the wireless tag may operate in accordance with a radio-frequency identification (RFID) protocol. The energy used to operate the wireless tag may be extracted from an interrogation signal transmitted by an interrogating device, RFID reader or other device. In one aspect of this disclosure, the mobile device may be configured to operate as an interrogating device. Certain devices constructed according to certain aspects of the presently described invention can be incorporated in, or controlled by wireless charging devices.

Another aspect of the present disclosure relates to systems, apparatus and methods related to a charging device has a first plurality of transmitting coils arranged in a pattern on a first printed circuit board, the first plurality of transmitting coils defining a first charging surface, a second plurality of transmitting coils arranged in the pattern on a second printed circuit board, the second plurality of transmitting coils defining a second charging surface, a fastening device configured to fasten the first printed circuit board in alignment with the second printed circuit board such that the pattern is continued from the first charging surface into the second charging surface, an electrical interconnect configured to conduct a charging current from the first charging surface into the second charging surface, and a processor configured to select one or more transmitting coils to receive the charging current. Each of the one or more transmitting coils is provided in the first plurality of transmitting coils or the second plurality of transmitting coils.

Certain aspects of the present disclosure relate to systems, apparatus and methods applicable to wireless charging devices that provide a free-positioning charging surface that has multiple transmitting coils or that can concurrently charge multiple receiving devices. In one aspect, a processing circuit coupled to the free-positioning charging surface can be configured to locate a device to be charged and can select and configure one or more power transmitting coils that are optimally positioned to deliver power to the receiving device. Charging cells may be configured with one or more inductive transmitting coils and multiple charging cells may be arranged or configured to provide the charging surface. The location of a device to be charged may be detected through sensing techniques that associate location of the device to changes in a physical characteristic centered at a known location on the charging surface. In some examples, sensing of location may be implemented using capacitive, resistive, inductive, touch, pressure, load, strain, and/or another appropriate type of sensing.

According to certain aspects disclosed herein, a charging surface in a wireless charging device may be provided using charging cells that are deployed adjacent to a surface of the charging device. In one example the charging cells are deployed in accordance with a honeycomb packaging configuration. A charging cell may be implemented using one or more coils that can each induce a magnetic field along an axis that is substantially orthogonal to the charging surface. In this disclosure, a charging cell may refer to an element having one or more coils where each coil is configured to produce an electromagnetic field that is additive with respect to the fields produced by other coils in the charging cell and directed along or proximate to a common axis. In this description, a coil in a charging cell may be referred to as a charging coil or a transmitting coil.

In some examples, a charging cell includes coils that are stacked along a common axis. One or more coils may overlap such that they contribute to an induced magnetic field substantially orthogonal to the charging surface. In some examples, a charging cell includes coils that are arranged within a defined portion of the charging surface and that contribute to an induced magnetic field within the defined portion of the charging surface, the magnetic field contributing to a magnetic flux flowing substantially orthogonal to the charging surface. In some implementations, charging cells may be configurable by providing an activating current to coils that are included in a dynamically-defined charging cell. For example, a wireless charging device may include multiple stacks of coils deployed across a charging surface, and the wireless charging device may detect the location of a device to be charged and may select some combination of stacks of coils to provide a charging cell adjacent to the device to be charged. In some instances, a charging cell may include, or be characterized as a single coil. However, it should be appreciated that a charging cell may include multiple stacked coils and/or multiple adjacent coils or stacks of coils.

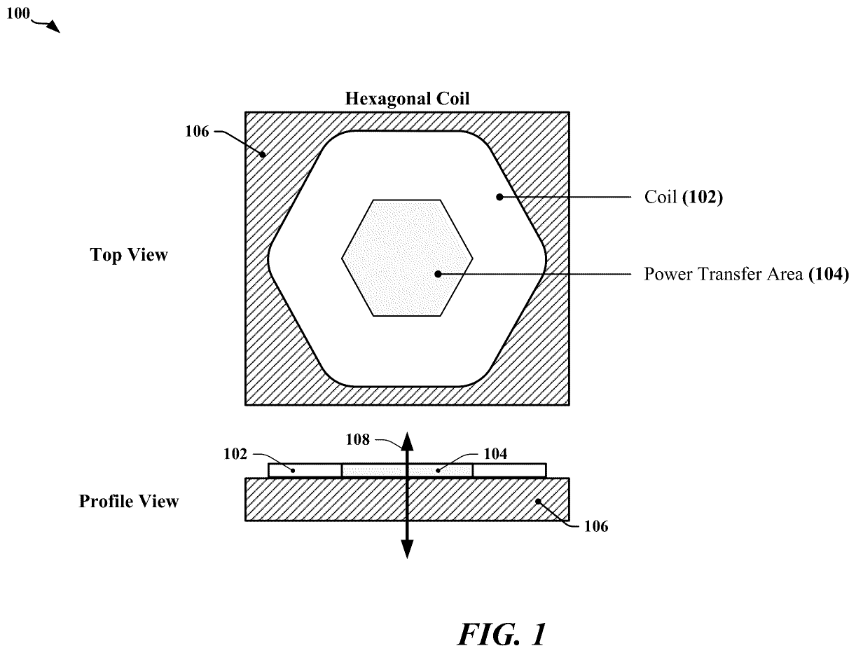

FIG. 1 illustrates an example of a charging cell 100 that may be deployed and/or configured to provide a charging surface in a wireless charging device. In this example, the charging cell 100 has a substantially hexagonal shape that encloses one or more coils 102 constructed using conductors, wires or circuit board traces that can receive a current sufficient to produce an electromagnetic field in a power transfer area 104. In various implementations, some coils 102 may have a shape that is substantially polygonal, including the hexagonal charging cell 100 illustrated in FIG. 1. Other implementations may include or use coils 102 that have other shapes. The shape of the coils 102 may be determined at least in part by the capabilities or limitations of fabrication technology or to optimize layout of the charging cells on a substrate 106 such as a printed circuit board substrate. Each coil 102 may be implemented using wires, printed circuit board traces and/or other connectors in a spiral configuration. Each charging cell 100 may span two or more layers separated by an insulator or substrate 106 such that coils 102 in different layers are centered around a common axis 108.

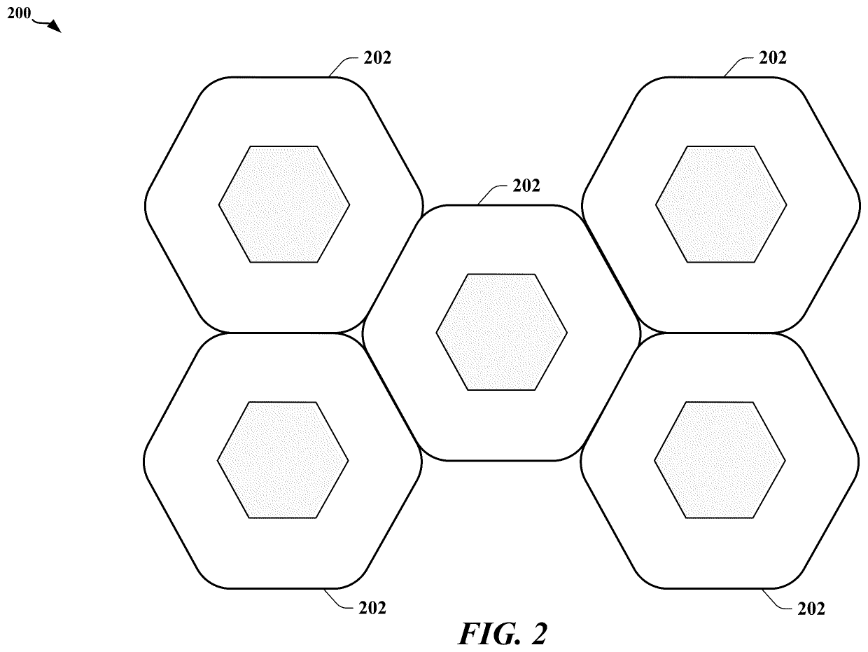

FIG. 2 illustrates an example of an arrangement 200 of charging cells 202 provided on a single layer of a segment or portion of a charging surface that may be adapted in accordance with certain aspects disclosed herein. The charging cells 202 are arranged according to a honeycomb packaging configuration. In this example, the charging cells 202 are arranged end-to-end without overlap. This arrangement can be provided without through-holes or wire interconnects. Other arrangements are possible, including arrangements in which some portion of the charging cells 202 overlap. For example, wires of two or more coils may be interleaved to some extent.

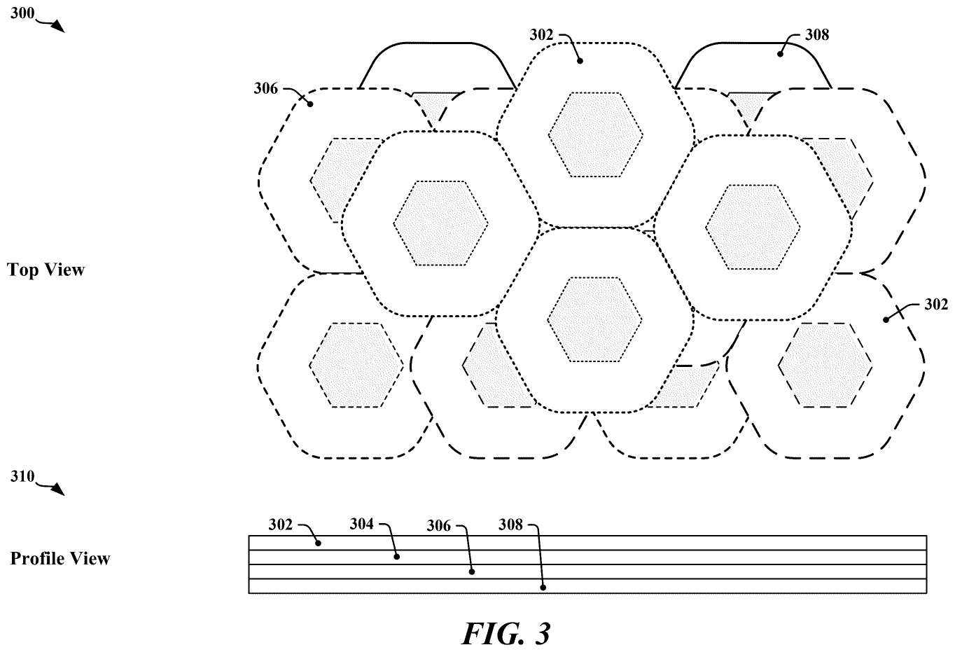

FIG. 3 illustrates an example of an arrangement of charging cells from two perspectives 300, 310 when multiple layers are overlaid within a segment or portion of a charging surface that may be adapted in accordance with certain aspects disclosed herein. Layers of charging cells 302, 304, 306, 308 are provided within the charging surface. The charging cells within each layer of charging cells 302, 304, 306, 308 are arranged according to a honeycomb packaging configuration. In one example, the layers of charging cells 302, 304, 306, 308 may be formed on a printed circuit board that has four or more layers. The arrangement of charging cells 100 can be selected to provide complete coverage of a designated charging area that is adjacent to the illustrated segment.

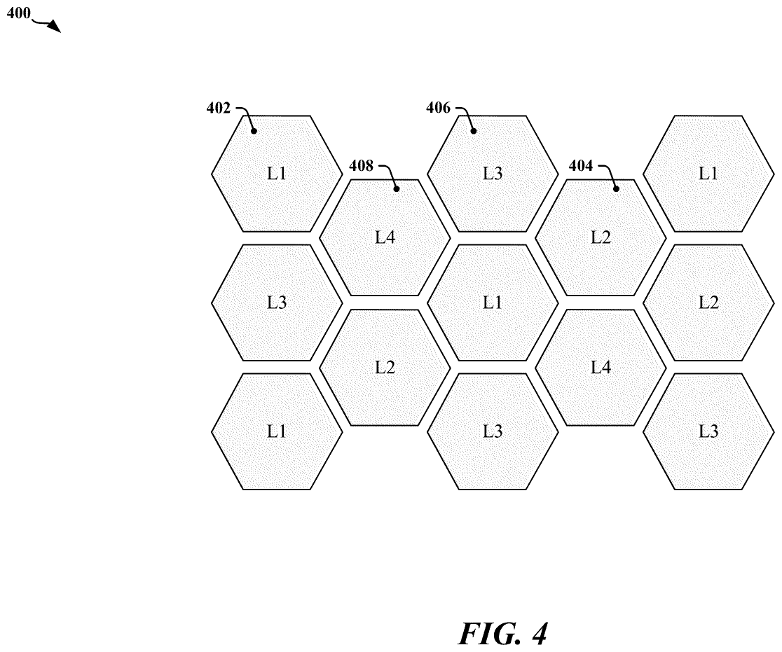

FIG. 4 illustrates the arrangement of power transfer areas provided across a charging surface 400 of a charging device that employs multiple layers of charging cells configured in accordance with certain aspects disclosed herein. The charging device may be constructed from four layers of charging cells 402, 404, 406, 408. In FIG. 4, each power transfer area provided by a charging cell in the first layer of charging cells 402 is marked “L1”, each power transfer area provided by a charging cell in the second layer of charging cells 404 is marked “L2”, each power transfer area provided by a charging cell in the third layer of charging cells 406 is marked “L3”, and each power transfer area provided by a charging cell in the fourth layer of charging cells 408 is marked “L4”.

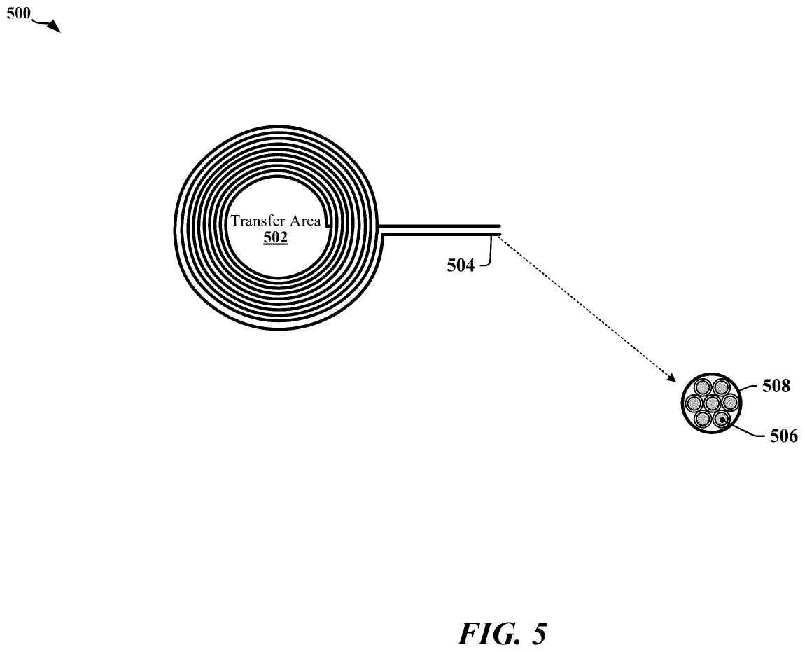

FIG. 5 illustrates an example of a transmitting coil configured in accordance with certain aspects of this disclosure. The transmitting coil may be wound from a multi-stranded Litz wire 504 and may be referred to as a Litz coil 500. Each strand 506 of the Litz wire 504 is formed as an insulated conductor that is sufficiently thin to mitigate or substantially reduce skin effect loss. Skin effect losses occur in wires carrying high frequency signals where the current tends to flow at outermost reaches (skin) of the wire. The strands 506 are insulated to maintain their individual nature and are twisted such that the relative positioning of the individual strands 506 changes over the length of the Litz wire 504. In some instances, the strands 506 are bound by an exterior insulating layer 508. The Litz coil 500 is wound as a substantially planar coil with an open interior that corresponds to the power transfer area 502.

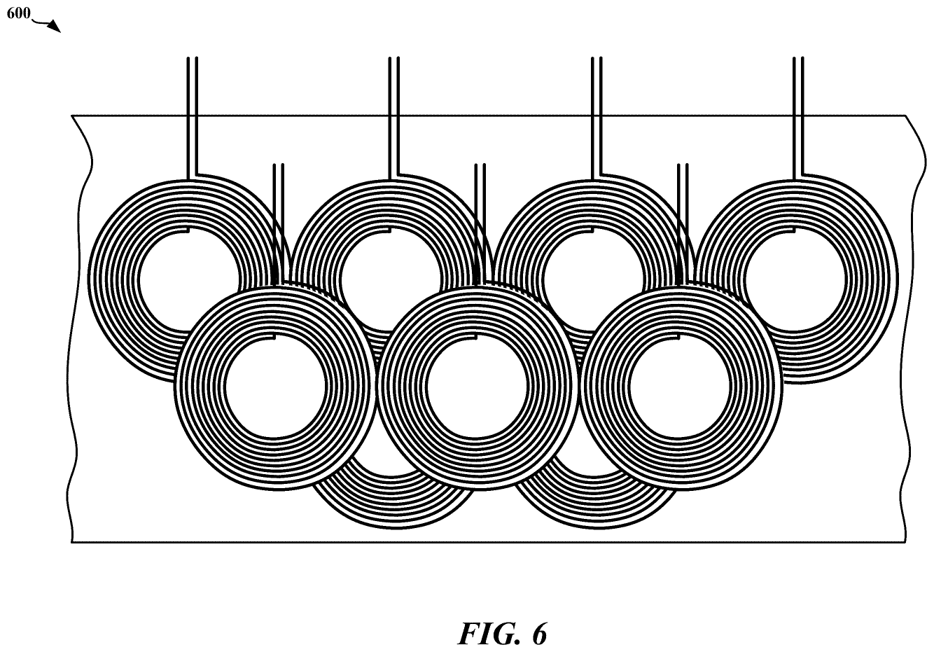

FIG. 6 illustrates an example of a portion of a charging surface 600 provided using multiple overlapping Litz coils 500. In the illustrated example, the charging surface 600 is constructed using three layers of Litz coils 500, although the number of layers of Litz coils 500 and arrangement of the Litz coils 500 in the charging surface 600 may vary according to application, size of the charging surface 600 and power transfer requirements per Litz coil 500.

The configuration of Litz coils 500 in a charging surface 600 may be precisely defined by design requirements. In some instances, it can be difficult to manage and align the number of Litz coils 500 to be assembled during manufacture of a wireless charging device that provides a free positioning charging surface using multiple transmitting coils. Variability in positioning of the Litz coils 500 during manufacture can result in imprecise configurations of coils in some finished devices. In some instances, the Litz coils 500 may be retained in position using an adhesive or epoxy resin. According to certain aspects of this disclosure, a substrate may be configured to receive the Litz coils 500 and maintain the Litz coils 500 in a desired configuration for the lifetime of the wireless charging device.

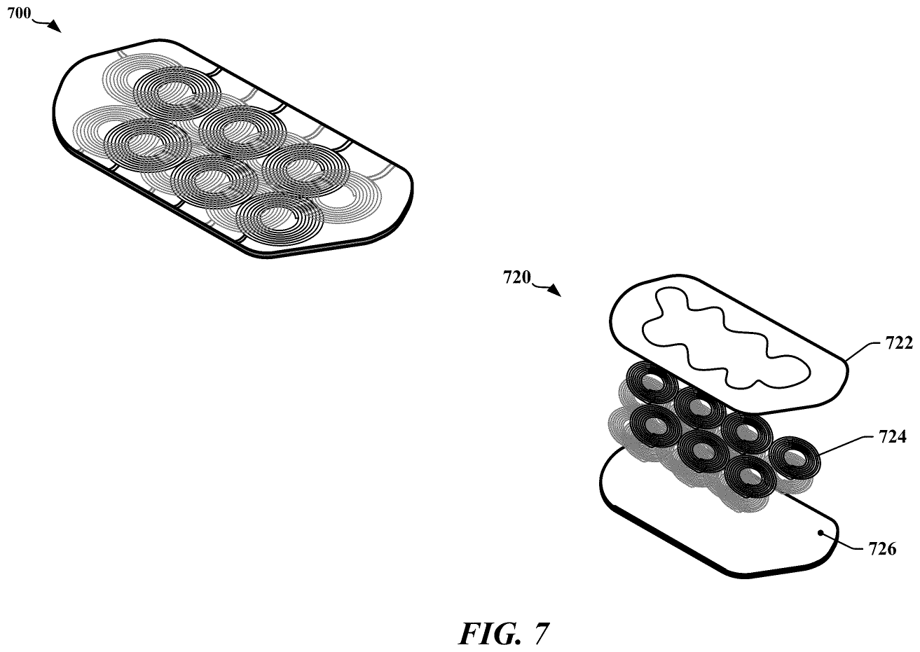

FIG. 7 illustrates a charging assembly 700 in a wireless charging device constructed from Litz coils 500 according to certain aspects of this disclosure. The exploded view 720 shows a Litz coil substrate 722 configured to receive Litz coils and maintain the Litz coils in a predefined multi-layer Litz coil structure 724 with 3D displacements between coils that meet tolerances defined by a designer. The Litz coil substrate 722 may also define the spatial relationship between the multi-layer Litz coil structure 724 and a ferrite layer 726 or another type of magnetic half-core.

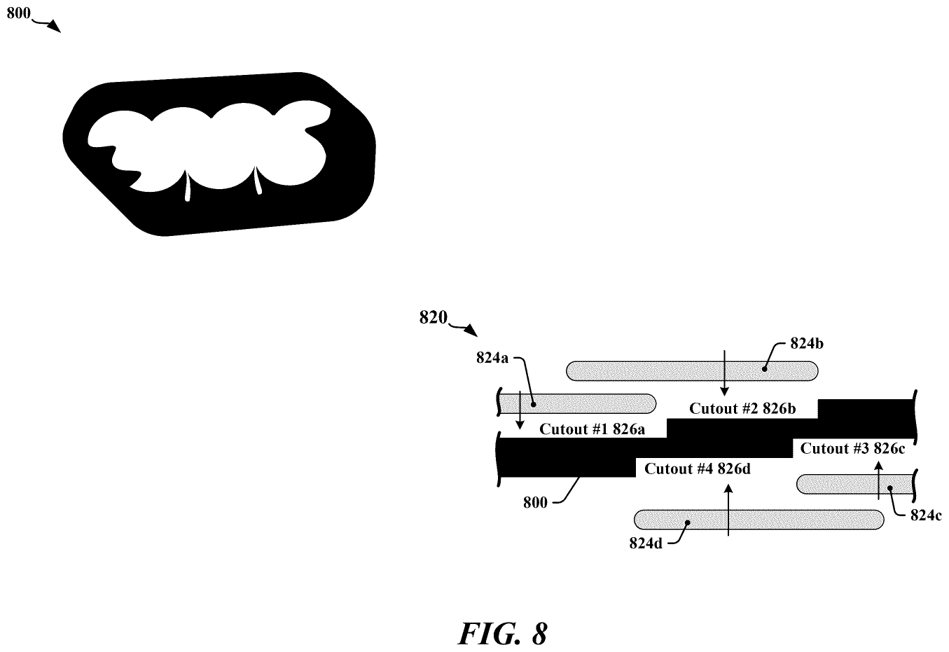

FIG. 8 illustrates certain aspects of a Litz coil substrate 800 provided in accordance with certain aspects of this disclosure. The Litz coil substrate 800 may be formed from a polymer, acetate, vinyl, nitrile rubber, latex, extruded polystyrene foam and/or other material. The Litz coil substrate 800 may have multiple cutouts that enable Litz coils 800 to be placed in position in an ordered assembly. In some examples, the cut-outs may be performed, including when the Litz coil substrate 800 is manufactured by 3D printing, molding, extrusion and/or low-pressure expansion. In some examples, the cut-outs may be formed by milling, grinding, etching, abrading, chemical erosion, chemical dissolution or by another technique suitable for use with the material used to form the Litz coil substrate 800.

Certain aspects of the Litz coil substrate 800 are illustrated in a cross-sectional view 820. The illustrated Litz coil substrate 800 provides a four-layer charging surface and the cross-sectional view 820 illustrates an example of placement and assembly of four Litz coils 824a-824d. The Litz coil substrate 800 has a deep, first cutout 826a in the Litz coil substrate 800 that receives a first Litz coil 824a. This first cutout 826a may be formed as a complete circle in some examples. In other examples, the first cutout 826a may have a portion that overlaps a portion of another cutout in the same plane of the Litz coil substrate 800.

When the first Litz coil 824a has been secured within the first cutout 826a, a second Litz coil 824b may be placed in a second cutout 826b in the Litz coil substrate 800. When in position within the Litz coil substrate 800, the second Litz coil 824b lies in a plane above the plane that includes the first Litz coil 824a. A portion of the second Litz coil 824b overlaps a portion of the first Litz coil 824a. The separation of the planes that include the horizontal center lines of the first Litz coil 824a and the second Litz coil 824b may be configured by the relative difference in depths of the first cutout 826a and the second cutout 826b.

The third Litz coil 824c is received by a deep, third cutout 826c in the Litz coil substrate 800. This third cutout 826c may be formed as a complete circle in some examples. In other examples, the third cutout 826c may overlap with another cutout in the same plane. In one example, the third cutout 826c may partially overlap the first cutout 826a resulting in a through-hole, when the bottom surface of the first Litz coil 824a is in the same plane as the top surface or some other portion of the third Litz coil 824c.

When the third Litz coil 824c has been secured within the third cutout 826c, a fourth Litz coil 824d may be placed in a fourth cutout 826d. The fourth Litz coil 824d lies in a plane below the plane that includes the third Litz coil 824c. A portion of the fourth Litz coil 824d overlaps a portion of the third Litz coil 824c when secured within the Litz coil substrate 800. The separation of the planes that include the horizontal center lines of the third Litz coil 824c and the fourth Litz coil 824d may be configured by the relative difference in depths of the third cutout 826c and the fourth cutout 826d.

A Litz coil 824a-824d may be secured within the Litz coil substrate 800 through a pressure fit, including when the Litz coil substrate 800 is manufactured from a foam material. In some examples, a Litz coil 824a-824d may be secured within the Litz coil substrate 800 by adhesive. In some examples, a Litz coil 824a-824d may be secured within the Litz coil substrate 800 by mechanical means.

In some implementations, a completed charging assembly comprising the Litz coil substrate 800 and the Litz coils 824a-824d may be attached to, or mounted on a substrate, which may be retained within a housing that can be mounted under a countertop, for example. In some implementations, the completed charging assembly comprising the Litz coil substrate 800 and the Litz coils 824a-824d may be attached to, or mounted on a printed circuit board, which may be retained within a housing.

In accordance with certain aspects disclosed herein, location sensing may rely on changes in some property of the electrical conductors that form coils in a charging cell. Measurable differences in properties of the electrical conductors may include capacitance, resistance, inductance and/or temperature. In some examples, loading of the charging surface can affect the measurable resistance of a coil located near the point of loading. In some implementations, sensors may be provided to enable location sensing through detection of changes in touch, pressure, load and/or strain. Certain aspects disclosed herein provide apparatus and methods that can sense the location of devices that may be freely placed on a charging surface using low-power differential capacitive sense techniques.

According to certain aspects of this disclosure, a search may be conducted using passive pings to identify objects that may be chargeable devices placed on or near in a multi-coil, free position charging pad. Digital pings may then be used to establish whether the object is a chargeable device that is configured to receive charge from the wireless charging device. A valid or compatible chargeable device is expected to respond to the digital ping by modulating the flux transmitted by the wireless charging device to encode information that can be detected and decoded at the transmitter. Savings in power consumption can be obtained by refraining from providing digital pings until a potential device is detected in a search, thereby limiting the number of digital ping transmissions needed to detect presence of a chargeable device and establish an electromagnetic charging connection with the detected chargeable device.

In accordance with certain aspects disclosed herein, location sensing may rely on changes in some property of the electrical conductors that form coils in a charging cell. Measurable differences in properties of the electrical conductors may include changes in capacitance, resistance, inductance and/or temperature when an object is placed in proximity to one or more coils. In some examples, placement of an object on the charging surface can affect the measurable resistance, capacitance, inductance of a coil located near the point of placement. In some implementations, circuits may be provided to measure changes in resistance, capacitance, and/or inductance of one or more coils located near the point of placement. In some implementations, sensors may be provided to enable location sensing through detection of changes in touch, pressure, load and/or strain in the charging surface. Conventional techniques used in current wireless charging applications for detecting devices employ “ping” methods that drive the transmitting coil and consume substantial power (e.g., 100-200 mW). The field generated by the transmitting coil is used to detect a receiving device.

Wireless charging devices may be adapted in accordance with certain aspects disclosed herein to support a low-power discovery technique that can replace and/or supplement conventional ping transmissions. A conventional ping is produced by driving a resonant LC circuit that includes a transmitting coil of a base station. The base station then waits for an ASK-modulated response from the receiving device. A low-power discovery technique may include utilizing a passive ping to provide fast and/or low-power discovery. According to certain aspects, a passive ping may be produced by driving a network that includes the resonant LC circuit with a fast pulse that includes a small amount of energy. The fast pulse excites the resonant LC circuit and causes the network to oscillate at its natural resonant frequency until the injected energy decays and is dissipated. In one example, the fast pulse may have a duration corresponding to a half cycle of the resonant frequency of the network and/or the resonant LC circuit. When the base station is configured for wireless transmission of power within the frequency range 100 kHz to 200 kHz, the fast pulse may have a duration that is less than 2.5 μs.

The passive ping may be characterized and/or configured based on the natural frequency at which the network including the resonant LC circuit rings, and the rate of decay of energy in the network. The ringing frequency of the network and/or resonant LC circuit may be defined as:

$$ω = \frac{1}{\sqrt{LC}} \qquad ( Eq . 1 )$$

The rate of decay is controlled by the quality factor (Q factor) of the oscillator network, as defined by:

$$Q = \frac{1}{R} \sqrt{\frac{L}{C}} \qquad ( Eq . 2 )$$

Equations 1 and 2 show that resonant frequency is affected by L and C, while the Q factor is affected by L, C and R. In a base station provided in accordance with certain aspects disclosed herein, the wireless driver has a fixed value of C determined by the selection of the resonant capacitor. The values of L and R are determined by the wireless transmitting coil and by an object or device placed adjacent to the wireless transmitting coil.

The wireless transmitting coil is configured to be magnetically coupled with a receiving coil in a device placed within close proximity of the transmitting coil, and to couple some of its energy into the proximate device to be charged. The L and R values of the transmitter circuit can be affected by the characteristics of the device to be charged, and/or other objects within close proximity of the transmitting coil. As an example, if a piece of ferrous material with a high magnetic permeability placed near the transmitter coils can increase the total inductance (L) of the transmitter coil, resulting in a lower resonant frequency, as shown by Equation 1. Some energy may be lost through heating of materials due to eddy current induction, and these losses may be characterized as an increase the value of R thereby lowering the Q factor, as shown by Equation 2.

A wireless receiver placed in close proximity to the transmitter coil can also affect the Q factor and resonant frequency. The receiver may include a tuned LC network with a high Q which can result in the transmitter coil having a lower Q factor. The resonant frequency of the transmitter coil may be reduced due to the addition of the magnetic material in the receiver, which is now part of the total magnetic system. Table 1 illustrates certain effects attributable to different types of objects placed within close proximity to the transmitter coil.

TABLE 1

| Object | L | R | Q | Frequency |
|---|---|---|---|---|
| None present | Base Value | Base value | Base Value (High) | Base Value |
| Ferrous | Small Increase | Large Increase | Large Decrease | Small Decrease |
| Non-ferrous | Small Decrease | Large Increase | Large Decrease | Small Increase |
| Wireless Receiver | Large Increase | Small Decrease | Small Decrease | Large Decrease |

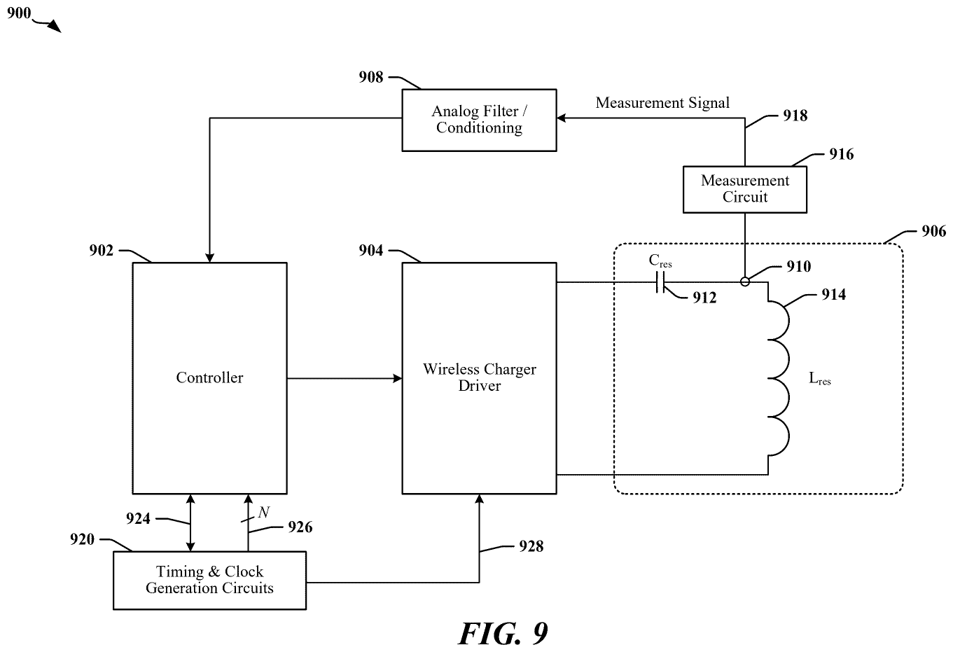

FIG. 9 illustrates a wireless transmitter 900 that may be provided in a charger base station. A controller 902 may receive a feedback signal filtered or otherwise processed by a filter circuit 908. The controller may control the operation of a driver circuit 904. The driver circuit 904 provides an alternating current to a resonant circuit 906 that includes a capacitor 912 and inductor 914. The frequency of the alternating current may be determined by a charging clock signal 928 provided by timing circuits 920. A measurement circuit 916 may generate a measurement signal 918 indicative of current flow or voltage measured at an LC node 910 of the resonant circuit 906. The measurement signal 918 may be used to calculate or estimate Q factor of the resonant circuit 906.

The timing circuits 920 may provide the controller with one or more clock signals 924, including a system clock signal that controls the operation of the controller 902. The one or more clock signals 924 may further include a clock signal used to modulate or demodulate a data signal carried on a charging current in the resonant circuit 906. The timing circuits 920 may include configurable clock generators that produce signals at frequencies defined by configuration information, including the charging clock signal 928. The timing circuits 920 may be coupled to the controller through an interface 926. The controller 902 may configure the frequency of the charging clock signal 928. In some implementations, the controller 902 may configure the duration and frequency of a pulsed signal used for passive ping in accordance with certain aspects disclosed herein. In one example, the pulsed signal includes a number of cycles of the pulsed signal.

Passive ping techniques may use the voltage and/or current measured or observed at the LC node 910 to identify the presence of a receiving coil in proximity to the charging pad of a device adapted in accordance with certain aspects disclosed herein. Many conventional wireless charger transmitters include circuits that measure voltage at the LC node 910 or measure the current in the network. These voltages and currents may be monitored for power regulation purposes and/or to support communication between devices. In the example illustrated in FIG. 9, voltage at the LC node 910 may be measured, although it is contemplated that a circuit may be adapted or provided such that current can additionally or alternatively be monitored to support passive ping. A response of the resonant circuit 906 to a passive ping (initial voltage V₀) may be represented by the voltage (V_{LC}) at the LC node 910, such that:

$${V}_{L C} = {V}_{0} {e}^{- ( \frac{ω}{2 Q} ) t} \qquad ( Eq . 3 )$$

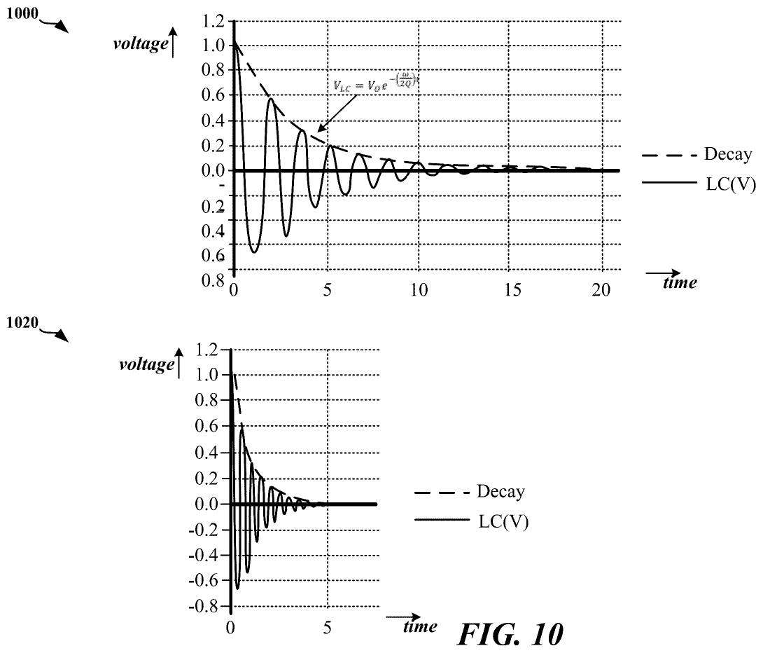

FIG. 10 illustrates examples of responses 1000, 1020 to a passive ping. In each of the responses 1000, 1020, an initial voltage decays according to Equation 3. After the excitation pulse at time=0, the voltage and/or current is seen to oscillate at the resonant frequency defined by Equation 1, and with a decay rate defined by Equation 3. The first cycle of oscillation begins at voltage level V₀ and V_{LC} continues to decay to zero as controlled by the Q factor and ω. The first response 1000 illustrates a typical open or unloaded response when no object is present or proximate to the charging pad. In this first response 1000, the value of the Q factor may be assumed to be 20. The second response 1020 illustrates a loaded response that may be observed when an object is present or proximate to the charging pad loads the coil. In the illustrated second response 1020, the Q factor may have a value of 7. V_{LC} oscillates at a higher frequency in the voltage response 1020 with respect to the voltage response 1000.

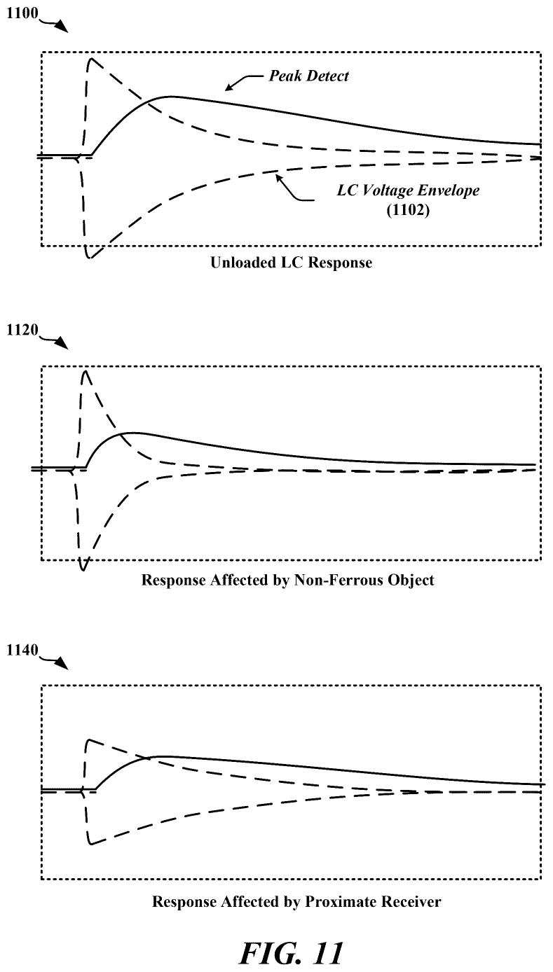

FIG. 11 illustrates a set of examples in which differences in responses 1100, 1120, 1140 may be observed. A passive ping is initiated when a driver circuit 904 excites the resonant circuit 906 using a pulse that is shorter than 2.5 μs. Different types of wireless receivers and foreign objects placed on the transmitter result in different responses observable in the voltage at the LC node 910 or current in the resonant circuit 906 of the transmitter. The differences may indicate variations in the Q factor of the resonant circuit 906 frequency of the oscillation of V₀. Table 2 illustrates certain examples of objects placed on the charging pad in relation to an open state.

TABLE 2

| | | | | | 50% Decay | Q |
|---|---|---|---|---|---|---|
| Object | Frequency | | Vₚₑₐₖ (mV) | | Cycles | Factor |
| None present | 96.98 | kHz | 134 | mV | 4.5 | 20.385 |
| Type-1 Receiver | 64.39 | kHz | 122 | mV | 3.5 | 15.855 |
| Type-2 Receiver | 78.14 | kHz | 78 | mV | 3.5 | 15.855 |
| Type-3 Receiver | 76.38 | kHz | 122 | mV | 3.2 | 14.496 |
| Misaligned | 210.40 | kHz | 110 | mV | 2.0 | 9.060 |
| Type-3 Receiver | | | | | | |
| Ferrous object | 93.80 | kHz | 110 | mV | 2.0 | 9.060 |
| Non-ferrous | 100.30 | kHz | 102 | mV | 1.5 | 6.795 |
| object | | | | | | |

In Table 2, the Q factor may be calculated as follows:

$$Q = \frac{π N}{ln ( 2 )} ≅ 4.53 N , \qquad ( Eq . 4 )$$

where N is the number of cycles from excitation until amplitude falls below 0.5 V₀.

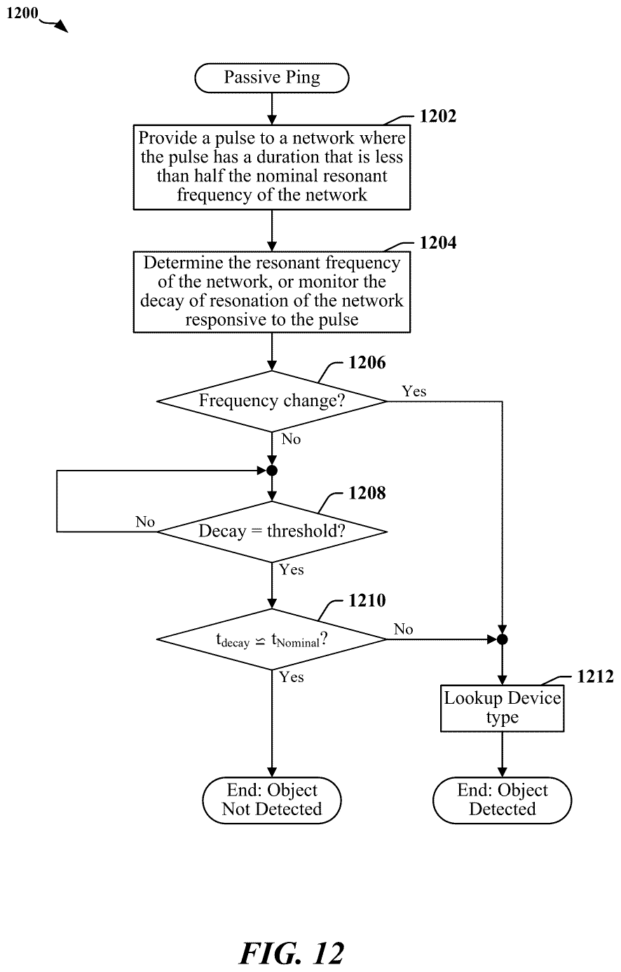

FIG. 12 is a flowchart 1200 that illustrates a method involving passive ping implemented in a wireless charging device adapted in accordance with certain aspects disclosed herein. At block 1202, a controller may generate a short excitation pulse and may provide the short excitation pulse to a network that includes a resonant circuit. The network may have a nominal resonant frequency and the short excitation pulse may have a duration that is less than half the nominal resonant frequency of the network. The nominal resonant frequency may be observed when the transmitting coil of the resonant circuit is isolated from external objects, including ferrous objects, non-ferrous objects and/or receiving coils in a device to be charged.

At block 1204, the controller may determine the resonant frequency of the network or may monitor the decay of resonation of the network responsive to the pulse. According to certain aspects disclosed herein, the resonant frequency and/or the Q factor associated with the network may be altered when a device or other object is placed in proximity to the transmitting coil. The resonant frequency may be increased or decreased from the nominal resonant frequency observed when the transmitting coil of the resonant circuit is isolated from external objects. The Q factor of the network may be increased or decreased with respect to a nominal Q factor measurable when the transmitting coil of the resonant circuit is isolated from external objects. According to certain aspects disclosed herein, the duration of delay can be indicative of the presence or type of an object placed in proximity to the transmitting coil when differences in Q factor prolong or accelerate decay of amplitude of oscillation in the resonant circuit with respect to delays associated with a nominal Q factor.

In one example, the controller may determine the resonant frequency of the network using a transition detector circuit configured to detect zero crossings of a signal representative of the voltage at the LC node 910 using a comparator or the like. In some instances, direct current (DC) components may be filtered from the signal to provide a zero crossing. In some instances, the comparator may account for a DC component using an offset to detect crossings of a common voltage level. A counter may be employed to count the detected zero crossings. In another example the controller may determine the resonant frequency of the network using a transition detector circuit configured to detect crossings through a threshold voltage by a signal representative of the voltage at the LC node 910, where the amplitude of the signal is clamped or limited within a range of voltages that can be detected and monitored by logic circuits. In this example, a counter may be employed to count transitions in the signal. The resonant frequency of the network may be measured, estimated and/or calculated using other methodologies.

In another example, a timer or counter may be employed to determine the time taken for V_{LC} to decay from voltage level V₀ to a threshold voltage level. The elapsed time may be used to represent a decay characteristic of the network. The threshold voltage level may be selected to provide sufficient granularity to enable a counter or timer to distinguish between various responses 1100, 1120, 1140 to the pulse. V_{LC} may be represented by detected or measured peak, peak-to-peak, envelope 1102 and/or rectified voltage level. The decay characteristic of the network may be measured, estimated and/or calculated using other methodologies.

If at block 1206, the controller determines that a change in resonant frequency with respect to a nominal resonant frequency indicate presence of an object in proximity to the transmitting coil, the controller may attempt to identify the object at block 1212. If the controller determines at block 1206 that resonant frequency is substantially the same as the nominal resonant frequency, the controller may consider the decay characteristic of the amplitude of oscillation in the resonant circuit at block 1208. The controller may determine that the resonant frequency of the network is substantially the same as the nominal resonant frequency when the frequency remains within a defined frequency range centered on, or including the nominal resonant frequency. In some implementations, the controller may identify objects using changes in resonant frequency and decay characteristics. In these latter implementations, the controller may continue at block 1208 regardless of resonant frequency, and may use changes in change in resonant frequency as an additional parameter when identifying an object positioned proximately the transmission coil.

At block 1208, the controller may use a timer and/or may count the cycles of the oscillation in the resonant circuit that have elapsed between the initial V_{O} amplitude and a threshold amplitude used to assess the decay characteristic. In one example, V_{O}/2 may be selected as the threshold amplitude. At block 1210, the number of cycles or the elapsed time between the initial V_{O} amplitude and the threshold amplitude may be used to characterize decay in the amplitude of oscillation in the resonant circuit, and to compare the characterize decay with a corresponding nominal decay characteristic. If at block 1210, no change in frequency and delay characteristic is detected, the controller may terminate the procedure with a determination that no object is proximately located to the transmission coil. If at block 1210, a change in frequency and/or delay characteristic has been detected, the controller may identify the object at block 1212.

At block 1212, the controller may be configured to identify receiving devices placed on a charging pad. The controller may be configured to ignore other types of objects, or receiving devices that are not optimally placed on the charging pad including, for example, receiving devices that are misaligned with the transmission coil that provides the passive ping. In some implementations, the controller may use a lookup table indexed by resonant frequency, decay time, change in resonant frequency, change in decay time and/or Q factor estimates. The lookup table may provide information identifying specific device types, and/or charging parameters to be used when charging the identified device or type of device.

Passive ping uses a very short excitation pulse that can be less than a half-cycle of the nominal resonant frequency observed at the LC node 910 in the resonant circuit 906. A conventional ping may actively drive a transmission coil for more than 16,000 cycles. The power and time consumed by a conventional ping can exceed the power and time use of a passive ping by several orders of magnitude. In one example, a passive ping consumes approximately 0.25 μJ per ping with a max ping time of around ~100 μs, while a conventional digital ping consumes approximately 80 mJ per ping with a max ping time of around 90 ms. In this example, energy dissipation may be reduced by a factor of 320,000 and the time per ping may be reduced by a factor of 900.

Detection and characterization of the decay of the voltage at the LC node 910 may require fast, sensitive and/or low-voltage circuits to accommodate the low-power nature of resonant signals at the LC node 910 when a short excitation pulse is used to produce resonant signals in the resonant circuit 906. In some instances, passive ping may be implemented using a burst of energy at the nominal resonant frequency of the resonant circuit 906. The burst of energy may have a duration of several periods of the nominal resonant frequency. This burst-mode passive ping necessarily consumes more energy per ping that passive ping that is initiated by short excitation pulses. The additional energy provides additional time to characterize resonant response.

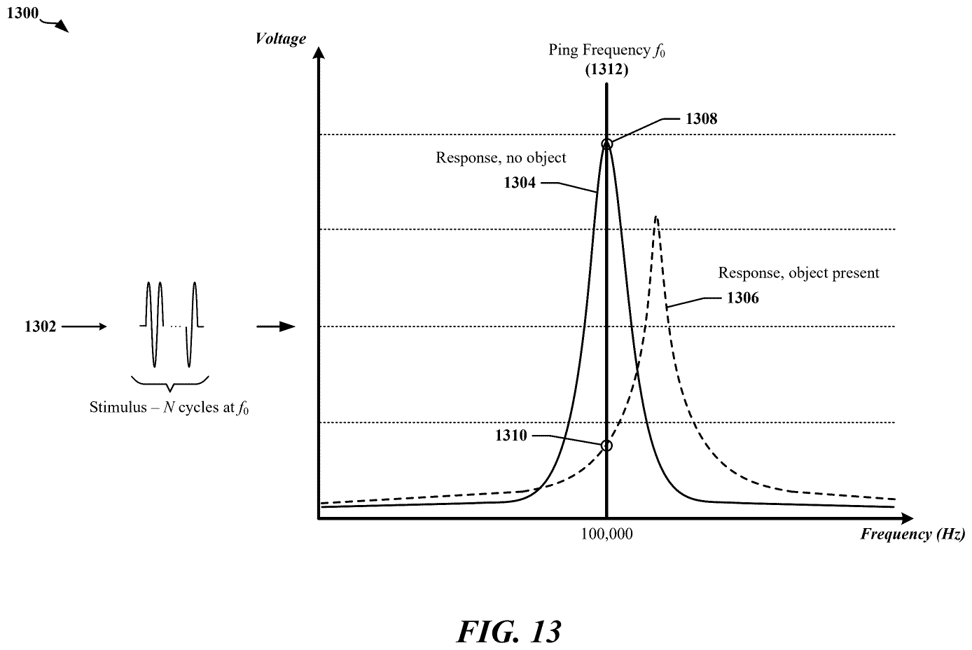

FIG. 13 illustrates an example of frequency response 1300 of the resonant circuit 906 when the resonant circuit 906 is stimulated by a ping (here, a passive ping 1302) that includes several cycles of a signal that oscillates at or near the nominal resonant frequency (f₀ 1312) of the resonant circuit 906. A first frequency response 1304 illustrates the response of the resonant circuit 906 when no device is present, while a second frequency response 1306 illustrates the response of the resonant circuit 906 when a chargeable object is present. The chargeable object reduces the Q-factor of the resonant circuit 906. The higher Q-factor of the resonant circuit 906 when no device is present causes the resonant circuit 906 to produce a significantly higher voltage response 1308 and draw the maximum current with the longest decay time in response to a passive ping 1302 at f₀ 1312 than the voltage response 1310 produced when a chargeable device lowers the Q-factor of the resonant circuit 906, causing the resonant circuit 906 to produce lower voltage, draw less current and have a shorter decay time in response to a passive ping at f₀ 1312. In typical applications, no object is present for a majority of the time a charging device is in operation, and the resonant circuit 906 in the charging device has a high Q-factor for a majority of the time. The high Q-factor results in a high power draw. The resonant circuit 906 has a slower response time when it has a high Q-factor, since more time is needed for the energy in the passive ping 1302 to decay thereby delaying initiation of another ping.

An improved passive ping technique implemented in accordance with certain aspects disclosed herein can reduce power consumption associated with passive pings 1302 and can increase the ping rate. The improved passive ping technique may use a frequency that is significantly different from the resonant frequency of the resonant circuit 906.

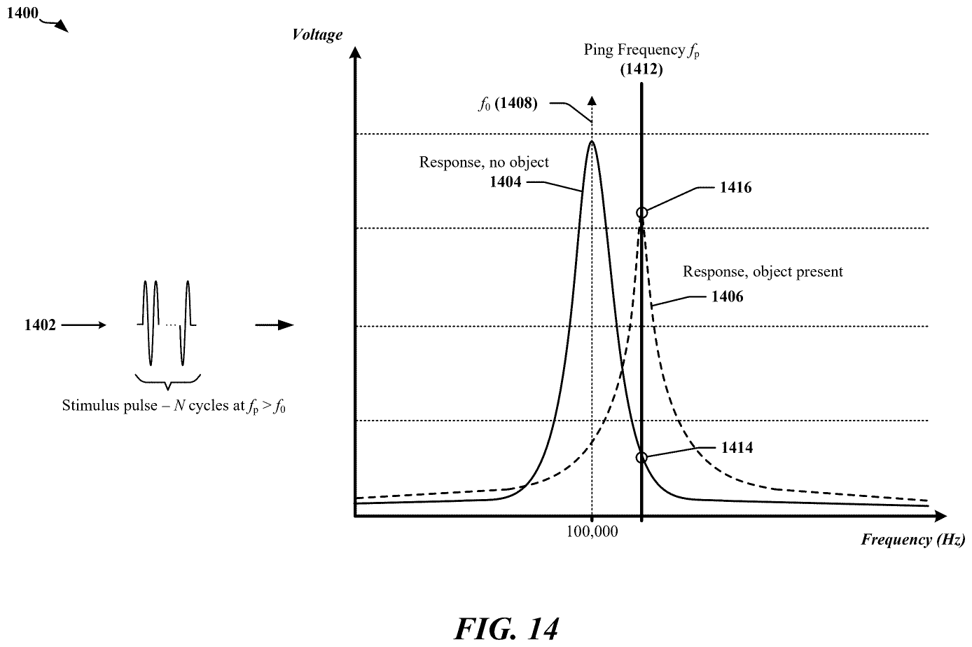

FIG. 14 illustrates an example of frequency responses 1400 of the resonant circuit 906 illustrating the effect of a ping (here, a pulse 1402) provided as burst of a stimulation signal that oscillates at a frequency (fₚ 1412) that is greater than the nominal resonant frequency (f₀ 1408) of the resonant circuit 906. The burst spans two or more cycles of the stimulation signal. In one example, the duration of the burst may be controlled by a timer. In another example, the stimulation may be modulated using a gating signal that causes the stimulation signal to be provided to the resonant circuit at a desired repetition rate and with an active duration that defines the number of cycles of the stimulation signal in the burst. In some implementations, the ping is provided as a multi-cycle burst of a stimulation signal that has a frequency that is lower than f₀ 1408.

The use of a stimulation signal that has a frequency different from the resonant frequency of the resonant circuit 906 can result in the dominant state of the charging device, where no chargeable object is present, to have a lower power draw and faster decay rate than would be expected for a stimulation signal that has a frequency at or near the resonant frequency of the resonant circuit 906. The use of a non-resonant stimulation signal can provide improved performance with respect to the example illustrated in FIG. 13. The disclosed ping technique can result in increased decay rates and can limit the occurrence of higher-power draws to pulses 1402 that lead to detection of a chargeable object. Additional pulses 1402 are typically superfluous after detection.

The resonant circuit 906 may be stimulated during a passive ping procedure by a pulsed signal that includes pulses of a duration that can include several cycles at fₚ 1412. A first frequency response 1404 illustrates the response of the resonant circuit 906 to a pulse 1402 when no device is present, while a second frequency response 1406 illustrates the response of the resonant circuit 906 to a pulse 1402 when a chargeable object is present. The effect of the chargeable object on the resonant circuit 906 may be exhibited in a reduction in the Q-factor of the resonant circuit 906. The resonant circuit 906 produces a significantly lower voltage level 1414 and draws a lower current with a shorter decay time in response to a ping at fₚ 1412 when no device is present than the voltage level 1416 produced when a chargeable device is present. In typical applications, no object is present for a majority of the time a charging device is in operation, and the resonant circuit 906 exhibits a lower power consumption and a faster decay time per ping with respect to the example illustrated in FIG. 13.

The frequency spread (fₚ−f₀ or f₀−fₚ) between the resonant frequency (f₀ 1408) and the ping frequency (fₚ 1412) may be proportionate to the value of f₀ 1408. For example, the frequency spread may increase as f₀ 1408 increases. In some implementations, the frequency spread and f₀ 1408a have a logarithmic (log base 10) relationship. In an example that is compliant or compatible with Qi standards, where 80 Khz<f₀<110 Khz, a passive ping frequency may be defined such that 175 KHz<fₚ<210 KHz.

According to certain aspects disclosed herein, frequency spread may be selected as a trade-off between signal-to-noise ratio (SNR) and power consumption or response time. In the example illustrated in FIG. 14, an overly high value for frequency spread may result in lower SNR, while an overly high value for frequency spread may result in high power draw and/or slow response. The optimal balance between SNR and power draw may vary by application. In some implementations, the lowest power and fast scan rate is obtained by setting fₚ 1412 as high as possible while permitting reliable detection of objects given SNR for the system.

The duration of a pulse 1402 can be defined as a number of fractions of a cycle of fₚ 1412. In one example, the duration of the passive ping pulse may be set to a half-cycle of fₚ 1412. In another example, the duration of the passive ping pulse may be set to multiple cycles of fₚ 1412. In some implementations, the duration of the passive ping pulse includes enough half-cycles of fₚ 1412 to obtain a current draw in the detectable range of an analog-to-digital converter (ADC) in microprocessor of a charging device. The passive ping pulse may include additional cycles to accommodate the SNR margin. The number of additional cycles may be the subject of a trade-off to increase the SNR, while limiting power and ping time. In one example, where fₚ=190 KHz and f₀=100 KHz, the duration of the passive ping pulse is less than 100 μS.

The repetition rate for pulses 1402 in a pulsed stimulus signal can be determined dynamically when speed of detection is prioritized. In one example, the ADC can be checked to determine when current has fallen back to zero before launching the next pulse 1402. In this manner, a detection circuit can determine that no energy remains in the resonant circuit 906 from the pulse 1402 before initiating the next pulse 1402. In some implementations, a fixed delay between pulses 1402 may be implemented. In one example, the fixed delay may be configured to be 6 times the longest decay time constant expected or observed in the resonant circuit 906. In one example, the fixed delay may be configured to provide a one millisecond interval between pulses. The one millisecond ping interval may enable an 18-coil charging pad to be scanned in 18 mS, permitting sub-second device detection. The fixed time approach can be used if further optimization for speed is not necessary. For example, a dynamic ping interval may be used when larger numbers of charging coils are provided in a charging pad.

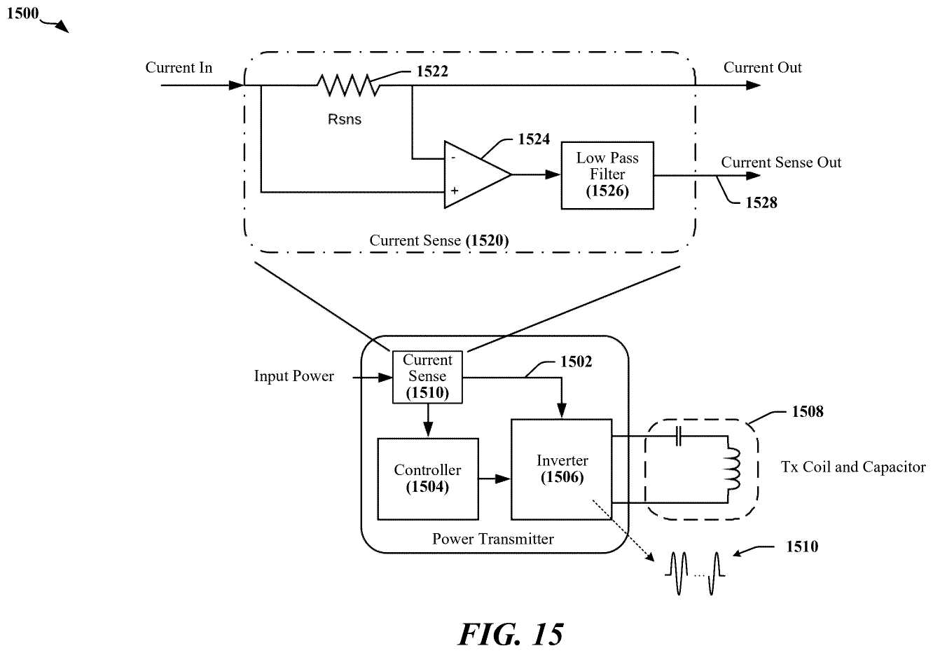

FIG. 15 illustrates a circuit 1500 that may be used to measure response of a resonant circuit in a passive ping procedure. In the illustrated example, the circuit 1500 monitors the power 1502 supplied to an inverter 1506 that produces the pulse 1510. The power 1502 may be measured as current flow to the resonant circuit 1508. In some implementations, power 1502 may be measured as a voltage across the resonant circuit 1508. In the illustrated example, a current sensing circuit 1520 provides measurements to a controller 1504 that configures, initiates and/or triggers pulses 1510 provided to the resonant circuit 1508. In one example, the current sensing circuit 1520 uses a comparator 1524 to measure the voltage across a low-value resistor 1522 in the power supply coupling to the inverter 1506. A low-pass filter 1526 may be used to provide an average or root-mean square value as the output 1528 of the current sensing circuit 1520.

Passive ping procedures may also be coupled with another, reduced-power sensing methodology, such as capacitive sensing. Capacitive sensing or the like can provide an ultra-low power detection method that determines presence or non-presence of an object is in proximity to the charging surface. After capacitive sense detection, a passive ping can be transmitted sequentially or concurrently on each coil to produce a more accurate map of where a potential receiving device and/or object is located. After a passive ping procedure has been conducted, a digital ping may be provided in the most likely device locations.

Certain aspects of the disclosure relate to the use of active pings to exchange and establish information related to device configuration, control, status and other attributes and parameters that may determine certain aspects of power transmission between a power transmitter in a wireless charging device and a power receiver in a chargeable device. The configuration, control, status and other information may be communicated wirelessly before and during power transmission in messages encoded in accordance with standards-defined protocols. In one example, Qi protocols enable the power receiver to transmit requests to the power transmitter that permit the power receiver to exercise some control over the power transmitter. Qi protocols are implemented in many wireless charging devices to manage the wireless interconnection between a power transmitter to a power receiver. Qi protocols provide for the exchange of messages from power receiver to power transmitter by way of Amplitude Shift Keying (ASK) modulation that produces an ASK signal carried in the electromagnetic flux between the power transmitter and power receiver.

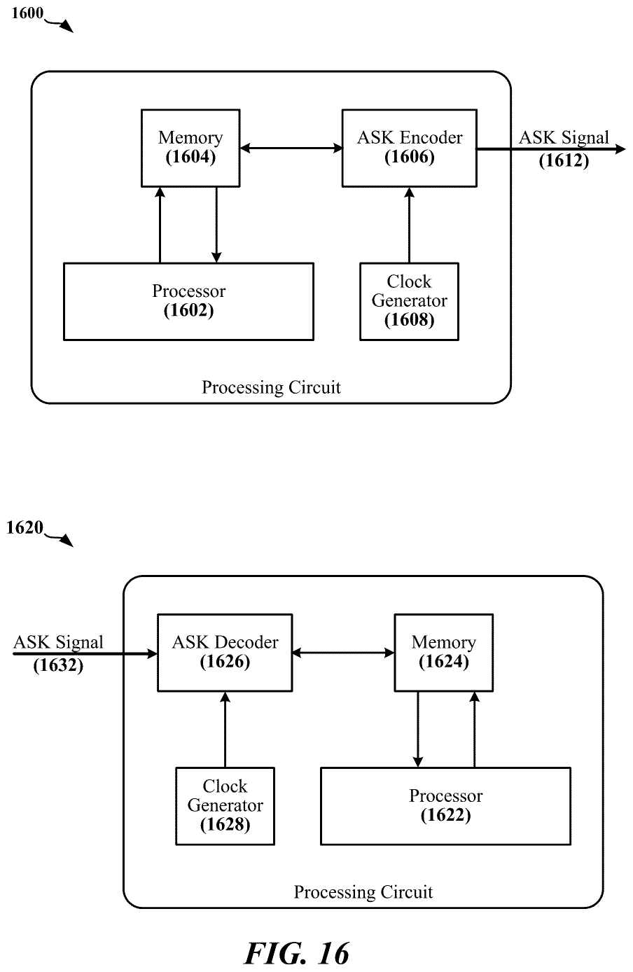

FIG. 16 illustrates an example of a processing circuit 1600 in a power receiving device that may be configured to encode information in an ASK-modulated signal 1612. The processing circuit 1600 includes a processor 1602 which may be coupled to a memory device 1604, registers or other types of storage operable to store messages to be transmitted in the ASK-modulated signal 1612. The processing circuit 1600 includes an ASK encoder 1606 that may be implemented using hardware, software or some combination of hardware and software. The ASK encoder 1606 may use a clock signal received from a clock generation or recovery circuit 1608 to control timing of transmission of the ASK-modulated signal 1612.

The processor 1602 may comprise a microprocessor, a digital signal processor (DSP), a finite state machine, a microcontroller, or another type of controller. The processor 1602 may configure and/or cause the ASK encoder 1606 to modulate voltage or current in the tank circuit of a wireless power transmitting device. In one example, the voltage or current in the tank circuit of the wireless power transmitting device may be modulated by causing step changes in the inductance of a resonant circuit in the power receiving device. The changes in the inductance modify the inductance of the tank circuit of the wireless power transmitting device through the electromagnetic coupling between transmitting and receiving devices.

FIG. 16 illustrates an example of a processing circuit 1620 that may be configured to receive and decode an ASK-modulated signal 1632. The processing circuit 1620 includes a processor 1622 which may be coupled to a memory device 1624, registers or other types of storage operable to store messages decoded from the ASK-modulated signal 1632. The processing circuit 1620 includes an ASK decoder 1626 that may be implemented using hardware, software or some combination of hardware and software. The ASK decoder 1626 may use a clock signal received from a clock generation or recovery circuit 1628 to control sampling and decoding of the ASK-modulated signal 1632.

The processor 1622 may comprise a microprocessor, a DSP, a finite state machine, a microcontroller, or another type of controller. The processor 1622 may configure or control the operation of the ASK decoder 1626. In some implementations, the ASK decoder 1626 may operate as a demodulator that provided a demodulated signal to be processed by some combination of deserializing or decoding logic and the processor 1622. With reference also to FIG. 9, the ASK-modulated signal 1632 may represent or be derived from changes in the amplitude of charging current or voltage measured at an LC node 910 of the resonant circuit 906. In many examples, interrupts can be used to determine or measure timing between level changes on the ASK-modulated signal 1632. In one example, a demodulation circuit may cooperate with a timer provided by a microcontroller (MCU) to generate interrupts used to calculate time between edges. A sequence of time measurements may be used to decode the ASK-modulated signal 1632. In another example, a DSP or digital signal controller may be used to demodulate the ASK-modulated signal using digital signal processing methods.

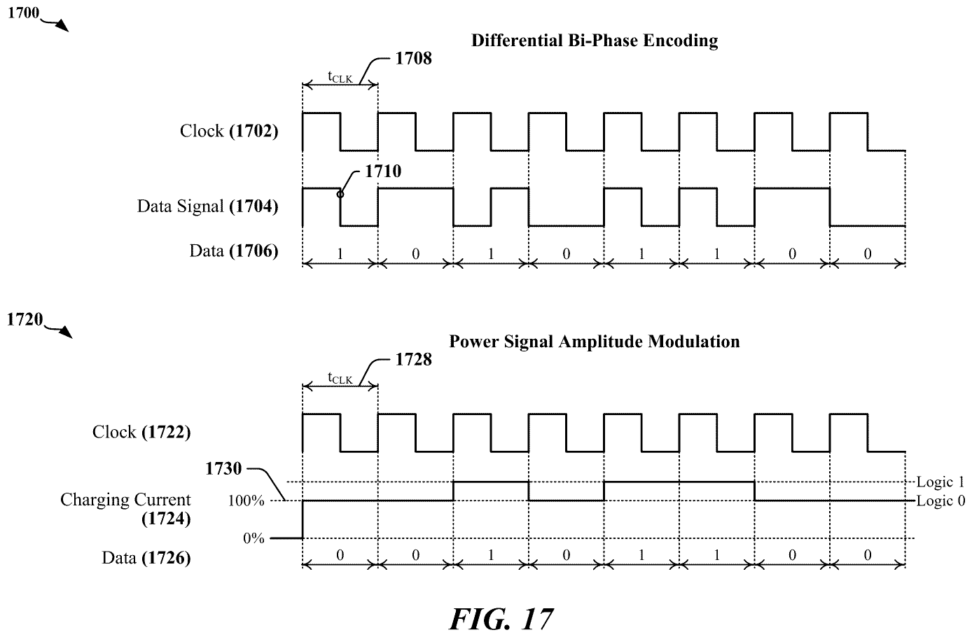

FIG. 17 illustrates examples of encoding schemes 1700, 1720 that may be adapted to digitally encode messages exchanged between power receivers and power transmitters. In the first example, a differential bi-phase encoding scheme 1700 encodes binary bits in the phase of a data signal 1704. In the illustrated example, each bit of a data byte 1706 is encoded in a corresponding cycle 1708 of an encoder clock signal 1702. The value of each bit is encoded in the presence or absence of a transition 1710 (phase change) in the data signal 1704 during the corresponding cycle 1708.

In the second example, a tank voltage or charging current 1724 is encoded using a power signal amplitude encoding scheme 1720. In the illustrated example, binary bits of a data byte 1726 are encoded in level of the charging current 1724. Each bit of the data byte 1726 is encoded in a corresponding cycle 1728 of an encoder clock signal 1722. The value of each bit is encoded in the voltage level of the charging current 1724 relative to a nominal 100% voltage level 1730 of the charging current 1724 during the corresponding cycle 1708.

ASK modulation by the receiver can be appreciated by referring again to FIG. 9. The charging current provided to the resonant circuit 906 by the driver circuit 904 in the wireless transmitter 900 of FIG. 9 causes the inductor 914 to produce an electromagnetic flux that is coupled to the receiving coil in a receiving circuit provided in the chargeable device. The chargeable device can communicate information to the base station in the wireless charging device by modulating the charging current through an LC node 910 and/or the voltage at the LC node 910. The receiving device can modulate the charging current or the voltage measured at the LC node 910 by changing the electromagnetic coupling between a transmitting coil and the receiving coil in the receiving device in accordance with a pulse-width modulated signal, for example. The inductance provided by the transmitting and receiving coils contribute to the inductance represented by the inductor 914 in the resonant circuit 906. The coupling between the transmitting and receiving coils may be changed by modifying the impedance presented by the receiving circuit in the chargeable device to the wireless transmitter 900.

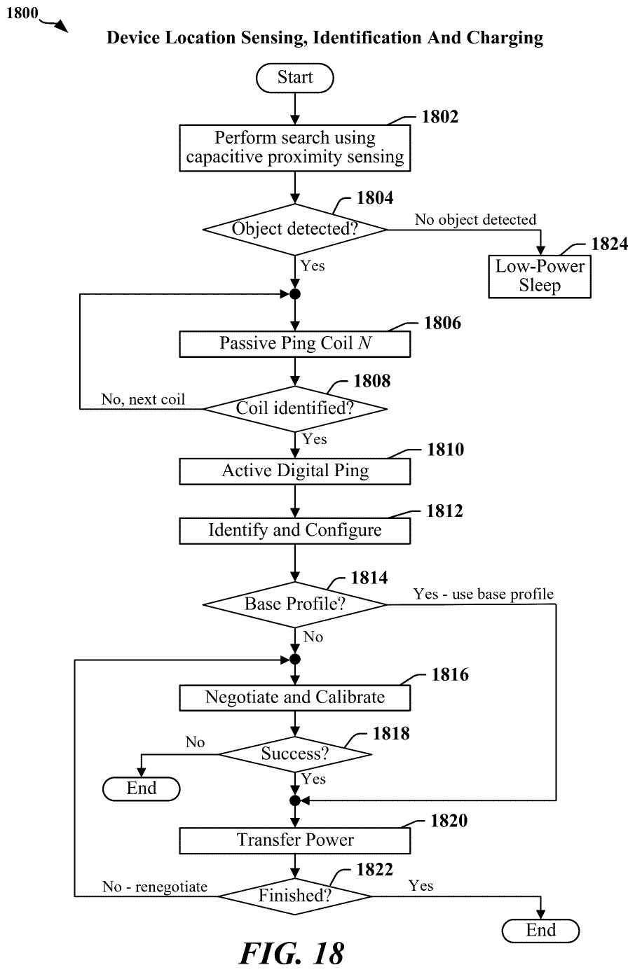

FIG. 18 is a flowchart 1800 that illustrates an example of a power transfer management procedure that includes device location sensing, identification and charging. The power transfer management procedure utilizes multiple sensing and/or interrogation techniques that may be implemented using a controller in a wireless charging device implemented in accordance with certain aspects disclosed herein. The procedure may be initiated periodically and, in some instances, may be initiated after the wireless charging device exits a low-power or sleep state. In one example, the procedure may be repeated at a frequency calculated to provide sub-second response to placement of a device on a charging pad. The procedure may be re-entered when an error condition has been detected during a first execution of the procedure, and/or after charging of a device placed on the charging pad has been completed.

At block 1802, a controller may perform an initial search using capacitive proximity sensing. Capacitive proximity sensing may be performed quickly and with low power dissipation. In one example, capacitive proximity sensing may be performed iteratively, where one or more transmission coils is tested in each iteration. The number of transmission coils tested in each iteration may be determined by the number of sensing circuits available to the controller. At block 1804, the controller may determine whether capacitive proximity sensing has detected the presence or potential presence of an object proximate to one of the transmission coils. If no object is detected by capacitive proximity sensing, the controller may cause the charging device to enter a low-power, idle and/or sleep state at block 1824. If an object has been detected, the controller may initiate passive ping sensing at block 1806.

At block 1806, the controller may initiate passive ping sensing to confirm presence of an object near one or more transmission coils, and/or to evaluate the nature of the proximately located object. Passive ping sensing may consume a similar quantity of power but span a greater of time than capacitive proximity sensing. In one example, each passive ping can be completed in approximately 100 μs and may expend 0.25 μJ. A passive ping may be provided to each transmission coil identified as being of-interest by capacitive proximity sensing. In some implementations, a passive ping may be provided to transmission coils near each transmission coil identified as being of-interest by capacitive proximity sensing, including overlaid transmission coils. At block 1808, the controller may determine whether passive ping sensing has detected the presence of a potentially chargeable device proximate to one of the transmission coils that may be a receiving device. If a potentially chargeable device has been detected, the controller may initiate active digital ping sensing at block 1810. If no potential chargeable device has been detected, passive ping sensing may continue at block 1806 until all of the coils have been tested and/or the controller terminates passive ping sensing. In one example, the controller terminates passive ping sensing after all transmitting coils have been tested. When passive ping sensing fails to find a potentially chargeable device, the controller the controller may cause the charging device to enter a low-power, idle and/or sleep state. In some implementations, passive ping sensing may be paused when a potentially chargeable device is detected so that a digital ping can be used to interrogate the potentially chargeable device. Passive ping sensing may be resumed after the results of a digital ping have been obtained.

At block 1810, the controller may use a digital ping to interrogate a potentially chargeable device. The digital ping may be provided to a transmitting coil identified by passive ping sensing. In one example, a standards-defined digital ping exchange can be completed in approximately 90 ms and may expend 80 mJ. A digital ping may be provided to each transmission coil associated with a potentially chargeable device.

At block 1812, the controller may identify and configure a chargeable device. The digital ping provided at block 1810 may be configured to stimulate a chargeable device such that it transmits a response that includes information identifying the chargeable device. In some instances, the controller may fail to identify or configure a potentially chargeable device detected by passive ping, and the controller may resume a search based on passive ping at block 1806. At block 1814, the controller may determine whether a baseline charging profile or negotiated charging profile should be used to charge an identified chargeable device. The baseline, or default charging profile may be defined by standards. In one example, the baseline profile limits charging power to 5 W. In another example, a negotiated charging profile may enable charging to proceed at up to 17 W. When a baseline charging profile is selected, the controller may begin transferring power (charging) at block 1820.

At block 1816, the controller may initiate a standards-defined negotiation and calibration process that can optimize power transfer. The controller may negotiate with the chargeable device to determine an extended power profile that is different from a power profile defined for the baseline charging profile. The controller may determine at block 1818 that the negotiation and calibration process has failed and may terminate the power transfer management procedure. When the controller determines at block 1818 that the negotiation and calibration process has succeeded, charging in accordance with the negotiate profile may commence at block 1820.

At block 1822, the controller may determine whether charging has been successfully completed. In some instances, an error may be detected when a negotiated profile is used to control power transfer. In the latter instance, the controller may attempt to renegotiate and/or reconfigure the profile at block 1816. The controller may terminate the power transfer management procedure when charging has been successfully completed.

The use of passive ping techniques disclosed herein can enable rapid, low-power detection or discovery of devices or objects that have been placed or positioned proximate to a charging surface. A charging device that employs passive ping can benefit from reduced quiescent power draw, increased detection speed, and reduced radiated EMI. A conventional system that uses passive ping detection operates by providing a stimulating pulse that is used to measure a current or voltage value or rate of decay in order to determine a characteristic of the stimulated the network. Conventional systems, for example, strive to detect changes in Q factor of a resonant circuit stimulated by the stimulating pulse. The value of the Q factor may be calculated or estimated base do a comparison of an electrical or electromagnetic signal to a threshold value.

According to certain aspects of this disclosure, a charging surface provided in wireless charging system may be implemented using a modular PCB system in which each modular PCB carries one or more charging coils arranged in substantially parallel alignment with the charging surface. According to one aspect, the charging system may include multiple modular PCBs configured to provide a large surface area on which a chargeable device can be placed for charging and which can be controlled, managed or drive by a single controlling system. In one example, the modular PCBs may be physically coupled, joined or otherwise provided in a side-by-side or end-on-end configuration to provide a combined charging surface with a desired length, breadth or surface area. In another example, two or more of the modular PCBs may be physically separated and may provide multiple charging surfaces within a room or cabin of a vehicle or in different locations of an item of furniture, such as a desk. The charging system may include modular PCBs that have the same charging coil configuration, including same size and layout of charging coils. In some examples, the charging system includes different types of modular PCBs, including modular PCBs with different layouts, differently-sized charging coils and/or different PCB size. In some examples, a modular PCB may include charging coils of different sizes. In some examples, a modular PCB may include charging coils of different shapes. In some examples, some modular PCBs may be made from a flexible PCB while other modular PCBs may be made from inflexible materials.

In some examples, a modular PCB may be manufactured on printed circuit boards that have 4 or more layers and the charging coils may include coil portions on one or more surfaces of each layer. In conventional systems, it can be advantageous to have an interconnect that passes through some layers but not all layers of the board in printed circuit board designs employing more than 2 layers. Blind vias penetrate a surface on only one side of the PCB, while buried vias connect internal layers without penetrating either surface of the PCB. The use of blind and buried vias can allow higher density packing of circuits onto a PCB. However, the use of blind and buried vias requires additional process steps in PCB production, that can increase cost and time of manufacturing substantially. According to certain aspects disclosed herein, blind and buried vias can be implemented using standard low-cost PCB manufacturing techniques using through holes/vias without increased time and/or cost associated with PCB manufacture and assembly. In some instances, multiple standard-technology, low-cost PCBs may be joined to form a laminate using an adhesive or other mechanical means to bond boards together to form a single larger multilayer board. Interconnections can be made by pressing in pins or soldering a bus connection between the boards.

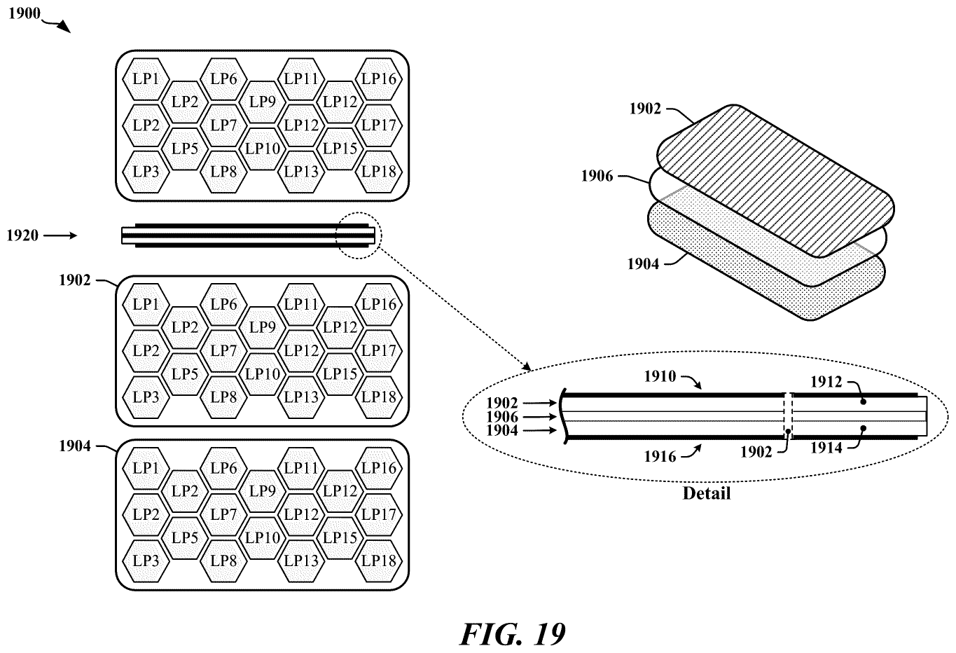

FIG. 19 illustrates a first example of a wireless charging device 1900 that provides a charging surface in accordance with certain aspects disclosed herein. A profile view of the wireless charging device 1900 is shown at 1920. In some examples, multiple copies of the same printed circuit board 1902, 1904 may be laminated to obtain a final module. In some instances, one or more printed circuit boards 1902, 1904 can be mirrored, and layered as mirrored versions to form a single assembly with one or more printed circuit boards 1902, 1904 that have not been mirrored. In the illustrated wireless charging device 1900, two 2-layer printed circuit boards 1902, 1904 of the same design are glued or otherwise joined together. In other examples, more than two printed circuit boards 1902, 1904 may be layered to form the wireless charging device 1900. The printed circuit boards 1902, 1904 may have different layers, designs, thicknesses, etc. In some examples, magnetic or shielding material may be provided within or in addition to the adhesive layer 1906 provided between printed circuit boards 1902, 1904 to facilitate on-board inductor operation, to shield circuits from EMI and/or for other purposes. Magnetic or shielding material cannot easily be inserted between printed circuit boards 1902, 1904 that form layers of the wireless charging device 1900, where the printed circuit boards 1902, 1904 are obtained using conventional manufacturing techniques.

In some examples, a charging surface may be provided using two or more printed circuit boards 1902, 1904. A first printed circuit board 1902 has a top layer 1910 and a bottom layer 1912. The top layer 1910 and the bottom layer 1912 may be metal, and/or insulated metal. The charging surface includes a second printed circuit board 1904 having a top layer 1914 and a bottom layer 1916. The top layer 1914 and the bottom layer 1916 may be metal, and/or insulated metal. The charging surface includes an adhesive layer 1906 joining the first printed circuit board 1902 and the second printed circuit board 1904 such that the bottom layer 1912 of the first printed circuit board 1902 is adjacent to the top layer 1914 of the second printed circuit board 1904. The charging surface may also include one or more interconnects provided between the bottom layer 1912 of the first printed circuit board 1902 and the top layer 1914 of the second printed circuit board 1904. In one example, at least one interconnect does not penetrate the top layer 1910 of the first printed circuit board 1902. One or more interconnects may not penetrate the bottom layer 1916 of the second printed circuit board 1904. The adhesive layer 1906 may include openings through which at least one interconnect passes between the first printed circuit board 1902 and the second printed circuit board 1904.

According to certain aspects disclosed herein, a modular charging surface may be assembled by physically joining, coupling or otherwise physically interconnecting multiple PCB modules. In some examples, the modular charging surface is assembled from multiple PCBs that have the same shape and size and that provide the same number and configuration of charging coils. In some examples, the modular charging surface is assembled from multiple PCBs that can have different shapes or sizes and/or that provide different numbers or configurations of charging coils.

Certain aspects of this disclosure apply to systems that provide a distributed charging surface that may be implemented using two or more modular charging devices to provide physically distributed charging surface portions that can be operated as a single modular charging surface. From an electrical circuit perspective, the components of the distributed charging surface may be electrically coupled or interconnected in the same manner as that the components of a single charging surface implemented using multiple modular charging devices. From a data communication perspective, the components of the distributed charging surface may be logically coupled or interconnected in the same manner as that the components of a single charging surface implemented using multiple modular charging devices. The physical and electrical characteristics of interconnects may differ between a distributed charging surface and a single charging surface implemented using multiple modular charging devices based on length and impedance of interconnects and other physical characteristics of the interconnects. For the purposes of this description the communication and power distribution architectures may be considered to be identical for a distributed charging surface and for a single charging surface implemented using multiple modular charging devices.

In one example, a primary or main controller may be provided to manage and control charging and/or device discovery procedures in a wireless charging system that includes multiple modular charging devices. In some examples, a controller provided in one of the modular charging devices may be configured to serve as the main controller. In some examples, the main controller may be attached to an edge of a charging surface or provided separately from the modular charging devices. In the latter examples, the separated main controller may enable thin charging surfaces to be attached to or embed in an object of furniture or a surface in a vehicle.

The modular charging devices may include control circuits that can be used to monitor, configure and manage charging operations through the respective charging surfaces provided by the modular charging devices. In some instances, the control circuits may include processing devices or switches that enable the control circuits in a first modular charging device to manage and control charging and/or device discovery in a second modular charging device, including where the second modular charging device is spaced apart or otherwise physically separated from the first modular charging device. The control circuits may control flow of charging currents through access to a power source or by directing the charging current to independent groupings of coils provided on multiple PCBs in interconnected charging devices. The control circuits may be configured to define physically independent charging zones that can be managed and operated as a single system. In one example, the independent charging zones may be provided on a tabletop, shelf, appliance, or other suitable carrier. In another example, the independent charging zones may be deployed in multiple locations within a confined space, such as within a cabin of a car or other vehicle or form of transportation. A modular or physically-distributed charging surface may be configured to optimize concurrent wireless charging of devices that have a variety of sizes and shapes or that have different sized receiving coils. Concurrent wireless charging of devices may be optimized when a maximum number of devices can be charged simultaneously without compromising speed of charging devices associated with high power consumption. In one example, a wireless charging system may be expected to charge a tablet computer and multiple smaller devices such as a smartwatch or mobile telephone. Optimal charging of the tablet computer may necessitate the use of a large transmitting coil, while smaller transmitting coils may facilitate stacking of physically smaller devices or devices associated with low power consumption by providing a larger number of charging cells within an area of the charging surface.

In one aspect of the disclosure, a mixture of modular or physically-distributed charging surfaces can be connected or coupled to provide different charging zones with different charging cell sizes. In another aspect of the disclosure, certain modular or physically-distributed charging surfaces can include different charging zones with different charging cell sizes. In another aspect of the disclosure, a standalone charging surface can include different charging zones with different charging cell sizes.

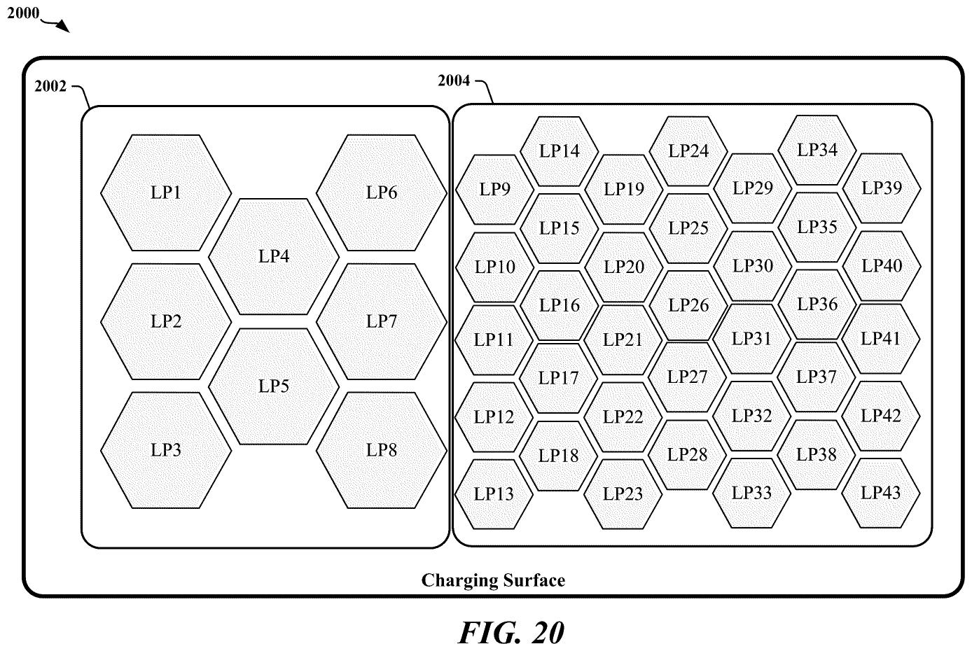

FIG. 20 illustrates an example of a modular or physically distributed charging surface 2000 that includes two charging zones 2002, 2004 that have charging cells of different sizes. The first charging zone 2002 includes larger charging cells that may be suited for high-power wireless transfers. In one example, multi-coil transmitting cells in the first charging zone 2002 may be configured to transfer power up to 30 W. The second charging zone 2004 includes smaller charging cells that may be suited for lower-power wireless transfers. In one example, transmitting cells in the second charging zone 2004 may be configured to wirelessly transfer power at 5-10 W.

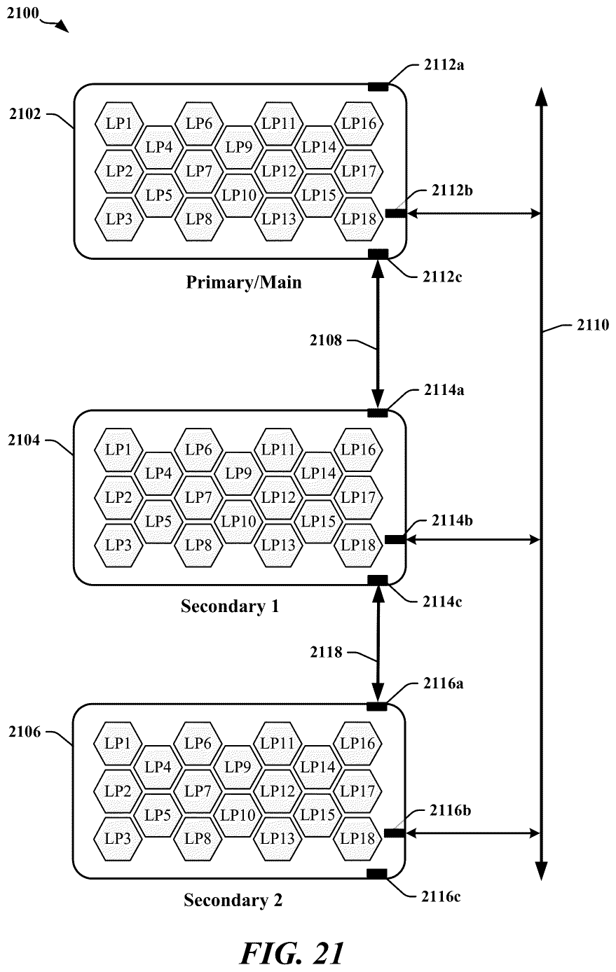

FIG. 21 illustrates an example of a charging system 2100 that includes multiple charging devices 2102, 2104, 2106 provided in accordance with certain aspects of this disclosure. In one example, the charging devices 2102, 2104, 2106 may be physically joined or interconnected to provide a single scalable, modular charging surface such as the modular charging surfaces illustrated in FIGS. 14-16. In some examples, one or more of the charging devices 2102, 2104, 2106 may be remotely located from at least one other charging device 2102, 2104, 2106 to provide a distributed charging surface. The charging system 2100 may include one or more controllers that can communicate with the charging devices 2102, 2104, 2106. In one example, a primary controller may communicate control messages to a secondary controller over a data communication link. In some examples, a primary controller may provide control signals that are used to control charging or detection operations at the charging devices 2102, 2104, 2106. In some examples, the primary controller may control power flow in the charging devices 2102, 2104, 2106. In some examples, the primary controller may provide charging currents to one or more groups of charging coils on the charging devices 2102, 2104, 2106.

Each charging device 2102, 2104, 2106 may include one or more charging cells that encompass one or more power transfer areas. Each power transfer area is substantially planar and centered around an axis that is substantially perpendicular to its a charging surface of its associated charging device 2102, 2104, 2106. In some examples, each of the charging devices 2102, 2104, 2106 can operate as a standalone wireless charger that includes controllers and power management circuits. The standalone wireless charger may be configured to detect chargeable devices, generate charging configurations and provide a charging current to one or more charging cells identified by the charging configurations.

In some examples, certain charging devices 2104, 2106 operate as secondary devices that have limited capability. In one example, the limited-capability charging devices 2104, 2106 receive charging currents through dedicated connectors and the charging currents are directed to one or more charging cells through fixed electrical paths or through a switch that may be controlled by a primary charging device 2104 or other centralized or distributed controller. In another example, the limited-capability charging devices 2104, 2106 may have a controller capable of selecting charging cells to receive a charging current and to provide the charging current to the selected charging cells. In the latter example, some limited-capability charging devices 2104, 2106 may be configured to exchange messages with one or more other charging devices 2102, 2104, 2106 in the system, or exchange messages with a chargeable device. In some instances, the limited-capability charging devices 2104, 2106 may be capable of conducting searches for chargeable devices or may be configured to participate in a search for chargeable devices controlled by a primary charging device 2104 or other centralized or distributed controller.

The charging system 2100 is constructed from interconnected charging devices 2102, 2104, 2106. The charging devices 2102, 2104, 2106 may have a same or different size or shape. The charging devices 2102, 2104, 2106 may have a same or different number or configuration of power transmitting coils. In the illustrated example, the charging devices 2102, 2104, 2106 have similar size, shape and transmitting coil configuration, although the charging devices 2102, 2104, 2106 have a same or different configuration in other implementations. The charging devices 2102, 2104, 2106 may correspond to the charging devices illustrated in FIGS. 13-22 or may provide similar configurations of charging surfaces illustrated in the charging devices of FIGS. 13-22.

In certain examples, each of the charging devices 2102, 2104, 2106 includes one or more connectors 2112a, 2112b, 2112c, 2114a 2114b, 2114c, 2116a 2116b, 2116c, which may couple the charging devices 2102, 2104, 2106 to a multi-drop serial bus 2110 or support a daisy chain connection 2108, 2118. In one example, the multi-drop serial bus 2110 is configured as a serial bus that enables the charging devices 2102, 2104, 2106 to exchange command and control messages. In one example, the serial bus is operated in accordance with Improved Inter-Integrated Circuit (13C) protocols, Controller Area Network (CAN) bus protocols, Local Interconnected Network (LIN) bus protocols, or the like. In some instances, the charging devices 2102, 2104, 2106 may communicate wirelessly. In some implementations, the daisy chain connection 2108, 2118 is used to distribute charging current among the charging devices 2102, 2104, 2106. The daisy chain connection 2108, 2118 may also be used for exchanging command and control messages.

In one example, one or more of the charging devices 2102, 2104, 2106 can serve as a primary device and may include a processing circuit configured to manage operation of one or more charging devices 2102, 2104, 2106 that is operated as a secondary device. In the illustrated example, two charging devices 2104, 2106 operate as secondary devices and may include processing circuits configured to communicate over the multi-drop serial bus 2110 in order to receive commands from the primary charging device 2102 and to report feedback information to the primary charging device 2102. Secondary charging devices 2102, 2104, 2106 may include or control a driver circuit that provides a flow of a charging current provided through the daisy chain connection 2108, 2118, when the charging current is provided by a current source through the operation of the primary charging device 2102.

The secondary charging devices 2104, 2106 may cooperate with the primary charging device 2102 to discover, enumerate and configure the combination of charging devices 2102, 2104, 2106 provided in the charging system 2100. In one example, the secondary charging devices 2104, 2106 participate in a serial bus arbitration process to identify themselves to the primary charging device 2102 and/or to obtain unique addresses. In another example, the secondary charging devices 2104, 2106 may be preconfigured with at least a secondary address that the primary charging device 2102 can use to address each secondary charging device 2104, 2106 through the multi-drop serial bus 2110. The primary charging device 2102 may use the multi-drop serial bus 2110 to configure the secondary charging devices 2104, 2106, interrogate the secondary charging devices 2104, 2106 for capability, charging cell size, number and configuration as well as status information. The primary charging device 2102 may use the multi-drop serial bus 2110 to configure the secondary charging devices 2104, 2106 for one or more charging operations.

In some implementations, each of the charging devices 2102, 2104, 2106 can be independently connected to a power supply that can be used to provide and configure a charging current. In one example, the charging devices 2102, 2104, 2106 may include an inverter or switching power supply configurable to produce an alternating current (AC) that has frequency suitable for wireless charging. In some implementations, each of the charging devices 2102, 2104, 2106 may be coupled to a multi-purpose communication bus that is used by other devices or systems (in an automobile for example). In the latter implementations, the primary charging device 2102 may also be a controlling entity on the bus.

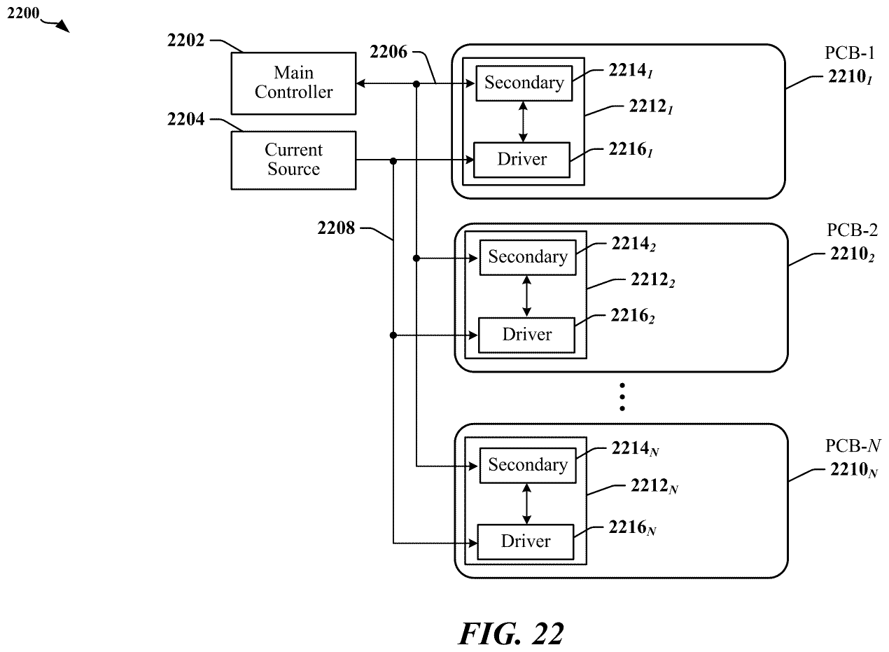

FIG. 22 illustrates a first example of a combined control circuit 2200 in a charging system provided in accordance with certain aspects disclosed herein. Each PCB 2210₁-2212_{N} includes a processing circuit 2212₁-2212_{N} that is configured and controlled by a main controller 2202 to manage operation of its respective PCB 2210₁-2212_{N}. In one example, each processing circuit 2212₁-2212_{N} includes a secondary circuit 2214₁-2214_{N} configured to communicate over a serial bus 2206 in order to receive commands and report feedback information to the main controller 2202. The secondary circuit 2214₁-2214_{N} may control a driver circuit 2216₁-2216_{N} that controls flow of a charging current provided through an interlink 2208 by a current source 2204.

The secondary circuits 2214₁-2214_{N} may cooperate with the main controller 2202 to discover, enumerate and configure the combination of PCBs 2210₁-2212_{N} provided in the modular charging surface. In one example, the secondary circuits 2214₁-2214_{N} participate in an arbitration process to identify themselves to the main controller 2202 and/or to obtain unique addresses. In another example, the secondary circuits 2214₁-2214_{N} may be preconfigured with at least a secondary address that the main controller 2202 can use to address each secondary circuit 2214₁-2214_{N} through the serial bus 2206. The main controller 2202 may use the serial bus 2206 to configure the secondary circuits 2214₁-2214_{N}, interrogate the secondary circuits 2214₁-2214_{N} for capability and status information, and configure the secondary circuits 2214₁-2214_{N} for one or more charging operations.

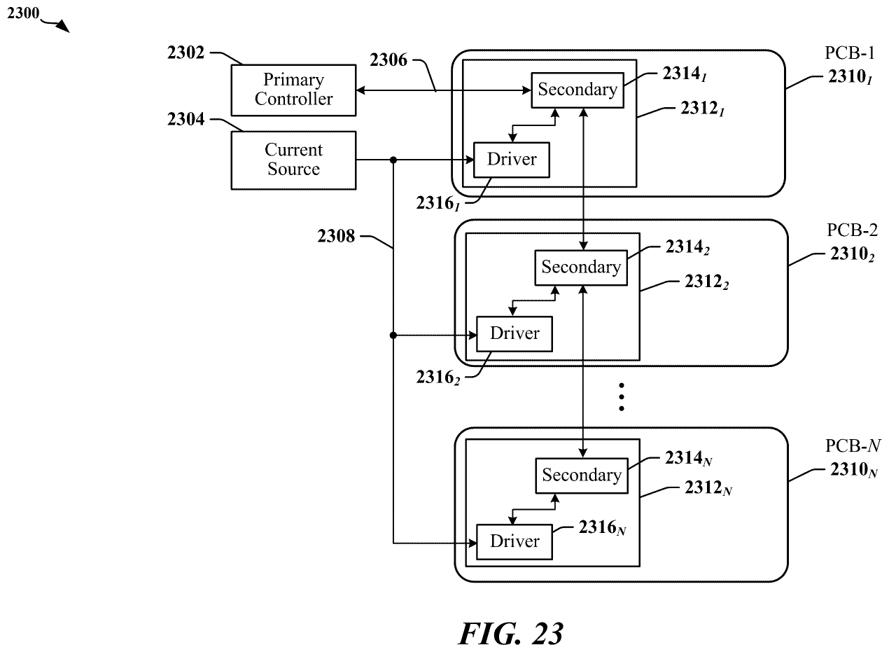

FIG. 23 illustrates a second example of a combined control circuit 2300 that may be provided in a charging system provided in accordance with certain aspects disclosed herein. Each PCB 2310₁-2312_{N} includes a processing circuit 2312₁-2312_{N} that is configured and controlled by a main controller 2302 to manage operation of its respective PCB 2310₁-2312_{N}. In one example, each processing circuit 2312₁-2312_{N} includes a secondary circuit 2314₁-2314_{N} configured to communicate over a serial bus 2306 in order to receive commands and report feedback information to the main controller 2302. The secondary circuit 2314₁-2314_{N} may control a driver circuit 2316₁-2316_{N} that controls flow of a charging current provided through an interlink 2308 by a current source.

The secondary circuits 2314₁-2314_{N} may cooperate with the main controller 2302 to discover, enumerate and configure the combination of PCBs 2310₁-2312_{N} provided in the modular charging surface. In the illustrated example, the secondary circuits 2314₁-2314_{N} are connected in a daisy chain fashion, whereby the main controller 2302 connects with and configures a first secondary circuit 2314₁, which then couples the second secondary circuit 2314₂ to the main controller 2302 through the serial bus 2306. The main controller 2302 configures the second secondary circuit 2314₂ and the process continues until the last secondary circuit 2314_{N} has been configured. In another example, the secondary circuits 2314₁-2314_{N} may be preconfigured with at least a secondary address that the main controller 2302 can use to address each secondary circuit 2314₁-2314_{N} through the serial bus 2306.

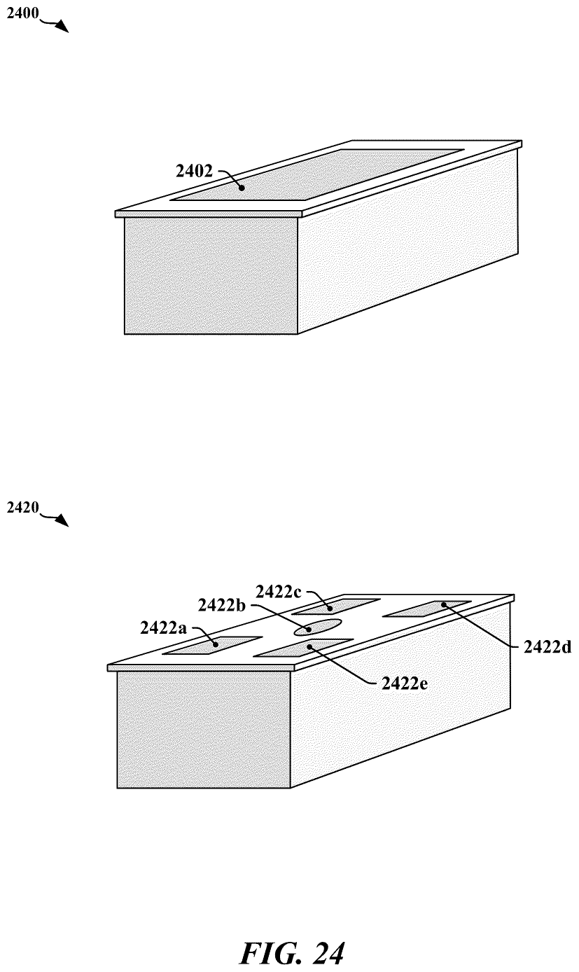

FIG. 24 illustrates the use of modular charging devices to provide one or more charging surfaces on an item of furniture in accordance with certain aspects of this disclosure. The item of furniture is selected for clarity and ease of illustration. Modular charging devices may be provided in other items including armrests of an armchair, armrests in an automobile, windowsills in a room, consoles in a vehicle, tray tables in an airplane and other examples. A first table 2400 is equipped with a large charging surface 2402 that may be assembled from numerous charging modules that are arranged and configured to provide the large charging surface 2402. A second table 2420 is equipped with a multiple charging surfaces 2422a-2422e that can have different sizes or shapes. Each of the charging surfaces 2422a-2422e may be implemented using one or more charging modules constructed in accordance with the examples illustrated in FIGS. 13-25. In some examples, at least one of the charging modules may differ from other charging modules by overall size or shape or by the number, size or configuration of included charging coils.

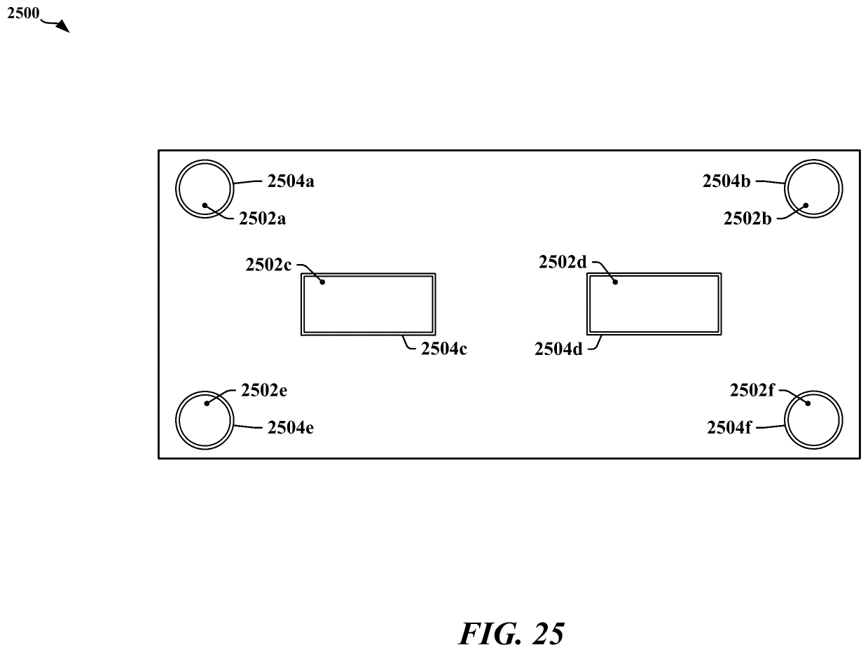

FIG. 25 illustrates an example of modular charging devices deployed on a surface 2500 of a table, desk, workbench, bar top, kitchen worksurface, or other item of furniture in accordance with certain aspects of this disclosure. The modular charging devices are deployed to provide multiple charging areas 2502a-2502f across the surface 2500 of the table, desk, workbench, bar top, kitchen worksurface, or other item of furniture, including armrests of an armchair, armrests in an automobile, windowsills in a room, consoles in a vehicle, tray tables in an airplane and other examples. Each of the charging areas 2502a-2502f may be implemented using one or more charging modules constructed in accordance with the examples illustrated in FIGS. 13-25. In some examples, at least one of the charging modules may differ from other charging modules by overall size or shape or by the number, size or configuration of included charging coils.

In the illustrated example, each of the charging areas 2502a-2502f is circumscribed by an indicator line 2504a-2504f that follows the shape of the corresponding charging area 2502a-2502f. In this example, visual indicators such as LED lamps or strips of LED lamps are used to illuminate the indicator lines 2504a-2504f. The LED lamps may be configured to emit colored light that is visible to a user during placement and/or charging of a device through the charging surface. In some examples, light from the LED lamps is carried through light pipes, light guides and/or light diffusers to an upper surface of the table, desk, workbench, bar top, kitchen worksurface, or other item of furniture. In some implementations, the light pipes, light guides or light diffusers may be used alone or in combination to provide the visible indicator line 2504a-2504f on the table, desk, workbench, bar top, kitchen worksurface, or other item of furniture. In these latter implementations, the visible indicator line 2504a-2504f may be illuminated when a chargeable device is detected nearby, or may be in an always on state. The visible indicator line 2504a-2504f may present a first color to indicate availability of charging circuits and may present a second color to indicate that the charging surface is in use. In some instances, the color of the visible indicator line 2504a-2504f may indicate whether charging is in progress or completed, or whether an error has occurred. The error may relate to misalignment of the chargeable device, presence of a foreign object, an overheating condition or the like.

The visible indicator line 2504a-2504f may be illuminated when a chargeable device is detected using capacitive sensing, passive ping, active or digital ping, detection of NFC transmissions, detection of responses to NFC transmissions, wireless identification transmissions using Bluetooth, Wi-Fi based on the IEEE 802.11 standard, Zigbee, WiMax based on the IEEE 802.16 standard, Ultra-Wide Band, wireless USB and other known technologies, or some combination of these transmissions, technologies and detections.

In some implementations, a controller in a processing circuit of a wireless charging device may implement device detection steps of the power transfer management procedure illustrated in FIG. 18. The power transfer management procedure uses multiple sensing and/or interrogation techniques and may be initiated periodically to determine whether a chargeable device is located near a charging surface controlled by the processing circuit of the wireless charging device. In some implementations, the procedure may be repeated at a frequency calculated to provide sub-second response to placement of a device on a charging pad.

In some instances, the controller in the processing circuit of the wireless charging device may perform an initial search using capacitive proximity sensing. Capacitive proximity sensing may be performed to determine whether changes in capacitance measured in one or more power transmitting coils has changed, indicating the presence or potential presence of an object proximate to one of the power transmitting coils.

In some instances, the controller in the processing circuit of the wireless charging device may employ passive ping sensing to confirm presence of an object near one or more power transmitting coils, and/or to evaluate the nature of the proximately located object. A passive ping may be provided to one or more power transmitting coils and the controller may determine that a potentially chargeable device is proximate to one of the power transmitting coils based on a change in resonance frequency that may be attributable to such potentially chargeable device.

In some instances, the controller in the processing circuit of the wireless charging device may employ active digital ping sensing. The controller may transmit the active digital ping using a burst of power transmitted through one or more power transmitting coils. A receiving device may respond by modulating the magnetic flux generated by the transmission of power.

The use of capacitive sensing, passive ping and digital ping techniques can be used to detect chargeable devices that are passed close to a charging area 2502a-2502f provided in the surface 2500 of a table, desk, workbench, bar top, kitchen worksurface, or other item of furniture. In one aspect of this disclosure, the chargeable device may be waved the across the surface 2500 in order to activate one or more charging areas 2502a-2502f that detect presence of the chargeable device. A controller may illuminate the indicator line 2504a-2504f of any charging area 2502a-2502f near to which the chargeable device has been detected. A charging area 2502a-2502f associated with an illuminated indicator line 2504a-2504f may be defined as an activated charging area.

The controller in the processing circuit of the wireless charging device may increase the frequency at which the power transfer management procedure is performed (see FIG. 18 for example) and for a period of time calculated to permit a user to place the chargeable device within the boundary of one of the illuminated indicator lines 2504a-2504f. The controller in the processing circuit of the wireless charging device may generate a charging configuration for the chargeable device and begin transmitting a charging electromagnetic flux. The LED lamps in an indicator line 2504a-2504f may be configured to emit different colored lights during detection of an approaching chargeable device or placement and/or charging of the device. The colored lights in the indicator line 2504a-2504f may be visible to a user through the charging surface and may indicate a physical location of a charging area 2502a-2502f, and/or may indicate whether the chargeable device has been detected, is optimally placed, is being charged or is fully charged.

According to certain aspects of this disclosure, other wireless technologies may be used to detect presence or proximity of a chargeable device, including when the chargeable device is being waved over the surface 2500 of a table, desk, workbench, bar top, kitchen worksurface, or other item of furniture. The approach of a chargeable device toward a charging area 2502a-2502f or movement across or near a chargeable device may generate small changes in capacitance or resonant frequency of resonant circuits and/or transmitting coils. These small changes in capacitance or resonant frequency may be ignored in conventional systems that are configured to detect chargeable devices and other objects that are placed proximate to a charging area 2502a-2502f and directly on the surface 2500 of a table, desk, workbench, bar top, kitchen worksurface, or other item of furniture. For example, a conventional system may be configured to respond to changes in capacitance or resonant frequency that exceed a threshold level. In some instances, the small changes in capacitance or resonant frequency resulting from a chargeable device that is being waved over the surface 2500 may resemble variations due to changes in temperature, voltage or changes induced by noise.

According to certain aspects of this disclosure, a waved chargeable device can be detected based on small changes or perturbations in capacitance or resonant frequency involving multiple power transmitting coils, when a geometric pattern of changes can be discerned. In one example, small changes or perturbations in capacitance or resonant frequency may be detected in a set of power transmitting coils that are centered along a line, along an arc of an ellipse, or along an arc of a curve. In some instances, a controller in the processing circuit of the wireless charging device may be able to time stamp each of a sequence of small changes or perturbations in capacitance or resonant frequency affecting the set of power transmitting coils. The time stamp may reveal an order in which the small changes or perturbations occurred.

In one aspect, the controller in the processing circuit of the wireless charging device may be configured to correlate a sequence of small changes or perturbations in capacitance or resonant frequency with an event involving a chargeable device being moved above the surface 2500 in a wiping motion. The wiping motion may cause the chargeable device to pass over or affect one or more power transmitting coils in at least one charging area 2502a-2502f. The detection of a correlated sequence of small changes or perturbations may trigger the illumination of any of the indicator lines 2504a-2504f associated with a charging area 2502a-2502f that includes transmitting coils affected by the wiping motion.

In some implementations, the surface 2500 of the table, desk, workbench, bar top, kitchen worksurface, or other item of furniture may be equipped with one or more wireless transmitters and receivers that can be used to detect doppler shifts in reflected signals transmitted by one of the wireless transmitters. In one example, the controller in the processing circuit of the wireless charging device may be coupled to a receiver may be configured to detect doppler shift in an acoustic ultrasound signal, a microwave signal or an infrared signal that indicates approach of an object toward a charging area 2502a-2502f embedded in or attached to the surface 2500. The timing and strength of the reflected signal and the frequency or phase of a signal representative of the doppler shift may indicate proximity, direction and other information related to the positioning of the object with respect to one or more of the charging areas 2502a-2502f. In some instances, information received from multiple wireless receivers may be used to triangulate the position of an object. In some examples, each of the wireless receivers is tuned to a single frequency or wireless transmitter. In some examples, triangulation can be accomplished using signals received by wireless receivers that are reflections of a signal transmitted by a single wireless transmitter. In these latter examples, information received from the wireless receivers may relate to reflected signals corresponding to a time-sequence of signals transmitted by multiple wireless transmitters.

In some implementations, the surface 2500 of the table, desk, workbench, bar top, kitchen worksurface, or other item of furniture may be equipped with one or more wireless transmitters and/or wireless receivers that can be used to detect transmissions involving an object located near a charging area 2502a-2502f that has been embedded or attached to the surface 2500. In one example, short range NFC transmissions by a chargeable device may be detected. In another example, responses to NFC interrogating signals by a chargeable device may be detected. NFC typically has a range of 4 centimeters or less, and can indicate proximity to a specific charging area 2502a-2502f embedded in or attached to the surface 2500. In some instances, the detection of an NFC transmission is sufficient to cause a controller to activate a charging area 2502a-2502f near the receiver that detects the NFC transmission without a need to decode the content of the NFC transmission. In some instances, a processing circuit may be configured to activate or refrain from activating a charging area 2502a-2502f near the receiver that detects the NFC transmission based on an identity of a specific device or types of devices that is determined based on the content of a detected NFC transmission or sequence of NFC transmissions.

In some implementations, the surface 2500 of the table, desk, workbench, bar top, kitchen worksurface, or other item of furniture may be equipped with one or more wireless transmitters and/or wireless receivers that can be used to communicate with chargeable devices or detect transmissions involving an object located near a charging area 2502a-2502f that has been embedded or attached to the surface 2500. In some implementations, a processing circuit of the wireless charging device may be coupled to one or more wireless communication receivers and may be configured to determine identity of a device or a type of device that is communicating using NFC, Bluetooth, Wi-Fi, Zigbee, WiMax, Ultra-Wide Band, wireless USB, or other protocols. Certain types of wireless communication have ranges of 100 meters or more and decoding or detection of identifying information in a wireless transmission may not indicate that a device is sufficiently close to a charging area 2502a-2502f to be a candidate for charging. In some instances, the processing circuit of the wireless charging device may be configured to determine strength of transmission or to triangulate the source of a transmission based on received wireless signals.

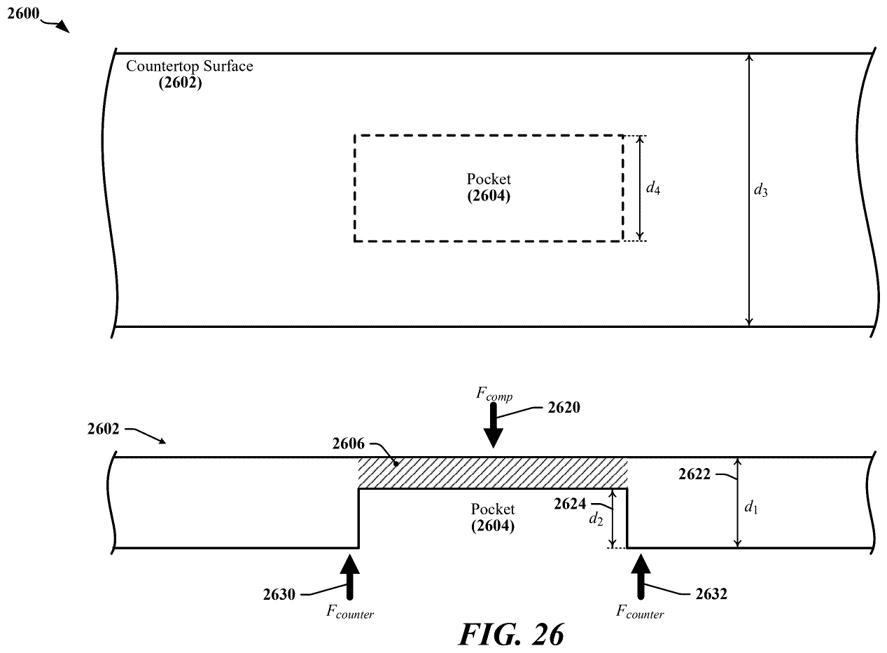

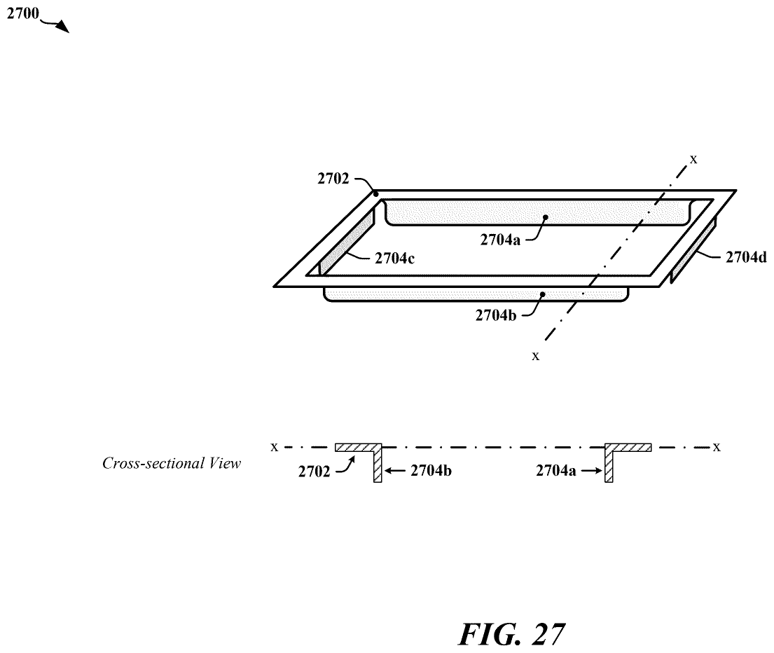

FIGS. 26-27 relate to apparatus, structures, systems, techniques and methods for embedding a charging device within a cavity, hollow or pocket formed within the body of a table, desk, workbench, bar top, kitchen worksurface, or other item of furniture in accordance with certain aspects of this disclosure. In certain embodiments, a mounting bracket installed within the hollow or pocket may be configured and/or structured to strengthen and/or stiffen the table, desk, workbench, bar top, kitchen worksurface, or other item of furniture around the location of the hollow or pocket. The creation of the hollow or pocket can be expected to weaken the structure in which the charging device is to be installed.

FIG. 26 illustrates an example of a countertop 2600 in which a cavity, hollow or pocket 2604 is provided near an upper surface 2602 of the countertop 2600. In the illustrated example, the cavity, hollow or pocket 2604 has a depth 2624 that is a significant proportion of the height 2622 of the countertop 2600. The depth 2624 of the cavity, hollow or pocket 2604 may be selected, calculated and/or configured to position power transmitting coils of an embedded charging device close as possible to the upper surface 2602 of the countertop 2600. The distance between the power transmitting coils and a receiving coil in a chargeable device placed on the surface can limit the rate at which power can be transferred between the charging device and the chargeable device due to imperfect coupling between the power transmitting coils and the receiving coil.

The depth 2624 of the cavity, hollow or pocket 2604 can significantly reduce the ability of the countertop 2600 to withstand forces applied in the vicinity of the cavity, hollow or pocket 2604. In one example, a compressive force 2620 acting on the upper surface 2602 of the countertop 2600 is met by counteracting forces 2630, 2632 attributable to the structure on which the countertop 2600 is mounted. In one example the countertop 2600 is mounted on a closed cabinet. In a countertop that has no pocket or hollow section, the counteracting force may be applied evenly across a portion of the lower surface of the countertop 2600. In the illustrated example, the counteracting forces 2630, 2632 applied at the edges of the cavity, hollow or pocket 2604 resist a compressive force 2620 applied to the upper surface 2602 of the countertop 2600 at a point or area located above the center of the cavity, hollow or pocket 2604. The compressive force 2620 is resisted by a suspended section 2606 of the countertop 2600 that is located over the cavity, hollow or pocket 2604. In some examples, the countertop 2600 is constructed from a material that has sufficient elasticity to cause the suspended section 2606 of the countertop 2600 to bow. In some examples, the countertop 2600 is constructed from an inelastic material that substantially maintains its shape until a maximum shear force is reached where the structure of the countertop 2600 fails. The maximum force that the countertop 2600 can withstand decreases with the thickness of the suspended section 2606 of the countertop 2600.

The need to limit distance between the power transmitting coils of a charging device and a receiving coil in a chargeable device conflicts with the preference to maintain the thickness of the suspended section 2606 of the countertop 2600. Certain aspects of this disclosure relate to a structural brace that can be used to strengthen the countertop 2600 in the vicinity of the cavity, hollow or pocket 2604. In certain implementations, the structural brace can be included in a mounting bracket used to locate and hold a charging device within the cavity, hollow or pocket 2604.

FIG. 27 illustrates an example of a structural brace 2700 that may be configured in accordance with certain aspects of this disclosure. With continued reference to FIG. 26, the structural brace 2700 can be fixed within the cavity, hollow or pocket 2604 formed in the countertop 2600. The illustrated structural brace 2700 is rectangular in shape and comprises a rim 2702 and flanges 2704a, 2704b, 2704c and 2704d. Each flange 2704a-2704d is joined to one side of the rim 2702 and extends perpendicularly from a line along the side of the rim 2702 to which the flange 2704a-2704d is joined.

In some implementations, the flanges 2704a-2704d are formed as an integral part of the structural brace 2700. In one example, the structural brace 2700 may be manufactured from a single sheet of metal, whereby the structural brace 2700 is formed by stamping or cutting and the flanges 2704a-2704d are bent to obtain a perpendicular or other desired orientation with respect to the rim 2702. In some implementations, the flanges 2704a-2704d are manufactured separately from the rim 2702 and subsequently welded, bonded or otherwise fastened to the rim 2702.

In the illustrated example, the flanges 2704a-2704d are straight and extend perpendicularly from the rim 2702. In some examples, the orientation of the flanges 2704a-2704d may be offset from the perpendicular. In some examples, the flanges 2704a-2704d may be curved.

In some implementations, the flanges 2704a-2704d are not interconnected. In some examples, the flanges 2704a-2704d may be joined by interconnecting elements. In some examples, the flanges 2704a-2704d may be joined at their vertical edges.

In some implementations, the flanges 2704a-2704d are dimensioned to provide a tight or precise fit within the cavity, hollow or pocket 2604. A tight or precise fit may be provided when the flanges 2704a-2704d align with the outer edges of the cavity, hollow or pocket 2604 and are dimensioned such that portions of the structural brace 2700 are compressed during insertion exert pressure on the walls of the cavity, hollow or pocket 2604 sufficient to hold the structural brace 2700 in place after insertion. In some implementations, the flanges 2704a-2704d are dimensioned to provide a close fit whereby any gaps between the flanges 2704a-2704d and the walls of the cavity, hollow or pocket 2604 are filled by glue or bonding compounds used to fix the structural brace 2700 in place.

The thickness of the rim 2702 and thickness of the flanges 2704a-2704d may be selected to provide a desired tensile or compressive strength. The thickness of the rim 2702 and thickness of the flanges 2704a-2704d may be selected to provide a desired stiffness, which may be defined as the ability of the structural brace 2700 to resist deformation in response to the compressive force 2620.

The cross-sectional shape of the illustrated structural brace 2700 is configured to enable each flange 2704a-2704d in combination with a portion of the rim 2702 can resist deformation along multiple axes. The flanges 2704a-2704d may be configured to prevent deformation of the rim 2702 in the presence of the compressive force 2620.

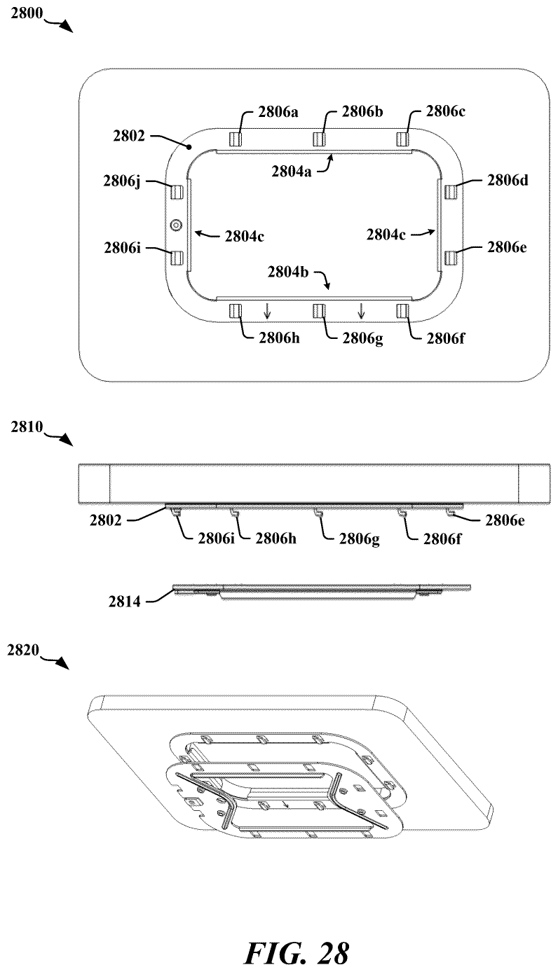

FIG. 28 illustrates an example of a mounting bracket 2800 that may be configured in accordance with certain aspects of this disclosure. The mounting bracket 2800 incorporates many of the concepts and features of the structural brace 2700 illustrated in FIG. 27 and is shown as mounted and/or fixed within the cavity, hollow or pocket 2604 formed in the countertop 2600 illustrated in FIG. 26. The illustrated mounting bracket 2800 is generally rectangular in shape and has rounded corners. The mounting bracket 2800 comprises a rim 2802 and flanges 2804a, 2804b, 2804c and 2804d. Each flange 2804a-2804d is joined to one side of the rim 2802 and extends perpendicularly from a line along the side of the rim 2802 to which the flange 2804a-2804d is joined. In some implementations, the flanges 2804a-2804d are formed as an integral part of the mounting bracket 2800. In one example, the mounting bracket 2800 may be manufactured from a single sheet of metal, whereby the mounting bracket 2800 is formed by stamping or cutting and the flanges 2804a-2804d are bent to obtain a perpendicular or other desired orientation with respect to the rim 2802. In some implementations, the flanges 2804a-2804d are manufactured separately from the rim 2802 and subsequently welded, bonded or otherwise fastened to the rim 2802.

In the illustrated example, the flanges 2804a-2804d are straight and extend perpendicularly from the rim 2802. In some examples, the orientation of the flanges 2804a-2804d may be offset from the perpendicular. In some examples, the flanges 2804a-2804d may be curved.

In some implementations, the flanges 2804a-2804d are not interconnected. In some examples, the flanges 2804a-2804d may be joined by interconnecting elements. In some examples, the flanges 2804a-2804d may be joined at their vertical edges.

In some implementations, the flanges 2804a-2804d are not interconnected. In some examples, the flanges 2804a-2804d may be joined by interconnecting elements. In some examples, the flanges 2804a-2804d may be joined at their vertical edges.

In some implementations, the flanges 2804a-2804d are dimensioned to provide a tight or precise fit within the cavity, hollow or pocket 2604. A tight or precise fit may be provided when the flanges 2804a-2804d align with the outer edges of the cavity, hollow or pocket 2604 and are dimensioned such that portions of the mounting bracket 2800 are compressed during insertion exert pressure on the walls of the cavity, hollow or pocket 2604 sufficient to hold the mounting bracket 2800 in place after insertion. In some implementations, the flanges 2804a-2804d are dimensioned to provide a close fit whereby any gaps between the flanges 2804a-2804d and the walls of the cavity, hollow or pocket 2604 are filled by glue or bonding compounds used to fix the mounting bracket 2800 in place.

The thickness of the rim 2802 and thickness of the flanges 2804a-2804d may be selected to provide a desired tensile or compressive strength. The thickness of the rim 2802 and thickness of the flanges 2804a-2804d may be selected to provide a desired stiffness, which may be defined as the ability of the mounting bracket 2800 to resist deformation in response to the compressive force 2620.

The mounting bracket 2800 includes a number of fasteners 2806a-2806j configured to align with openings in a cover plate 2814, which is shown in the cross-sectional view 2810. In a fully assembled system, the cover plate 2814 may be attached to the bottom of a muti-coil charging device that is located within the cavity, hollow or pocket 2604 of the countertop 2600 when the cover plate 2814 is mated with the mounting bracket 2800. Certain aspects of the cover plate 2814 and mounting bracket 2800 are illustrated in the three-dimensional view 2820. The cover plate 2814 may be alternatively or additionally fastened to the mounting bracket 2800. In the illustrated example, the fasteners 2806a-2806j are formed as hook-like structures that are configured to engage with corresponding holes in the cover plate 2814. Any suitable fastener may be used to secure the coupling of the cover plate 2814 and mounting bracket 2800.

In certain implementations, a surface of the cover plate 2814 has a ribbed profile. In one aspect peaks of the ribs contact the lower surface of the countertop 2600 (see FIG. 26) within the cavity, hollow or pocket 2604, and can provide structural reinforcement to the stone or material of the countertop 2600. A ribbed cover plate 2814 can provide additional resistance to a compressive force 2620 exerted on the countertop 2600. In another aspect, the ribbing may be configured to conduct an airflow across the cover plate 2814. The airflow may be provided by a fan, vent, blower or other active cooling component. In one example, ribs may be provided in a substantially parallel orientation across the cover plate 2814. In another example, ribs may be curved across the cover plate 2814. In another example, ribs may be configured to provide a tortuous path across the surface of the cover plate 2814, where the tortuous path can optimize heat transfer through the cover plate 2814. Optimized heat transfer may be obtained by ensuring that airflows across known or expected hotspots on the cover plate 2814.

In one example, a mounting bracket has a rim, at least one flange and one or more fasteners. The rim may be configured to encompass a cavity formed in a countertop. The at least one flange may have a first edge joined to an inner edge of the rim. The at least one flange may have a second configured to extend into the cavity. The one or more fasteners may be formed on the rim. The one or more fasteners may be configured to engage with corresponding features of a cover plate. The mounting bracket may be configured to strengthen the countertop in the vicinity of the cavity when fastened to the countertop.

In some implementations, the cover plate is mounted on a charging device that is located within the cavity when the cover plate is coupled to the mounting bracket.

In some implementations, a plurality of ribs is provided on a surface of the cover plate. Peaks of the plurality of ribs may be configured to contact a lower surface of the countertop within the cavity when the mounting bracket is fastened to the countertop and the cover plate is engaged with the one or more fasteners. The mounting bracket may be configured to receive an airflow and to conduct the airflow across the cover plate and/or a surface of the countertop. The source of the airflow may be fluidically coupled to the cover plate. For example, the airflow may follow a path defined by channels formed between the plurality of ribs. The source of an airflow may be a fan. The source of an airflow may be vent. The source of an airflow may be a blower. The source of an airflow may be an active cooling device.

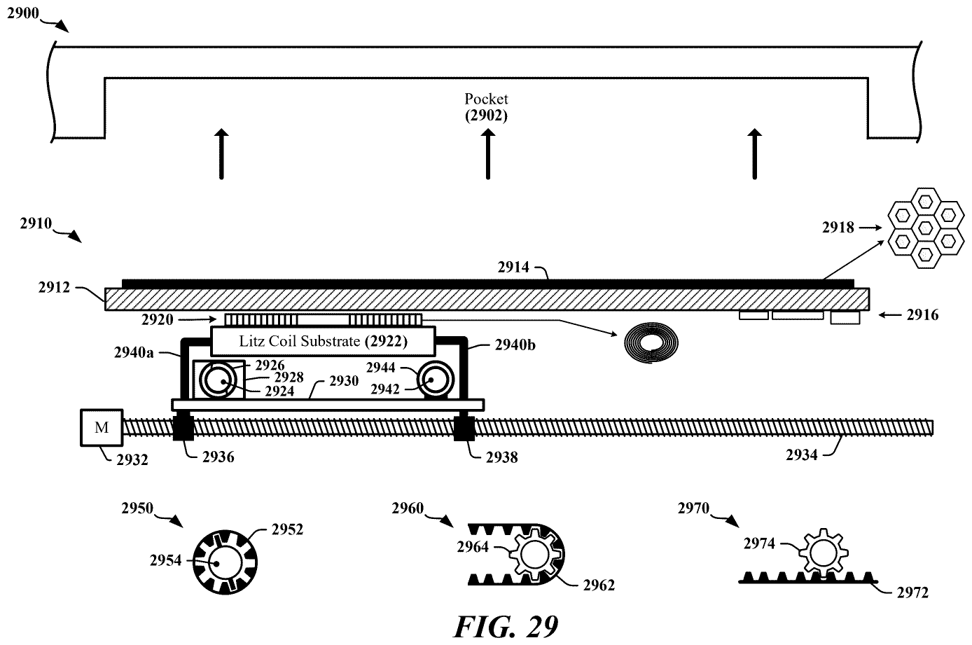

FIG. 29 illustrates an example of a charging system 2910 that includes fixed and relocatable charging coils configured in accordance with certain aspects of this disclosure. In some implementations, the fixed and relocatable charging coils can be attached or coupled to a charging device and can be at least partially mounted within a cavity, hollow or pocket 2902 of a countertop 2900. In one example, at least a portion of the charging system 2910 can be installed within the countertop 2900 using a mounting bracket and cover arrangement corresponding in some respects to the mounting bracket 2800 and cover plate 2814 shown in FIG. 28.

The charging system 2910 includes a PCB assembly 2912. The PCB assembly 2912 may include one or more PCBs that each has one or more metal layers 2914 or areas in which charging cells 2918 may be formed. In one example, the charging cells 2918 are formed in a configuration that is illustrated in FIG. 3, whereby multiple layers of charging cells 302, 304, 306, 308 can be formed on a PCB or stack of PCBs that has four or more metal layers. In another example, multiple copies of the same PCB assembly 2912 may be laminated to obtain a final module. As illustrated in FIG. 19, for example, one or more printed circuit boards 1902, 1904 can be glued or otherwise joined together to form a wireless charging device. The printed circuit boards 1902, 1904 may have different layers, designs, thicknesses, etc. and, in some instances, magnetic or shielding material may be provided within or in addition to an adhesive layer 1906 provided between printed circuit boards 1902, 1904. The illustrated PCB assembly 2912 includes multiple IC devices 2916 affixed to one side of a printed circuit board. The IC devices 2916 may be disposed across the surface of one or more printed circuit boards and may be part of a processing circuit, power generation circuit or power distribution circuit, for example. The IC devices 2916 may be coupled to other portions of a circuit provided elsewhere in the charging system 2910.

The illustrated charging system 2910 includes a motorized, relocatable charging coil subsystem that enables a Litz coil 2920 to be positioned within a 2-dimensional space corresponding to at least part of the charging surface provided by the charging system 2910. The Litz coil 2920 may be fixed to a substrate 2922. The substrate 2922 may include some combination of layers, including polymer, acetate, vinyl, nitrile rubber, latex, extruded polystyrene foam and/or other layers. In one example, the substrate 2922 is fabricated by joining or bonding extruded polystyrene foam to a printed circuit board or metal carrier. FIG. 8 shows an example of a Litz coil substrate 800 that may be adapted for use in the charging system 2910.

The substrate 2922 is mounted on a carriage 2930 using a pair of couplings 2940a, 2940b. The couplings 2940a, 2940b are typically manufactured from a rigid material and can also serve as spacing elements that control the distance between the substrate 2922 and the carriage 2930. In the illustrated example, the carriage 2930 can be moved in two dimensions by a pair of worm drives. In other implementations, a different type of drive may be used including, for example, a rack and pinion drive, a drive based on a toothed belt or chain or another type of linear actuator. In the illustrated example, a first worm drive includes a first worm 2924, which may be considered to be a gear formed as a screw. The first worm 2924 engages a threaded cylinder 2926, which moves along the first worm 2924 as the first worm 2924 rotates. The first worm 2924 is rotated by motor 2928. In certain implementations, motor 2928 comprises a stepping motor that can be used to accurately position the threaded cylinder 2926 and, consequently, the carriage 2930 in a first dimension. The carriage 2930 can be moved a desired distance by controlling the number of rotations or partial rotations of the stepping motor, which may be selected based on the gear ratio provided by the combination of the first worm 2924 and threaded cylinder 2926.

In the illustrated example, the carriage 2930 includes a bearing 2944 that is configured to slide along a cylindrical rod 2942 as the carriage 2930 moves in parallel to the first worm 2924. The bearing 2944 may be configured to provide low-friction contact with the cylindrical rod 2942, and may prevent rotation of the carriage 2930 about the first worm 2924. In some implementations, location may be determined based on a sensor-based system that determines position independently of the method of moving the carriage 2930. In one example, the cylindrical rod 2942 and/or bearing 2944 may be instrumented or equipped with sensors that can be used to determine position, motion and/or distance traveled.

The carriage 2930 may be moved in a second direction using a second worm drive, or other type of drive. The second worm drive includes a second worm 2934, which is configured to move the carriage 2930 in a direction of motion that is orthogonal to the direction of motion caused by the first worm 2924. The second worm 2934 engages a pair of threaded cylinders 2936, 2938, which are configured to move along the second worm 2934 as the second worm 2934 rotates. The second worm 2934 is rotated by motor 2932. In certain implementations, motor 2932 comprises a stepping motor that can be used to accurately position the carriage 2930 in a second dimension. The carriage 2930 can be moved a desired distance by controlling the number of rotations or partial rotations of the stepping motor, which may be selected based on the gear ratio provided by the combination of the second worm 2934 and the threaded cylinder 2936 and 2938. In some implementations, one of the threaded cylinder 2936 and 2938 is omitted and the other may be positioned in a central location on the carriage 2930. The carriage 2930 may also be mounted on a second cylindrical rod (not shown) to stabilize the carriage 2930 and/or prevent rotation of the carriage 2930 about the second worm 2934.

Various charging systems illustrated herein, including the charging system 2910 illustrated in FIG. 29 use worm drives to move one or more carriages in two dimensions. In other implementations, a different type of linear actuator may be used to move a carriage in one or more dimensions. In still other implementations, a combination of types of linear actuator may be used to move carriages in one or more dimensions. For example, one type of linear actuator may be suited for moving a carriage over relatively long distances in a horizontal plane, while another type of linear actuator may be better suited to move the carriage and in some instances, to move other actuator components in a direction that is perpendicular to the plane. Movement along a direction that is perpendicular to the plane may be necessitated when it is desired or necessary to close the distance between a movable coil and a charging surface. A cross-sectional view of a worm drive 2950 shows the interaction between a worm wheel 2952 (gear) and the worm 2954. A cross-sectional view of a belt drive 2960 shows the interaction between a toothed belt 2962 and a gear wheel 2964. A cross-sectional view of a rack and pinion drive 2970 shows the interaction between a rack 2972 and a pinion 2974 (gear wheel).

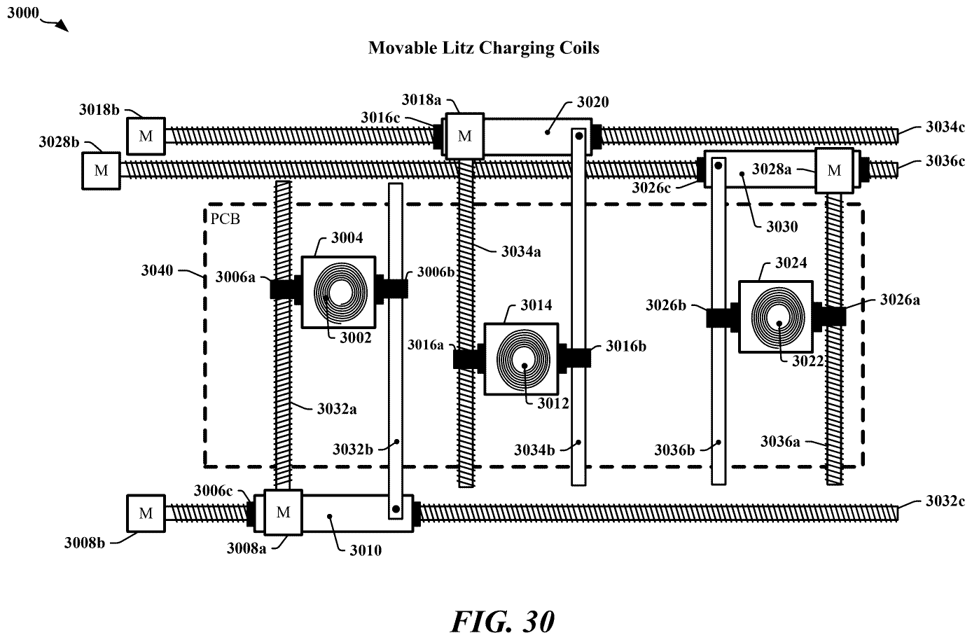

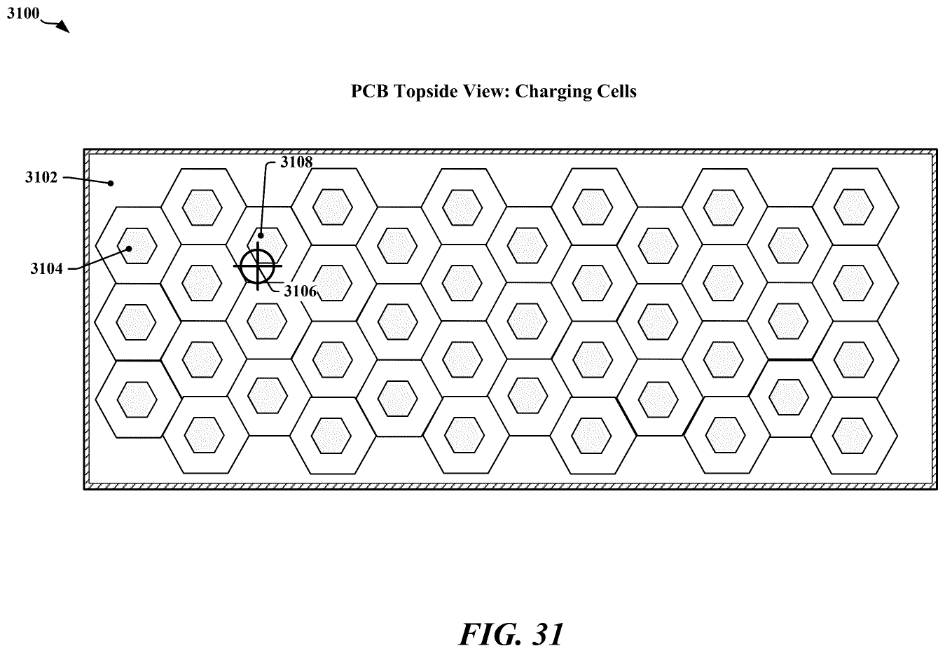

FIG. 30 illustrates a first example of a movable charging coil subsystem 3000 in accordance with certain aspects of this disclosure. The movable charging coil subsystem 3000 may be included in a charging apparatus such as the charging system 2910 illustrated in FIG. 29. The illustrated movable charging coil subsystem 3000 can position three charging coils 3002, 3012, 3022 at different locations under a PCB assembly. FIG. 31 shows an example of the topside 3100 of a PCB in which multiple charging cells, including charging cell 3104, have been formed in a metal layer 3102. The topside 3100 of the PCB may correspond to the topside of a PCB in the PCB assembly 2912 shown in FIG. 29, for example. A charging surface outline 3040 is shown for reference, and may correspond to the outer limits of the charging surface provided by the PCB assembly 2912 illustrated in FIG. 29.

Each of the three charging coils 3002, 3012, 3022 is carried on a respective fixed to a respective carriage, referred to herein as a y-axis carriage 3004, 3014, 3024. The identification of x and y axes is made herein for the sole purpose of facilitating description of certain aspects of the disclosure. In some implementations, the charging coils 3002, 3012, 3022 comprise Litz coils that may be mounted in a substrate fixed to their corresponding y-axis carriage 3004, 3014, 3024. The substrate may include some combination of layers, including polymer, acetate, vinyl, nitrile rubber, latex, extruded polystyrene foam and/or other layers. In one example, the substrate is fabricated by joining or bonding extruded polystyrene foam to a printed circuit board or metal carrier. FIG. 8 shows an example of a Litz coil substrate 800 that may be adapted for use in the movable charging coil subsystem 3000.

The y-axis carriages 3004, 3014, 3024 are coupled to respective worm drives that enable motion along the y-axis. In the illustrated example, a first threaded cylinder 3006a fixed to a first y-axis carriage 3004 engages a first worm 3032a. The first threaded cylinder 3006a is configured to pull the first y-axis carriage 3004 along the y-axis (i.e., along the first worm 3032a) as the first worm 3032a rotates. The first worm 3032a is rotated by a first y-axis motor 3008a. In certain implementations, the first y-axis motor 3008a comprises a stepping motor that can be used to accurately position charging coil 3002 at a desired y-axis coordinate. The first y-axis carriage 3004 can be moved to the desired y-axis coordinate by controlling the number of rotations or partial rotations of the stepping motor. The number of rotations or partial rotations of the stepping motor needed to locate the charging coil 3002 at the desired y-axis coordinate may be calculated or selected based on the gear ratio associated with the combination of the first worm 3032a and the first threaded cylinder 3006a. In the illustrated example, the first y-axis carriage 3004 includes a first bearing 3006b that is configured to slide along a first cylindrical rod 3032b as the first y-axis carriage 3004 moves along the first worm 3032a. The first bearing 3006b may be configured to provide low-friction contact with the first cylindrical rod 3032b, and may undesired prevent rotation of the first y-axis carriage 3004 about the first worm 3032a.

One end of the first worm 3032a may be coupled to a first x-axis carriage 3010. The first x-axis carriage 3010 may be coupled to a worm drive that enables motion along the x-axis. In the illustrated example, a second threaded cylinder 3006c fixed to the first x-axis carriage 3010 engages a second worm 3032c. The second threaded cylinder 3006c is configured to pull the first x-axis carriage 3010 along the x-axis (i.e., along the second worm 3032c) as the second worm 3032c rotates. The second worm 3032c is rotated by a first x-axis motor 3008b. In certain implementations, the first x-axis motor 3008b comprises a stepping motor that can be used to accurately position charging coil 3002 at a desired x-axis coordinate. The first x-axis carriage 3010 can be moved to the desired y-axis coordinate by controlling the number of rotations or partial rotations of the stepping motor. The number of rotations or partial rotations of the stepping motor needed to locate the charging coil 3002 at the desired x-axis coordinate may be calculated or selected based on the gear ratio associated with the combination of the second worm 3032c and the second threaded cylinder 3006c.

In the illustrated example, a first threaded cylinder 3016a fixed to a second y-axis carriage 3014 engages a first worm 3034a. The first threaded cylinder 3016a is configured to pull the second y-axis carriage 3014 along the y-axis (i.e., along the first worm 3034a) as the first worm 3034a rotates. The first worm 3034a is rotated by a first y-axis motor 3018a. In certain implementations, the first y-axis motor 3018a comprises a stepping motor that can be used to accurately position charging coil 3012 at a desired y-axis coordinate. The second y-axis carriage 3014 can be moved to the desired y-axis coordinate by controlling the number of rotations or partial rotations of the stepping motor. The number of rotations or partial rotations of the stepping motor needed to locate the charging coil 3012 at the desired y-axis coordinate may be calculated or selected based on the gear ratio associated with the combination of the first worm 3034a and the first threaded cylinder 3016a. In the illustrated example, the second y-axis carriage 3014 includes a first bearing 3016b that is configured to slide along a first cylindrical rod 3034b as the second y-axis carriage 3014 moves along the first worm 3034a. The first bearing 3016b may be configured to provide low-friction contact with the first cylindrical rod 3034b, and may undesired prevent rotation of the second y-axis carriage 3014 about the first worm 3034a.

One end of the first worm 3034a may be coupled to a second x-axis carriage 3020. The second x-axis carriage 3020 may be coupled to a worm drive that enables motion along the x-axis. In the illustrated example, a second threaded cylinder 3016c fixed to the second x-axis carriage 3020 engages a second worm 3034c. The second threaded cylinder 3016c is configured to pull the second x-axis carriage 3020 along the x-axis (i.e., along the second worm 3034c) as the second worm 3034c rotates. The second worm 3034c is rotated by a first x-axis motor 3018b. In certain implementations, the first x-axis motor 3018b comprises a stepping motor that can be used to accurately position charging coil 3012 at a desired x-axis coordinate. The second x-axis carriage 3020 can be moved to the desired y-axis coordinate by controlling the number of rotations or partial rotations of the stepping motor. The number of rotations or partial rotations of the stepping motor needed to locate the charging coil 3012 at the desired x-axis coordinate may be calculated or selected based on the gear ratio associated with the combination of the second worm 3034c and the second threaded cylinder 3016c.

In the illustrated example, a first threaded cylinder 3026a fixed to a third y-axis carriage 3024 engages a first worm 3036a. The first threaded cylinder 3026a is configured to pull the third y-axis carriage 3024 along the y-axis (i.e., along the first worm 3036a) as the first worm 3036a rotates. The first worm 3036a is rotated by a first y-axis motor 3028a. In certain implementations, the first y-axis motor 3028a comprises a stepping motor that can be used to accurately position charging coil 3022 at a desired y-axis coordinate. The third y-axis carriage 3024 can be moved to the desired y-axis coordinate by controlling the number of rotations or partial rotations of the stepping motor. The number of rotations or partial rotations of the stepping motor needed to locate the charging coil 3022 at the desired y-axis coordinate may be calculated or selected based on the gear ratio associated with the combination of the first worm 3036a and the first threaded cylinder 3026a. In the illustrated example, the third y-axis carriage 3024 includes a first bearing 3026b that is configured to slide along a first cylindrical rod 3036b as the third y-axis carriage 3024 moves along the first worm 3036a. The first bearing 3026b may be configured to provide low-friction contact with the first cylindrical rod 3036b, and may undesired prevent rotation of the third y-axis carriage 3024 about the first worm 3036a.

One end of the first worm 3036a may be coupled to a third x-axis carriage 3030. The third x-axis carriage 3030 may be coupled to a worm drive that enables motion along the x-axis. In the illustrated example, a second threaded cylinder 3026c fixed to the third x-axis carriage 3030 engages a second worm 3036c. The second threaded cylinder 3026c is configured to pull the third x-axis carriage 3030 along the x-axis (i.e., along the second worm 3036c) as the second worm 3036c rotates. The second worm 3036c is rotated by a first x-axis motor 3028b. In certain implementations, the first x-axis motor 3028b comprises a stepping motor that can be used to accurately position charging coil 3022 at a desired x-axis coordinate. The third x-axis carriage 3030 can be moved to the desired y-axis coordinate by controlling the number of rotations or partial rotations of the stepping motor. The number of rotations or partial rotations of the stepping motor needed to locate the charging coil 3022 at the desired x-axis coordinate may be calculated or selected based on the gear ratio associated with the combination of the second worm 3036c and the second threaded cylinder 3026c.

In one example, the y-axis carriages 3004, 3014, 3024 include motors or linear displacement transducers that permit respective that enable the charging coils 3002, 3012, 3022 to be moved along the z-axis to a location proximate to a targeted charging cell in the charging surface provided by the charging coil subsystem 3000. In one example, z-axis motion may be accomplished using one or more stepping motors. In other examples, mechanical or phase change actuators may be used. A phase change actuator includes a phase change material that increases or decreases volume in response to changes in temperature due to a change in phase (e.g., solid phase to liquid phase).

In certain implementations, the first x-axis carriage 3010, the first y-axis carriage 3004 and associated worms 3032a, 3032c may be provided in a different vertical plane (i.e., along the z-axis) than the other axis carriages 3014, 3020, 3024, 3030 and worms 3034a, 3032c, 3036a, 3036c.

In certain implementations, the movable charging coil subsystem 3000 may be configured such that each of the three charging coils 3002, 3012, 3022 can be centered at any x, y coordinate (i.e., position) within the charging surface outline 3040. When fully assembled in a countertop 2900, for example, the movable charging coil subsystem 3000 may be configured such that each of the three charging coils 3002, 3012, 3022 can be centered under any charging cell provided by the charging system 2910 illustrated in FIG. 29. With reference to FIG. 31 for example, the charging system 2910 may determine that optimum coupling with a chargeable device is centered on a location 3106. The location 3106 may be determined using a combination of the detection techniques disclosed herein. For example, a search based on passive ping may determine that a strongest response to a ping is centered on a first charging cell 3108 that includes a coil formed in the metal layer 3102 of the topside 3100 of a PCB. Other charging cells may also respond to the passive ping and a processing circuit in the charging system 2910 may calculate a likely location of a power receiving coil in the chargeable device, which may be centered on the location 3106.

Having determined the location 3106 through which charge may be optimally transferred, the processing circuit in the charging system 2910 may activate motors in the movable charging coil subsystem 3000 to cause one of the three movable charging coils 3002, 3012, 3022 to be centered on the detected location 3106. The processing circuit may initiate charging of the chargeable device through one or more cells, including the first charging cell 3108, before a movable charging coil 3002, 3012, 3022 has been positioned in alignment with the detected location 3106. The processing circuit may use a digital ping to determine the capabilities of the chargeable device including, for example, a maximum power that the chargeable device can support. The processing circuit may use such information to configure a charging current to be provided to the movable charging coil 3002, 3012, 3022 when it arrives on station, aligned with the detected location 3106. From a user perspective, charging can begin in substantially less than a second after placement of the chargeable device on the charging surface, with maximum power being applied after a maximum time that is dependent on initial positioning of the movable charging coil 3002, 3012, 3022, and that may be measured in seconds.

The movable charging coil subsystem 3000 illustrated in FIG. 30 is configured to position three charging coils 3002, 3012, 3022 at different locations under a PCB assembly. In many instances, the movable charging coil subsystem 3000 may enable concurrent charging through the three charging coils 3002, 3012, 3022. In some instances, Chargeable devices may be positioned in an alignment that prevents the positioning of one or more of the charging coils 3002, 3012, 3022 in sufficient proximity to enable charging. In certain implementations, certain dimensions of components of the movable charging coil subsystem 3000 may be reduced in size to limit potential for obstructions based on the alignment of chargeable devices. In one example, the charging coils 3002, 3012, 3022 may be formed by stacking coils in a vertical plane and reducing the planar diameter of the charging coils 3002, 3012, 3022.

In certain implementations, a movable charging coil subsystem may provide fewer than three movable charging coils. In certain implementations, a movable charging coil subsystem may provide more than three movable charging coils.

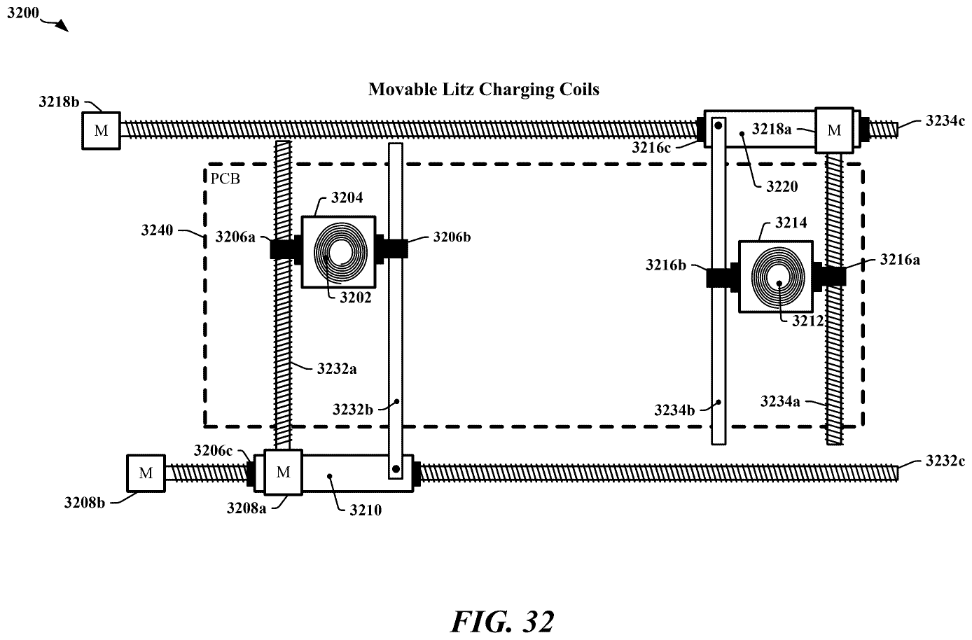

FIG. 32 illustrates a second example of a movable charging coil subsystem 3200 in accordance with certain aspects of this disclosure. The movable charging coil subsystem 3200 may be included in a charging apparatus such as the charging system 2910 illustrated in FIG. 29. The illustrated movable charging coil subsystem 3200 can position two charging coils 3202, 3212 at different locations under a PCB assembly. FIG. 31 shows an example of the topside 3100 of a PCB in which multiple charging cells, including charging cell 3104, have been formed in a metal layer 3102. The topside 3100 of the PCB may correspond to the topside of a PCB in the PCB assembly 2912 shown in FIG. 29, for example. A charging surface outline 3240 is shown for reference, and may correspond to the outer limits of the charging surface provided by the PCB assembly 2912 illustrated in FIG. 29.

Each of the charging coils 3202, 3212 is carried on a respective fixed to a respective carriage, referred to herein as y-axis carriage 3204, 3214. The identification of x and y axes is made herein for the sole purpose of facilitating description of certain aspects of the disclosure. In some implementations, the charging coils 3202, 3212 comprise Litz coils that may be mounted in a substrate fixed to their corresponding y-axis carriage 3204, 3214. The substrate may include some combination of layers, including polymer, acetate, vinyl, nitrile rubber, latex, extruded polystyrene foam and/or other layers. In one example, the substrate is fabricated by joining or bonding extruded polystyrene foam to a printed circuit board or metal carrier. FIG. 8 shows an example of a Litz coil substrate 800 that may be adapted for use in the movable charging coil subsystem 3200.

The y-axis carriages 3204, 3214 are coupled to respective worm drives that enable motion along the y-axis. In the illustrated example, a first threaded cylinder 3206a fixed to a first y-axis carriage 3204 engages a first worm 3232a. The first threaded cylinder 3206a is configured to pull the first y-axis carriage 3204 along the y-axis (i.e., along the first worm 3232a) as the first worm 3232a rotates. The first worm 3232a is rotated by a first y-axis motor 3208a. In certain implementations, the first y-axis motor 3208a comprises a stepping motor that can be used to accurately position charging coil 3202 at a desired y-axis coordinate. The first y-axis carriage 3204 can be moved to the desired y-axis coordinate by controlling the number of rotations or partial rotations of the stepping motor. The number of rotations or partial rotations of the stepping motor needed to locate the charging coil 3202 at the desired y-axis coordinate may be calculated or selected based on the gear ratio associated with the combination of the first worm 3232a and the first threaded cylinder 3206a. In the illustrated example, the first y-axis carriage 3204 includes a first bearing 3206b that is configured to slide along a first cylindrical rod 3232b as the first y-axis carriage 3204 moves along the first worm 3232a. The first bearing 3206b may be configured to provide low-friction contact with the first cylindrical rod 3232b, and may undesired prevent rotation of the first y-axis carriage 3204 about the first worm 3232a.

One end of the first worm 3232a may be coupled to a first x-axis carriage 3210. The first x-axis carriage 3210 may be coupled to a worm drive that enables motion along the x-axis. In the illustrated example, a second threaded cylinder 3206c fixed to the first x-axis carriage 3210 engages a second worm 3232c. The second threaded cylinder 3206c is configured to pull the first x-axis carriage 3210 along the x-axis (i.e., along the second worm 3232c) as the second worm 3232c rotates. The second worm 3232c is rotated by a first x-axis motor 3208b. In certain implementations, the first x-axis motor 3208b comprises a stepping motor that can be used to accurately position charging coil 3202 at a desired x-axis coordinate. The first x-axis carriage 3210 can be moved to the desired y-axis coordinate by controlling the number of rotations or partial rotations of the stepping motor. The number of rotations or partial rotations of the stepping motor needed to locate the charging coil 3202 at the desired x-axis coordinate may be calculated or selected based on the gear ratio associated with the combination of the second worm 3232c and the second threaded cylinder 3206c.

In the illustrated example, a first threaded cylinder 3216a fixed to a second y-axis carriage 3214 engages a first worm 3234a. The first threaded cylinder 3216a is configured to pull the second y-axis carriage 3214 along the y-axis (i.e., along the first worm 3234a) as the first worm 3234a rotates. The first worm 3234a is rotated by a first y-axis motor 3218a. In certain implementations, the first y-axis motor 3218a comprises a stepping motor that can be used to accurately position charging coil 3212 at a desired y-axis coordinate. The second y-axis carriage 3214 can be moved to the desired y-axis coordinate by controlling the number of rotations or partial rotations of the stepping motor. The number of rotations or partial rotations of the stepping motor needed to locate the charging coil 3212 at the desired y-axis coordinate may be calculated or selected based on the gear ratio associated with the combination of the first worm 3234a and the first threaded cylinder 3216a. In the illustrated example, the second y-axis carriage 3214 includes a first bearing 3216b that is configured to slide along a first cylindrical rod 3234b as the second y-axis carriage 3214 moves along the first worm 3234a. The first bearing 3216b may be configured to provide low-friction contact with the first cylindrical rod 3234b, and may undesired prevent rotation of the second y-axis carriage 3214 about the first worm 3234a.

One end of the first worm 3234a may be coupled to a second x-axis carriage 3220. The second x-axis carriage 3220 may be coupled to a worm drive that enables motion along the x-axis. In the illustrated example, a second threaded cylinder 3216c fixed to the second x-axis carriage 3220 engages a second worm 3234c. The second threaded cylinder 3216c is configured to pull the second x-axis carriage 3220 along the x-axis (i.e., along the second worm 3234c) as the second worm 3234c rotates. The second worm 3234c is rotated by a first x-axis motor 3218b. In certain implementations, the first x-axis motor 3218b comprises a stepping motor that can be used to accurately position charging coil 3212 at a desired x-axis coordinate. The second x-axis carriage 3220 can be moved to the desired y-axis coordinate by controlling the number of rotations or partial rotations of the stepping motor. The number of rotations or partial rotations of the stepping motor needed to locate the charging coil 3212 at the desired x-axis coordinate may be calculated or selected based on the gear ratio associated with the combination of the second worm 3234c and the second threaded cylinder 3216c.

In one example, the y-axis carriages 3204, 3214 include motors or linear displacement transducers that permit respective that enable the charging coils 3202, 3212 to be moved along the z-axis to a location proximate to a targeted charging cell in the charging surface provided by the charging coil subsystem 3200. In one example, z-axis motion may be accomplished using one or more stepping motors. In other examples, mechanical or phase change actuators may be used. A phase change actuator includes a phase change material that increases or decreases volume in response to changes in temperature due to a change in phase (e.g., solid phase to liquid phase).

In certain implementations, the first x-axis carriage 3210, the first y-axis carriage 3204 and associated worms 3232a, 3232c may be provided in a different vertical plane (i.e., along the z-axis) than the other axis carriages 3214, 3220 and worms 3234a, 3234c.

In certain implementations, the movable charging coil subsystem 3200 may be configured such that each of the two charging coils 3202, 3212 can be centered at any x, y coordinate (i.e., position) within the charging surface outline 3240. When fully assembled in a countertop 2900, for example, the movable charging coil subsystem 3200 may be configured such that each of the two charging coils 3202, 3212 can be centered under any charging cell provided by the charging system 2910 illustrated in FIG. 29. With reference to FIG. 31 for example, the charging system 2910 may determine that optimum coupling with a chargeable device is centered on a location 3106. The location 3106 may be determined using a combination of the detection techniques disclosed herein. For example, a search based on passive ping may determine that a strongest response to a ping is centered on a first charging cell 3108 that includes a coil formed in the metal layer 3102 of the topside 3100 of a PCB. Other charging cells may also respond to the passive ping and a processing circuit in the charging system 2910 may calculate a likely location of a power receiving coil in the chargeable device, which may be centered on the location 3106.

Having determined the location 3106 through which charge may be optimally transferred, the processing circuit in the charging system 2910 may activate motors in the movable charging coil subsystem 3200 to cause one of the movable charging coils 3202, 3212 to be centered on the detected location 3106. The processing circuit may initiate charging of the chargeable device through one or more cells, including the first charging cell 3108, before a movable charging coil 3202, 3212 has been positioned in alignment with the detected location 3106. The processing circuit may use a digital ping to determine the capabilities of the chargeable device including, for example, a maximum power that the chargeable device can support. The processing circuit may use such information to configure a charging current to be provided to the movable charging coil 3202, 3212 when it arrives on station, aligned with the detected location 3106. From a user perspective, charging can begin in substantially less than a second after placement of the chargeable device on the charging surface, with maximum power being applied after a maximum time that is dependent on initial positioning of the movable charging coil 3202, 3212, and that may be measured in seconds.

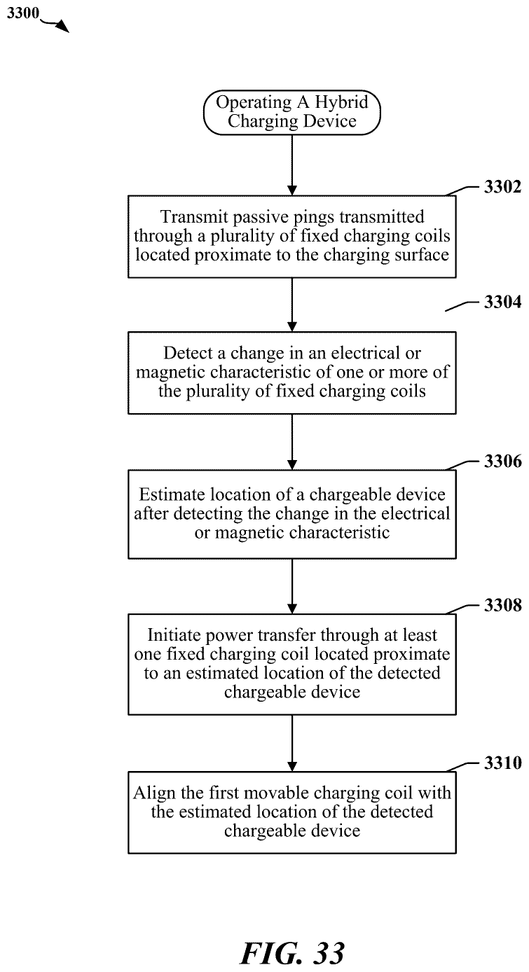

FIG. 33 is flowchart 3300 illustrating one example of a method for operating a charging system. At block 3302, passive pings may be transmitted through a plurality of fixed charging coils located proximate to the charging surface. At block 3304, a change in an electrical or magnetic characteristic may be detected in one or more of the plurality of fixed charging coils. At block 3306, location of a chargeable device may be estimated after detecting the change in the electrical or magnetic characteristic. At block 3308, power transfer may be initiated through at least one fixed charging coil located proximate to an estimated location of the detected chargeable device. At block 3310, the first movable charging coil may be aligned with the estimated location of the detected chargeable device.

In certain implementations, power transfer through the first movable charging coil may be initiated when the first movable charging coil is aligned with the estimated location of the first chargeable device. In some implementations, power transfer through a fixed charging coil may be terminated when power transfer through the first movable charging coil is initiated.

In certain implementations, the first movable charging coil may be one of a plurality of independently movable charging coils. In some instances, the method may be extended to include conducting a further search of the charging surface, estimating location of a second chargeable device after detecting a change in an electrical or magnetic characteristic associated with one or more other charging coils in the plurality of fixed charging coils, initiating power transfer through at least a second charging coil located proximate to an estimated location of the second chargeable device, and aligning a second movable charging coil with the estimated location of the second chargeable device.

In certain implementations, power transfer to the second chargeable device through the second movable charging coil may be initiated when the second movable charging coil is aligned with the estimated location of the second chargeable device. In some implementations, power transfer through a fixed charging coil may be terminated when power transfer through the second movable charging coil is initiated.

In some implementations, the charging system is configured to transfer power through the second movable charging coil while concurrently transferring power through the first movable charging coil.

A hybrid charging system provided in accordance with certain aspects of this disclosure has a plurality of fixed charging coils and one or more movable charging coils. The plurality of fixed charging coils may be formed in a metal layer of a PCB. The PCB may be located adjacent to a charging surface provided by the hybrid charging system.

A first movable charging coil may be mechanically coupled to a first positioning mechanism. The first positioning mechanism may be configured to move the first movable charging coil across the charging surface. The PCB may be located between the charging surface and the first movable charging coil. The first movable charging coil may be a Litz coil. At least a portion of the hybrid charging system is located within a cavity formed in a countertop

In certain implementations, the first positioning mechanism includes a first carriage mechanically coupled to a first worm screw and configured to move along the first worm screw when the first worm screw turns; a second carriage mechanically coupled to a second worm screw and configured to move along the second worm screw when the second worm screw turns; a first motor mounted on the second carriage and configured to turn the first worm screw in response to a first signal; and a second motor coupled to the second worm screw and configured to turn the second worm screw in response to a second signal. The first worm screw and the second worm screw may be aligned along mutually orthogonal axes (e.g., an x-axis and a y-axis). The hybrid charging system may include a processing circuit.

The processing circuit may be configured to conduct a search of the charging surface by transmitting passive pings through the plurality of fixed charging coils, and detecting a change in an electrical or magnetic characteristic of one or more of the plurality of fixed charging coils. The processing circuit may be further configured to estimate location of a chargeable device after detecting the change in the electrical or magnetic characteristic, initiate power transfer through at least one fixed charging coil located proximate to an estimated location of the detected chargeable device, and align the first movable charging coil with the estimated location of the detected chargeable device. The processing circuit may be further configured to initiate power transfer through the first movable charging coil when the first movable charging coil is aligned with the estimated location of the detected chargeable device.

The charging system may include a second movable charging coil mechanically coupled to a second positioning mechanism that is configured to move the second movable charging coil across the charging surface. The PCB may be located between the charging surface and the second movable charging coil. The second positioning mechanism may have a third carriage mechanically coupled to a third worm screw and configured to move along the third worm screw when the third worm screw turns; a fourth carriage mechanically coupled to a fourth worm screw and configured to move along the fourth worm screw when the fourth worm screw turns a third motor mounted on the fourth carriage and configured to turn the third worm screw in response to a third signal, and a fourth motor coupled to the fourth worm screw and configured to turn the fourth worm screw in response to a fourth signal. The third worm screw may be provided in parallel alignment with the first worm screw. The fourth worm screw may be provided in parallel alignment with the second worm screw.

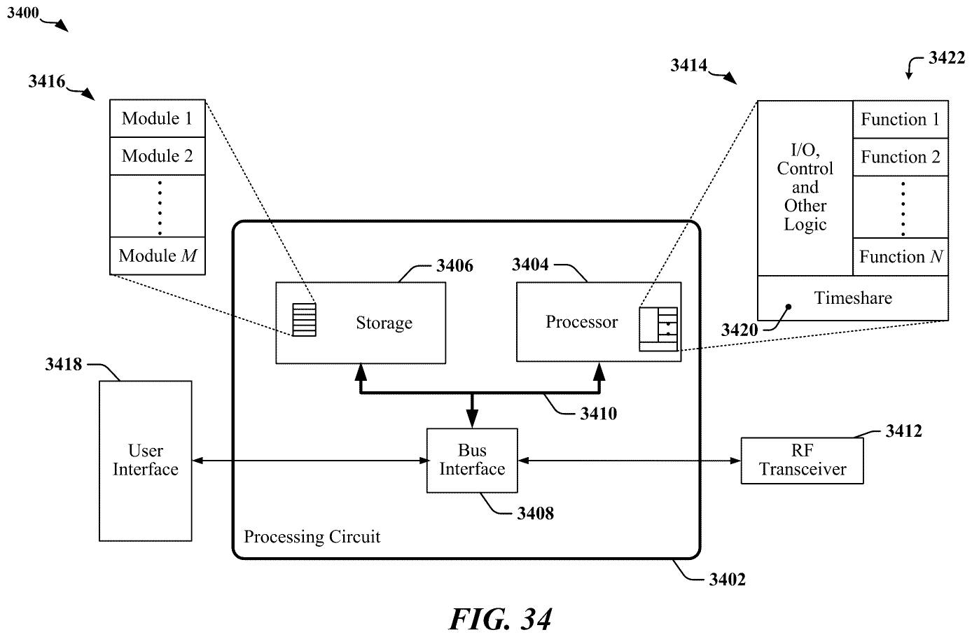

FIG. 34 is a diagram illustrating an example of a hardware implementation for an apparatus 3400 that may be incorporated in a charging device or in a receiving device that enables a battery to be wirelessly charged. In some examples, the apparatus 3400 may perform one or more functions disclosed herein. In accordance with various aspects of the disclosure, an element, or any portion of an element, or any combination of elements as disclosed herein may be implemented using a processing circuit 3402. The processing circuit 3402 may include one or more processors 3404 that are controlled by some combination of hardware and software modules. Examples of processors 3404 include microprocessors, microcontrollers, digital signal processors (DSPs), SoCs, ASICs, field programmable gate arrays (FPGAs), programmable logic devices (PLDs), state machines, sequencers, gated logic, discrete hardware circuits, and other suitable hardware configured to perform the various functionality described throughout this disclosure. The one or more processors 3404 may include specialized processors that perform specific functions, and that may be configured, augmented or controlled by one of the software modules 3416. The one or more processors 3404 may be configured through a combination of software modules 3416 loaded during initialization, and further configured by loading or unloading one or more software modules 3416 during operation.

In the illustrated example, the processing circuit 3402 may be implemented with a bus architecture, represented generally by the bus 3410. The bus 3410 may include any number of interconnecting buses and bridges depending on the specific application of the processing circuit 3402 and the overall design constraints. The bus 3410 links together various circuits including the one or more processors 3404, and storage 3406. Storage 3406 may include memory devices and mass storage devices, and may be referred to herein as computer-readable media and/or processor-readable media. The storage 3406 may include transitory storage media and/or non-transitory storage media.

The bus 3410 may also link various other circuits such as timing sources, timers, peripherals, voltage regulators, and power management circuits. A bus interface 3408 may provide an interface between the bus 3410 and one or more transceivers 3412. In one example, a transceiver 3412 may be provided to enable the apparatus 3400 to communicate with a charging or receiving device in accordance with a standards-defined protocol. Depending upon the nature of the apparatus 3400, a user interface 3418 (e.g., keypad, display, speaker, microphone, joystick) may also be provided, and may be communicatively coupled to the bus 3410 directly or through the bus interface 3408.

A processor 3404 may be responsible for managing the bus 3410 and for general processing that may include the execution of software stored in a computer-readable medium that may include the storage 3406. In this respect, the processing circuit 3402, including the processor 3404, may be used to implement any of the methods, functions and techniques disclosed herein. The storage 3406 may be used for storing data that is manipulated by the processor 3404 when executing software, and the software may be configured to implement any one of the methods disclosed herein.

One or more processors 3404 in the processing circuit 3402 may execute software. Software shall be construed broadly to mean instructions, instruction sets, code, code segments, program code, programs, subprograms, software modules, applications, software applications, software packages, routines, subroutines, objects, executables, threads of execution, procedures, functions, algorithms, etc., whether referred to as software, firmware, middleware, microcode, hardware description language, or otherwise. The software may reside in computer-readable form in the storage 3406 or in an external computer-readable medium. The external computer-readable medium and/or storage 3406 may include a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a “flash drive,” a card, a stick, or a key drive), RAM, ROM, a programmable read-only memory (PROM), an erasable PROM (EPROM) including EEPROM, a register, a removable disk, and any other suitable medium for storing software and/or instructions that may be accessed and read by a computer. The computer-readable medium and/or storage 3406 may also include, by way of example, a carrier wave, a transmission line, and any other suitable medium for transmitting software and/or instructions that may be accessed and read by a computer. Computer-readable medium and/or the storage 3406 may reside in the processing circuit 3402, in the processor 3404, external to the processing circuit 3402, or be distributed across multiple entities including the processing circuit 3402. The computer-readable medium and/or storage 3406 may be embodied in a computer program product. By way of example, a computer program product may include a computer-readable medium in packaging materials. Those skilled in the art will recognize how best to implement the described functionality presented throughout this disclosure depending on the particular application and the overall design constraints imposed on the overall system.

The storage 3406 may maintain software maintained and/or organized in loadable code segments, modules, applications, programs, etc., which may be referred to herein as software modules 3416. Each of the software modules 3416 may include instructions and data that, when installed or loaded on the processing circuit 3402 and executed by the one or more processors 3404, contribute to a run-time image 3414 that controls the operation of the one or more processors 3404. When executed, certain instructions may cause the processing circuit 3402 to perform functions in accordance with certain methods, algorithms and processes described herein.

Some of the software modules 3416 may be loaded during initialization of the processing circuit 3402, and these software modules 3416 may configure the processing circuit 3402 to enable performance of the various functions disclosed herein. For example, some software modules 3416 may configure internal devices and/or logic circuits of the processor 3404, and may manage access to external devices such as a transceiver 3412, the bus interface 3408, the user interface 3418, timers, mathematical coprocessors, and so on. The software modules 3416 may include a control program and/or an operating system that interacts with interrupt handlers and device drivers, and that controls access to various resources provided by the processing circuit 3402. The resources may include memory, processing time, access to a transceiver 3412, the user interface 3418, and so on.

One or more processors 3404 of the processing circuit 3402 may be multifunctional, whereby some of the software modules 3416 are loaded and configured to perform different functions or different instances of the same function. The one or more processors 3404 may additionally be adapted to manage background tasks initiated in response to inputs from the user interface 3418, the transceiver 3412, and device drivers, for example. To support the performance of multiple functions 3422, the one or more processors 3404 may be configured to provide a multitasking environment, whereby each of a plurality of functions is implemented as a set of tasks serviced by the one or more processors 3404 as needed or desired. In one example, the multitasking environment may be implemented using a timesharing program 3420 that passes control of a processor 3404 between different tasks, whereby each task returns control of the one or more processors 3404 to the timesharing program 3420 upon completion of any outstanding operations and/or in response to an input such as an interrupt. When a task has control of the one or more processors 3404, the processing circuit is effectively specialized for the purposes addressed by the function associated with the controlling task. The timesharing program 3420 may include an operating system, a main loop that transfers control on a round-robin basis, a function that allocates control of the one or more processors 3404 in accordance with a prioritization of the functions, and/or an interrupt driven main loop that responds to external events by providing control of the one or more processors 3404 to a handling function.

In one example, the apparatus 3400 may include or be configured with means for transferring power, processing means and means for aligning movable charging coils. The means for transferring power may be configured to transfer power through a charging surface to multiple chargeable devices. The means for transferring power may include a printed circuit board that has fixed charging coils formed in a metal layer. The means for transferring power may further include movable charging coils. The processing means, which may include the processing circuit 3402, may be configured to locate one or more chargeable devices located adjacent to the charging surface. The means for aligning movable charging coils may be configured to align at least one movable charging coil in the plurality of movable charging coils with each chargeable device located adjacent to the charging surface. In some examples, the means for transferring power is configured to transmit power through one or more fixed charging coils after locating a first chargeable device adjacent to the charging surface and before a first movable charging coil is aligned with the first chargeable device.

In some implementations, the processing means is configured to locate a first chargeable device by causing passive pings to be transmitted through a plurality of fixed charging coils located proximate to the charging surface, determining or detecting that a change in an electrical or magnetic characteristic of one or more of the plurality of fixed charging coils has occurred, estimating location of the first chargeable device after determining or detecting that the change in the electrical or magnetic characteristic has occurred, and aligning a first movable charging coil with the estimated location of the first chargeable device.

In some implementations, the means for transferring power is further configured to transmit power through the first movable charging coil after the first movable charging coil is aligned with the first chargeable device.

The means for aligning the at least one movable charging coil may include multiple carriages that are moved through the action of linear actuators. The linear actuators may be implemented using some combination of worm drives, rack and pinion drives, belt drives, chain drives or other suitable linear actuators. In one example, a first carriage mechanically coupled to a first linear actuator that is configured to move the first carriage along a first axis, and a second carriage mechanically coupled to a second linear actuator that is configured to move the second carriage along a second axis. The first axis and the second axis may be mutually orthogonal. In this latter example, a first motor is mounted on the second carriage and configured to drive the first linear actuator in response to a first signal, and a second motor is coupled to the second linear actuator and configured to drive the second linear actuator in response to a second signal.

The means for aligning the at least one movable charging coil may further include a third carriage mechanically that is coupled to a third linear actuator that is configured to move the first carriage along a third axis and a fourth carriage that is mechanically coupled to a fourth linear actuator that is configured to move the fourth carriage along a fourth axis. A third motor mounted on the fourth carriage may be configured to drive the third linear actuator in response to a third signal and a fourth motor coupled to the fourth linear actuator may be configured to drive the fourth linear actuator in response to a fourth signal. The third axis may be in parallel alignment with the first axis and the fourth axis may be in parallel alignment with the second axis.

The apparatus may be constructed with movable Litz charging coils.

In some examples, the apparatus 3400 is included in, or operates as a wireless charging system that has a battery charging power source coupled to a charging circuit, a plurality of charging cells and one or more processors 3404. The plurality of charging cells may be configured to provide one or more charging surfaces that may be physically separated. At least one coil may be configured to direct an electromagnetic field through a charge transfer area of each charging cell.

In one example, a hybrid charging system has a plurality of fixed charging coils and at least one movable charging coil. The plurality of fixed charging coils may be formed in a metal layer of a PCB that is located adjacent to a charging surface. A first movable charging coil may be mechanically coupled to a first positioning mechanism that is configured to move the first movable charging coil across the charging surface. The printed circuit board may be located between the charging surface and the first movable charging coil.

The first positioning mechanism may include multiple carriages. A first carriage may be mechanically coupled to a first worm screw and may be configured to move along the first worm screw when the first worm screw turns. A second carriage may be mechanically coupled to a second worm screw and may be configured to move along the second worm screw when the second worm screw turns. The first positioning mechanism may incorporate or cooperate with a first motor. The first motor may be mounted on the second carriage and may be configured to turn the first worm screw in response to a first signal. The first positioning mechanism may incorporate or cooperate with a second motor. The second motor may be coupled to the second worm screw and may configured to turn the second worm screw in response to a second signal. The first worm screw and the second worm screw may be aligned along mutually orthogonal axes.

A processing circuit may be configured to conduct a search of the charging surface using some combination of passive pings and digital pings. Passive pings may be transmitted through the plurality of fixed charging coils. The processing circuit may be configured to detect or respond to a change in an electrical or magnetic characteristic of one or more of the plurality of fixed charging coils. The processing circuit may be configured to estimate location of a chargeable device after detecting the change in the electrical or magnetic characteristic.

The processing circuit may be configured to initiate power transfer through at least one fixed charging coil located proximate to an estimated location of the detected chargeable device. The processing circuit may be configured to align the first movable charging coil with the estimated location of the detected chargeable device. The processing circuit may be further configured to initiate power transfer through the first movable charging coil when the first movable charging coil is aligned with the estimated location of the detected chargeable device.

The hybrid charging system may have a second movable charging coil mechanically coupled to a second positioning mechanism. The second positioning mechanism may be configured to move the second movable charging coil across the charging surface. The PCB may be located between the charging surface and the second movable charging coil. The second positioning mechanism may include additional carriages. A third carriage may be mechanically coupled to a third worm screw and may be configured to move along the third worm screw when the third worm screw turns. A fourth carriage may be mechanically coupled to a fourth worm screw and may be configured to move along the fourth worm screw when the fourth worm screw turns. The second positioning mechanism may incorporate or cooperate with a third motor. The third motor may be mounted on the fourth carriage and may be configured to turn the third worm screw in response to a third signal. The second positioning mechanism may incorporate or cooperate with a fourth motor. The fourth motor may be coupled to the fourth worm screw and may configured to turn the fourth worm screw in response to a fourth signal. The third worm screw may be provided in parallel alignment with the first worm screw. The fourth worm screw may be provided in parallel alignment with the second worm screw.

In some implementations, the first movable charging coil comprises a Litz coil. The hybrid charging system or a portion of the hybrid charging system may be located within a cavity formed in a countertop.

Some implementation examples are described in the following numbered clauses:
1. A hybrid charging system, comprising: a plurality of fixed charging coils formed in a metal layer of a printed circuit board that is located adjacent to a charging surface provided by the hybrid charging system; and a first movable charging coil mechanically coupled to a first positioning mechanism that is configured to move the first movable charging coil across the charging surface, wherein the printed circuit board is located between the charging surface and the first movable charging coil.
2. The hybrid charging system as described in clause 1, wherein the first positioning mechanism comprises: a first carriage mechanically coupled to a first worm screw and configured to move along the first worm screw when the first worm screw turns; a second carriage mechanically coupled to a second worm screw and configured to move along the second worm screw when the second worm screw turns; a first motor mounted on the second carriage and configured to turn the first worm screw in response to a first signal; and a second motor coupled to the second worm screw and configured to turn the second worm screw in response to a second signal, wherein the first worm screw and the second worm screw are aligned along mutually orthogonal axes.
3. The hybrid charging system as described in clause 2, further comprising a processing circuit configured to: conduct a search of the charging surface by: transmitting passive pings through the plurality of fixed charging coils; and detecting a change in an electrical or magnetic characteristic of one or more of the plurality of fixed charging coils; estimate location of a chargeable device after detecting the change in the electrical or magnetic characteristic; initiate power transfer through at least one fixed charging coil located proximate to an estimated location of the detected chargeable device; and align the first movable charging coil with the estimated location of the detected chargeable device.
4. The hybrid charging system as described in clause 3, wherein the processing circuit is further configured to: initiate power transfer through the first movable charging coil when the first movable charging coil is aligned with the estimated location of the detected chargeable device.
5. The hybrid charging system as described in any of clauses 2-4, further comprising: a second movable charging coil mechanically coupled to a second positioning mechanism that is configured to move the second movable charging coil across the charging surface, wherein the printed circuit board is located between the charging surface and the second movable charging coil.
6. The hybrid charging system as described in clause 5, wherein the second positioning mechanism comprises: a third carriage mechanically coupled to a third worm screw and configured to move along the third worm screw when the third worm screw turns; a fourth carriage mechanically coupled to a fourth worm screw and configured to move along the fourth worm screw when the fourth worm screw turns; a third motor mounted on the fourth carriage and configured to turn the third worm screw in response to a third signal; and a fourth motor coupled to the fourth worm screw and configured to turn the fourth worm screw in response to a fourth signal, wherein the third worm screw is provided in parallel alignment with the first worm screw, and wherein the fourth worm screw is provided in parallel alignment with the second worm screw.
7. The hybrid charging system as described in any of clauses 1-6, wherein the first movable charging coil comprises a Litz coil.
8. The hybrid charging system as described in any of clauses 1-7, wherein at least a portion of the hybrid charging system is located within a cavity formed in a countertop.
9. A method for operating a charging system, comprising: conducting a search of a charging surface by: transmitting passive pings through a plurality of fixed charging coils located proximate to the charging surface; and detecting a change in an electrical or magnetic characteristic of one or more of the plurality of fixed charging coils; estimating location of a first chargeable device after detecting the change in the electrical or magnetic characteristic; initiating power transfer through at least a first fixed charging coil located proximate to an estimated location of the first chargeable device; and aligning a first movable charging coil with the estimated location of the first chargeable device.
10. The method as described in clause 9, further comprising: initiating power transfer through the first movable charging coil when the first movable charging coil is aligned with the estimated location of the first chargeable device.
11. The method as described in clause 9 or clause 10, wherein the first movable charging coil is one of a plurality of independently movable charging coils.
12. The method as described in any of clauses 9-11, further comprising: conducting a further search of the charging surface; estimating location of a second chargeable device after detecting a change in an electrical or magnetic characteristic associated with one or more other charging coils in the plurality of fixed charging coils; initiating power transfer through at least a second charging coil located proximate to an estimated location of the second chargeable device; and aligning a second movable charging coil with the estimated location of the second chargeable device.
13. The method as described in clause 12, further comprising: initiating power transfer to the second chargeable device through the second movable charging coil when the second movable charging coil is aligned with the estimated location of the second chargeable device.
14. The method as described in clause 13, wherein the charging system is configured to transfer power through the second movable charging coil while concurrently transferring power through the first movable charging coil.
15. An apparatus, comprising: means for transferring power through a charging surface to multiple chargeable devices, including a printed circuit board having a plurality of fixed charging coils formed in a metal layer thereon and a plurality of movable charging coils; processing means configured to locate one or more chargeable devices located adjacent to the charging surface; and means for aligning at least one movable charging coil in the plurality of movable charging coils with each chargeable device located adjacent to the charging surface, wherein the means for transferring power is configured to transmit power through one or more of the plurality of fixed charging coils after locating a first chargeable device adjacent to the charging surface and before a first movable charging coil is aligned with the first chargeable device.
16. The apparatus as described in clause 15, wherein the processing means is configured to locate a first chargeable device by: transmitting passive pings through a plurality of fixed charging coils located proximate to the charging surface; detecting a change in an electrical or magnetic characteristic of one or more of the plurality of fixed charging coils; estimating location of the first chargeable device after detecting the change in the electrical or magnetic characteristic; and aligning a first movable charging coil with the estimated location of the first chargeable device.
17. The apparatus as described in clause 16, wherein the means for transferring power is further configured to transmit power through the first movable charging coil after the first movable charging coil is aligned with the first chargeable device.
18. The apparatus as described in clause 17, wherein the means for aligning the at least one movable charging coil comprises: a first carriage mechanically coupled to a first linear actuator that is configured to move the first carriage along a first axis; a second carriage mechanically coupled to a second linear actuator that is configured to move the second carriage along a second axis, the first axis and the second axis being mutually orthogonal; a first motor mounted on the second carriage and configured to drive the first linear actuator in response to a first signal; and a second motor coupled to the second linear actuator and configured to drive the second linear actuator in response to a second signal.
19. The apparatus as described in clause 18, wherein the means for aligning the at least one movable charging coil further comprises: a third carriage mechanically coupled to a third linear actuator that is configured to move the first carriage along a third axis; a fourth carriage mechanically coupled to a fourth linear actuator that is configured to move the fourth carriage along a fourth axis; a third motor mounted on the fourth carriage and configured to drive the third linear actuator in response to a third signal; and a fourth motor coupled to the fourth linear actuator and configured to drive the fourth linear actuator in response to a fourth signal, wherein the third axis is in parallel alignment with the first axis, and wherein the fourth axis is in parallel alignment with the second axis.
20. The apparatus as described in any of clauses 15-19, wherein the plurality of movable charging coils includes movable Litz coils.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, whereby reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

1. A hybrid charging system, comprising:
a plurality of fixed charging coils formed in a metal layer of a printed circuit board that is located adjacent to a charging surface provided by the hybrid charging system; and
a first movable charging coil mechanically coupled to a first positioning mechanism that is configured to move the first movable charging coil across the charging surface,
wherein the printed circuit board is located between the charging surface and the first movable charging coil.

2. The hybrid charging system of claim 1, wherein the first positioning mechanism comprises:
a first carriage mechanically coupled to a first worm screw and configured to move along the first worm screw when the first worm screw turns;
a second carriage mechanically coupled to a second worm screw and configured to move along the second worm screw when the second worm screw turns;
a first motor mounted on the second carriage and configured to turn the first worm screw in response to a first signal; and
a second motor coupled to the second worm screw and configured to turn the second worm screw in response to a second signal,
wherein the first worm screw and the second worm screw are aligned along mutually orthogonal axes.

3. The hybrid charging system of claim 2, further comprising a processing circuit configured to:
conduct a search of the charging surface by:
transmitting passive pings through the plurality of fixed charging coils; and
detecting a change in an electrical or magnetic characteristic of one or more of the plurality of fixed charging coils;
estimate location of a chargeable device after detecting the change in the electrical or magnetic characteristic;
initiate power transfer through at least one fixed charging coil located proximate to an estimated location of the detected chargeable device; and
align the first movable charging coil with the estimated location of the detected chargeable device.

4. The hybrid charging system of claim 3, wherein the processing circuit is further configured to:
initiate power transfer through the first movable charging coil when the first movable charging coil is aligned with the estimated location of the detected chargeable device.

5. The hybrid charging system of claim 2, further comprising:
a second movable charging coil mechanically coupled to a second positioning mechanism that is configured to move the second movable charging coil across the charging surface, wherein the printed circuit board is located between the charging surface and the second movable charging coil.

6. The hybrid charging system of claim 5, wherein the second positioning mechanism comprises:
a third carriage mechanically coupled to a third worm screw and configured to move along the third worm screw when the third worm screw turns;
a fourth carriage mechanically coupled to a fourth worm screw and configured to move along the fourth worm screw when the fourth worm screw turns;
a third motor mounted on the fourth carriage and configured to turn the third worm screw in response to a third signal; and
a fourth motor coupled to the fourth worm screw and configured to turn the fourth worm screw in response to a fourth signal,
wherein the third worm screw is provided in parallel alignment with the first worm screw, and
wherein the fourth worm screw is provided in parallel alignment with the second worm screw.

7. The hybrid charging system of claim 1, wherein the first movable charging coil comprises a Litz coil.

8. The hybrid charging system of claim 1, wherein at least a portion of the hybrid charging system is located within a cavity formed in a countertop.

9. A method for operating a charging system, comprising:
conducting a search of a charging surface by:
transmitting passive pings through a plurality of fixed charging coils located proximate to the charging surface; and
detecting a change in an electrical or magnetic characteristic of one or more of the plurality of fixed charging coils;
estimating location of a first chargeable device after detecting the change in the electrical or magnetic characteristic;
initiating power transfer through at least a first fixed charging coil located proximate to an estimated location of the first chargeable device; and
aligning a first movable charging coil with the estimated location of the first chargeable device.

10. The method of claim 9, further comprising:
initiating power transfer through the first movable charging coil when the first movable charging coil is aligned with the estimated location of the first chargeable device.

11. The method of claim 9, wherein the first movable charging coil is one of a plurality of independently movable charging coils.

12. The method of claim 9, further comprising:
conducting a further search of the charging surface;
estimating location of a second chargeable device after detecting a change in an electrical or magnetic characteristic associated with one or more other charging coils in the plurality of fixed charging coils;
initiating power transfer through at least a second charging coil located proximate to an estimated location of the second chargeable device; and
aligning a second movable charging coil with the estimated location of the second chargeable device.

13. The method of claim 12, further comprising:
initiating power transfer to the second chargeable device through the second movable charging coil when the second movable charging coil is aligned with the estimated location of the second chargeable device.

14. The method of claim 13, wherein the charging system is configured to transfer power through the second movable charging coil while concurrently transferring power through the first movable charging coil.

15. An apparatus, comprising:
means for transferring power through a charging surface to multiple chargeable devices, including a printed circuit board having a plurality of fixed charging coils formed in a metal layer thereon and a plurality of movable charging coils;
processing means configured to locate one or more chargeable devices located adjacent to the charging surface; and
means for aligning at least one movable charging coil in the plurality of movable charging coils with each chargeable device located adjacent to the charging surface,
wherein the means for transferring power is configured to transmit power through one or more of the plurality of fixed charging coils after locating a first chargeable device adjacent to the charging surface and before a first movable charging coil is aligned with the first chargeable device.

16. The apparatus of claim 15, wherein the processing means is configured to locate a first chargeable device by:
transmitting passive pings through a plurality of fixed charging coils located proximate to the charging surface;
detecting a change in an electrical or magnetic characteristic of one or more of the plurality of fixed charging coils;
estimating location of the first chargeable device after detecting the change in the electrical or magnetic characteristic; and
aligning a first movable charging coil with the estimated location of the first chargeable device.

17. The apparatus of claim 16, wherein the means for transferring power is further configured to transmit power through the first movable charging coil after the first movable charging coil is aligned with the first chargeable device.

18. The apparatus of claim 17, wherein the means for aligning the at least one movable charging coil comprises:
a first carriage mechanically coupled to a first linear actuator that is configured to move the first carriage along a first axis;
a second carriage mechanically coupled to a second linear actuator that is configured to move the second carriage along a second axis, the first axis and the second axis being mutually orthogonal;
a first motor mounted on the second carriage and configured to drive the first linear actuator in response to a first signal; and
a second motor coupled to the second linear actuator and configured to drive the second linear actuator in response to a second signal.

19. The apparatus of claim 18, wherein the means for aligning the at least one movable charging coil further comprises:
a third carriage mechanically coupled to a third linear actuator that is configured to move the third carriage along a third axis;
a fourth carriage mechanically coupled to a fourth linear actuator that is configured to move the fourth carriage along a fourth axis;
a third motor mounted on the fourth carriage and configured to drive the third linear actuator in response to a third signal; and
a fourth motor coupled to the fourth linear actuator and configured to drive the fourth linear actuator in response to a fourth signal,
wherein the third axis is in parallel alignment with the first axis, and
wherein the fourth axis is in parallel alignment with the second axis.

20. The apparatus of claim 15, wherein the plurality of movable charging coils includes movable Litz coils.
